(19) United States
(12) Patent Application Publication
(10) Pub. No.: US 2025/0248035 A1
(43) Pub. Date: Jul. 31, 2025

(54) THREE-DIMENSIONAL MEMORY DEVICE WITH COMPACT STAIRCASES AND METHODS OF FORMING THE SAME

(71) Applicant: SANDISK TECHNOLOGIES LLC, ADDISON, TX (US)

(72) Inventors: Kazuto OHSAWA, Yokkaichi (JP); Hirofumi TOKITA, Yokkaichi (JP)

(21) Appl. No.: 18/426,069

(22) Filed: Jan. 29, 2024

(51) Int. Cl. H10B 43/27; H10B 41/27

(52) U.S. Cl. CPC H10B 43/27; H10B 41/27

(57) ABSTRACT

A three-dimensional memory device includes an alternating stack of insulating layers and electrically conductive layers including multiple staircase structures in a contact region; memory opening fill structures extending through the alternating stack; and at least one retro-stepped dielectric material portion contacting the multiple staircase structures. A portion of the alternating stack located in a connection region includes a connection-region staircase structures including connection-region staircase structures, and each horizontally-extending surface segment within the multiple staircase structures may be vertically offset downward from a respective most proximal horizontally-extending surface segment in the connection-region staircase structures. Alternative or additionally, the various staircase structures can be patterned by forming trimmable photoresist material portions having a same initial gap width between them, and by forming pairs of a descending staircase structure and an ascending staircase structure.

### FIELD

The present disclosure relates generally to the field of semiconductor devices, and particularly to three-dimensional memory devices having compact staircases and methods of forming the same.

### BACKGROUND

A three-dimensional memory device including three-dimensional vertical NAND strings having one bit per cell are disclosed in an article by T. Endoh et al, titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: an alternating stack of insulating layers and electrically conductive layers, wherein the alternating stack comprises multiple staircase structures that are arranged along a first horizontal direction; memory openings vertically extending through the alternating stack; memory opening fill structures located in the memory openings, wherein each of the memory opening fill structures comprises a respective vertical stack of memory elements and a vertical semiconductor channel; and at least one retro-stepped dielectric material portion contacting the multiple staircase structures, wherein: a first subset of the memory opening fill structures is located in a first memory array region; a second subset of the memory opening fill structures is located in a second memory array region that is laterally offset from the first memory array region along a first horizontal direction; the multiple staircase structures are located in a contact region which is located between the first memory array region and the second memory array region; a predominant subset of the electrically conductive layers extends continuously between the first memory array region and the second memory array region within a connection region that is located between the first memory array region and the second memory array region and laterally offset from the contact region along a second horizontal direction; a portion of the alternating stack located in the connection region comprises connection-region staircase structures; and each horizontally-extending surface segment within the multiple staircase structures in the contact region is vertically offset downward from a respective most proximal horizontally-extending surface segment in the connection-region staircase structures at least by a sum of a thickness of an insulating layer in the alternating stack and a thickness of an electrically conductive layer within the alternating stack.

According to another aspect of the present disclosure, a method forming a three-dimensional memory device is provided. The method comprises: forming an alternating stack of insulating layers and sacrificial material layers, wherein the alternating stack comprises a first memory array region, a second memory array region that is laterally spaced from the first memory array region along a first horizontal direction, and a contact region and a connection region that are located between the first memory array region and the second memory array region and laterally offset from each other along a second horizontal direction; patterning an array of vertical indentation wells that are arranged along the first horizontal direction in upper portion of the alternating stack in the contact region without patterning the alternating stack in the connection region to form a vertical step between each of the vertical indentation wells and an adjoining portion of the alternating stack; forming vertical steps extending along the second horizontal direction across the contact region and the connection region by forming trimmable photoresist material portions over the alternating stack and repeatedly performing a combination of processing steps including an anisotropic etch step and a photoresist trimming step to form multiple staircase structures in the contact region and connection-region staircase structures are formed in the connection region; vertically recessing different staircase structures of the multiple staircase structures by different recess depths by performing a series of masked vertical recess processes wherein the multiple staircase structures comprise a physically exposed top surface segment of each sacrificial material layer within the alternating stack; forming at least one retro-stepped dielectric material portion over the multiple staircase structures and the connection-region staircase structures; and replacing the sacrificial material layers with electrically conductive layers.

According to yet another aspect of the present disclosure, a three-dimensional memory device is provided, which comprises: an alternating stack of insulating layers and electrically conductive layers overlying a semiconductor material layer, wherein the alternating stack comprises multiple staircase structures that are arranged along a first horizontal direction, wherein the multiple staircase structures comprise first staircase structures that are interconnected to each other by widthwise sidewalls that laterally extend along a second horizontal direction that is perpendicular to the first horizontal direction, second staircase structures that are laterally spaced from the first staircase structures, and third staircase structures that are laterally spaced from the first staircase structures and from the second staircase structures; memory openings vertically extending through the alternating stack; memory opening fill structures located in the memory openings, wherein each of the memory opening fill structures comprises a respective vertical stack of memory elements and a vertical semiconductor channel; and at least one retro-stepped dielectric material portion contacting the first staircase structures, the second staircase structures, the third staircase structures, a first surface segment of a top surface of the semiconductor material layer located between the first staircase structures and the second staircase structures, and a second surface segment of the top surface of the semiconductor material layer located between the first staircase structures and the third staircase structures.

According to still another aspect of the present disclosure, a method forming a three-dimensional memory device is provided. The method comprises: forming an alternating stack of insulating layers and sacrificial material layers over a semiconductor material layer, wherein the alternating stack comprises a first memory array region, a second memory array region that is laterally spaced from the first memory array region along a first horizontal direction, and a contact region and a connection region that are located between the first memory array region and the second memory array region and laterally offset from each other along a second horizontal direction; forming vertical steps extending along the second horizontal direction across the contact region and the connection region by forming trimmable photoresist material portions over the alternating stack and repeatedly performing a combination of processing steps including an anisotropic etch step and a photoresist trimming step, wherein each neighboring pair of trimmable photoresist material portions of the trimmable photoresist material portions is laterally spaced from each other along the first horizontal direction by a same initial gap width that is invariant along the second horizontal direction, and wherein multiple staircase structures are formed in the contact region and connection-region staircase structures are formed in the connection region; vertically recessing different staircase structures of the multiple staircase structures by different recess depths by performing a series of masked vertical recess processes, whereby the multiple staircase structures comprise a physically exposed top surface segment of each sacrificial material layer within the alternating stack; forming at least one retro-stepped dielectric material portion over the multiple staircase structures and the connection-region staircase structures; and replacing the sacrificial material layers with electrically conductive layers.

### BRIEF DESCRIPTION OF THE DRAWINGS

FIG. 1 is a plan view of a portion of a semiconductor wafer including semiconductor dies and kerf regions according to an embodiment of the present disclosure.

FIG. 2 is a vertical cross-sectional view of a first configuration of an exemplary structure after formation of optional semiconductor devices, optional lower-level dielectric material layers, optional lower-level metal interconnect structures, a semiconductor material layer, and an alternating layer stack of insulating layers and sacrificial material layers according to an embodiment of the present disclosure. The view shown in FIG. 2 corresponds to a vertical cross-sectional view of region M1 in FIG. 1 of a first configuration of the exemplary structure along a first horizontal direction.

FIG. 3A is a first vertical cross-sectional view along a first vertical plane of the first configuration of the exemplary structure after patterning the alternating stack employing a first patterned photoresist layer according to an embodiment of the present disclosure.

FIG. 3B is a second vertical cross-sectional view along a second vertical plane of the first configuration of the exemplary structure after the processing steps of FIG. 3A.

FIG. 3C is a top-down view of the first configuration of the exemplary structure of FIGS. 3A and 3B. The vertical plane A-A′ is the cut plane of the vertical cross-sectional view of FIG. 3A. The vertical plane B-B′ is the cut plane of the vertical cross-sectional view of FIG. 3B.

FIG. 3D is a top-down view of a portion of the semiconductor wafer after the processing steps of FIGS. 3A-3C. The region M1 corresponds to the area of the top-down view of FIG. 3C.

FIG. 3E is a vertical cross-sectional view of the semiconductor wafer along the vertical plane E-E′ of FIG. 3D.

FIG. 4A is a first vertical cross-sectional view along a first vertical plane of the first configuration of the exemplary structure after patterning the alternating stack employing a second patterned photoresist layer according to an embodiment of the present disclosure.

FIG. 4B is a second vertical cross-sectional view along a second vertical plane of the first configuration of the exemplary structure after the processing steps of FIG. 4A.

FIG. 4C is a top-down view of the first configuration of the exemplary structure of FIGS. 4A and 4B. The vertical plane A-A′ is the cut plane of the vertical cross-sectional view of FIG. 4A. The vertical plane B-B′ is the cut plane of the vertical cross-sectional view of FIG. 4B.

FIG. 4D is a top-down view of a portion of the semiconductor wafer after the processing steps of FIGS. 4A-4C. The region M1 corresponds to the area of the top-down view of FIG. 4C.

FIG. 4E is a vertical cross-sectional view of the semiconductor wafer along the vertical plane E-E′ of FIG. 4D.

FIG. 5A is a first vertical cross-sectional view along a first vertical plane of the first configuration of the exemplary structure after formation of patterned trimmable photoresist material portions according to an embodiment of the present disclosure.

FIG. 5B is a second vertical cross-sectional view along a second vertical plane of the first configuration of the exemplary structure after the processing steps of FIG. 5A.

FIG. 5C is a top-down view of the first configuration of the exemplary structure of FIGS. 5A and 5B. The vertical plane A-A′ is the cut plane of the vertical cross-sectional view of FIG. 5A. The vertical plane B-B′ is the cut plane of the vertical cross-sectional view of FIG. 5B.

FIG. 5D is a top-down view of a portion of the semiconductor wafer after the processing steps of FIGS. 5A-5C. The region M1 corresponds to the area of the top-down view of FIG. 5C.

FIG. 5E is a vertical cross-sectional view of the semiconductor wafer along the vertical plane E-E′ of FIG. 5D.

FIG. 6A is a first vertical cross-sectional view along a first vertical plane of the first configuration of the exemplary structure after performing a set of processing steps that include K anisotropic etch processes interlaced with (K−1) photoresist trimming processes according to an embodiment of the present disclosure.

FIG. 6B is a second vertical cross-sectional view along a second vertical plane of the first configuration of the exemplary structure after the processing steps of FIG. 6A.

FIG. 6C is a top-down view of the first configuration of the exemplary structure of FIGS. 6A and 6B. The vertical plane A-A′ is the cut plane of the vertical cross-sectional view of FIG. 6A. The vertical plane B-B′ is the cut plane of the vertical cross-sectional view of FIG. 6B.

FIG. 6D is a top-down view of a portion of the semiconductor wafer after the processing steps of FIGS. 6A-6C. The region M1 corresponds to the area of the top-down view of FIG. 6C.

FIG. 6E is a vertical cross-sectional view of the semiconductor wafer along the vertical plane E-E′ of FIG. 6D.

FIG. 7A is a first vertical cross-sectional view along a first vertical plane of the first configuration of the exemplary structure after performing a first masked vertical recess process according to an embodiment of the present disclosure.

FIG. 7B is a second vertical cross-sectional view along a second vertical plane of the first configuration of the exemplary structure after the processing steps of FIG. 7A.

FIG. 7C is a top-down view of the first configuration of the exemplary structure of FIGS. 7A and 7B. The vertical plane A-A′ is the cut plane of the vertical cross-sectional view of FIG. 7A. The vertical plane B-B′ is the cut plane of the vertical cross-sectional view of FIG. 7B.

FIG. 7D is a top-down view of a portion of the semiconductor wafer after the processing steps of FIGS. 7A-7C. The region M1 corresponds to the area of the top-down view of FIG. 7C.

FIG. 7E is a vertical cross-sectional view of the semiconductor wafer along the vertical plane E-E′ of FIG. 7D.

FIG. 8A is a first vertical cross-sectional view along a first vertical plane of the first configuration of the exemplary structure after performing a last masked vertical recess process according to an embodiment of the present disclosure.

FIG. 8B is a second vertical cross-sectional view along a second vertical plane of the first configuration of the exemplary structure after the processing steps of FIG. 8A.

FIG. 8C is a top-down view of the first configuration of the exemplary structure of FIGS. 8A and 8B. The vertical plane A-A′ is the cut plane of the vertical cross-sectional view of FIG. 8A. The vertical plane B-B′ is the cut plane of the vertical cross-sectional view of FIG. 8B.

FIG. 8D is a top-down view of a portion of the semiconductor wafer after the processing steps of FIGS. 8A-8C. The region M1 corresponds to the area of the top-down view of FIG. 8C.

FIG. 8E is a vertical cross-sectional view of the semiconductor wafer along the vertical plane E-E′ of FIG. 8D.

FIG. 9A is a first vertical cross-sectional view along a first vertical plane of the first configuration of the exemplary structure after formation of retro-stepped dielectric material portions and dielectric moat structures according to an embodiment of the present disclosure.

FIG. 9B is a second vertical cross-sectional view along a second vertical plane of the first configuration of the exemplary structure after the processing steps of FIG. 9A.

FIG. 9C is a top-down view of the first configuration of the exemplary structure of FIGS. 9A and 9B. The vertical plane A-A′ is the cut plane of the vertical cross-sectional view of FIG. 9A. The vertical plane B-B′ is the cut plane of the vertical cross-sectional view of FIG. 9B.

FIG. 9D is a top-down view of a portion of the semiconductor wafer after the processing steps of FIGS. 9A-9C. The region M1 corresponds to the area of the top-down view of FIG. 9C.

FIG. 9E is a vertical cross-sectional view of the semiconductor wafer along the vertical plane E-E′ of FIG. 9D.

FIG. 10A is a first vertical cross-sectional view along a first vertical plane of a second configuration of the exemplary structure after patterning the alternating stack employing a first patterned photoresist layer according to an embodiment of the present disclosure.

FIG. 10B is a second vertical cross-sectional view along a second vertical plane of the second configuration of the exemplary structure after the processing steps of FIG. 10A.

FIG. 10C is a top-down view of the second configuration of the exemplary structure of FIGS. 10A and 10B. The vertical plane A-A′ is the cut plane of the vertical cross-sectional view of FIG. 10A. The vertical plane B-B′ is the cut plane of the vertical cross-sectional view of FIG. 10B.

FIG. 11A is a first vertical cross-sectional view along a first vertical plane of the second configuration of the exemplary structure after patterning the alternating stack employing a second patterned photoresist layer according to an embodiment of the present disclosure.

FIG. 11B is a second vertical cross-sectional view along a second vertical plane of the second configuration of the exemplary structure after the processing steps of FIG. 11A.

FIG. 11C is a top-down view of the second configuration of the exemplary structure of FIGS. 11A and 11B. The vertical plane A-A′ is the cut plane of the vertical cross-sectional view of FIG. 11A. The vertical plane B-B′ is the cut plane of the vertical cross-sectional view of FIG. 11B.

FIG. 12A is a first vertical cross-sectional view along a first vertical plane of the second configuration of the exemplary structure after formation of patterned trimmable photoresist material portions according to an embodiment of the present disclosure.

FIG. 12B is a second vertical cross-sectional view along a second vertical plane of the second configuration of the exemplary structure after the processing steps of FIG. 12A.

FIG. 12C is a top-down view of the second configuration of the exemplary structure of FIGS. 12A and 12B. The vertical plane A-A′ is the cut plane of the vertical cross-sectional view of FIG. 12A. The vertical plane B-B′ is the cut plane of the vertical cross-sectional view of FIG. 12B.

FIG. 13A is a first vertical cross-sectional view along a first vertical plane of the second configuration of the exemplary structure after performing a set of processing steps that include K anisotropic etch processes interlaced with (K−1) photoresist trimming processes according to an embodiment of the present disclosure.

FIG. 13B is a second vertical cross-sectional view along a second vertical plane of the second configuration of the exemplary structure after the processing steps of FIG. 13A.

FIG. 13C is a top-down view of the second configuration of the exemplary structure of FIGS. 13A and 13B. The vertical plane A-A′ is the cut plane of the vertical cross-sectional view of FIG. 13A. The vertical plane B-B′ is the cut plane of the vertical cross-sectional view of FIG. 13B.

FIG. 14A is a first vertical cross-sectional view along a first vertical plane of the second configuration of the exemplary structure after performing a first masked vertical recess process according to an embodiment of the present disclosure.

FIG. 14B is a second vertical cross-sectional view along a second vertical plane of the second configuration of the exemplary structure after the processing steps of FIG. 14A.

FIG. 14C is a top-down view of the second configuration of the exemplary structure of FIGS. 14A and 14B. The vertical plane A-A′ is the cut plane of the vertical cross-sectional view of FIG. 14A. The vertical plane B-B′ is the cut plane of the vertical cross-sectional view of FIG. 14B.

FIG. 15A is a first vertical cross-sectional view along a first vertical plane of the second configuration of the exemplary structure after performing a last masked vertical recess process according to an embodiment of the present disclosure.

FIG. 15B is a second vertical cross-sectional view along a second vertical plane of the second configuration of the exemplary structure after the processing steps of FIG. 15A.

FIG. 15C is a top-down view of the second configuration of the exemplary structure of FIGS. 15A and 15B. The vertical plane A-A′ is the cut plane of the vertical cross-sectional view of FIG. 15A. The vertical plane B-B′ is the cut plane of the vertical cross-sectional view of FIG. 15B.

FIG. 16A is a first vertical cross-sectional view along a first vertical plane of the second configuration of the exemplary structure after formation of retro-stepped dielectric material portions and dielectric moat structures according to an embodiment of the present disclosure.

FIG. 16B is a second vertical cross-sectional view along a second vertical plane of the second configuration of the exemplary structure after the processing steps of FIG. 16A.

FIG. 16C is a top-down view of the second configuration of the exemplary structure of FIGS. 16A and 16B. The vertical plane A-A′ is the cut plane of the vertical cross-sectional view of FIG. 16A. The vertical plane B-B′ is the cut plane of the vertical cross-sectional view of FIG. 16B.

FIG. 17A is a first vertical cross-sectional view along a first vertical plane of a third configuration of the exemplary structure after patterning the alternating stack employing a first patterned photoresist layer according to an embodiment of the present disclosure.

FIG. 17B is a second vertical cross-sectional view along a second vertical plane of the third configuration of the exemplary structure after the processing steps of FIG. 17A.

FIG. 18A is a first vertical cross-sectional view along a first vertical plane of the third configuration of the exemplary structure after patterning the alternating stack employing a second patterned photoresist layer according to an embodiment of the present disclosure.

FIG. 18B is a second vertical cross-sectional view along a second vertical plane of the third configuration of the exemplary structure after the processing steps of FIG. 18A.

FIG. 19A is a first vertical cross-sectional view along a first vertical plane of the third configuration of the exemplary structure after performing a set of processing steps that include K anisotropic etch processes interlaced with (K−1) photoresist trimming processes according to an embodiment of the present disclosure.

FIG. 19B is a second vertical cross-sectional view along a second vertical plane of the third configuration of the exemplary structure after the processing steps of FIG. 19A.

FIG. 20A is a first vertical cross-sectional view along a first vertical plane of the third configuration of the exemplary structure after performing a last masked vertical recess process according to an embodiment of the present disclosure.

FIG. 20B is a second vertical cross-sectional view along a second vertical plane of the third configuration of the exemplary structure after the processing steps of FIG. 20A.

FIG. 21A is a first vertical cross-sectional view along a first vertical plane of the third configuration of the exemplary structure after formation of retro-stepped dielectric material portions and dielectric moat structures according to an embodiment of the present disclosure.

FIG. 21B is a second vertical cross-sectional view along a second vertical plane of the third configuration of the exemplary structure after the processing steps of FIG. 21A.

FIG. 22A is a first vertical cross-sectional view along a first vertical plane of a fourth configuration of the exemplary structure after patterning the alternating stack employing a first patterned photoresist layer according to an embodiment of the present disclosure.

FIG. 22B is a second vertical cross-sectional view along a second vertical plane of the fourth configuration of the exemplary structure after the processing steps of FIG. 22A.

FIG. 22C is a top-down view of the fourth configuration of the exemplary structure of FIGS. 22A and 22B. The vertical plane A-A′ is the cut plane of the vertical cross-sectional view of FIG. 22A. The vertical plane B-B′ is the cut plane of the vertical cross-sectional view of FIG. 22B.

FIG. 23A is a first vertical cross-sectional view along a first vertical plane of the fourth configuration of the exemplary structure after patterning the alternating stack employing a second patterned photoresist layer according to an embodiment of the present disclosure.

FIG. 23B is a second vertical cross-sectional view along a second vertical plane of the fourth configuration of the exemplary structure after the processing steps of FIG. 23A.

FIG. 23C is a top-down view of the fourth configuration of the exemplary structure of FIGS. 23A and 23B. The vertical plane A-A′ is the cut plane of the vertical cross-sectional view of FIG. 23A. The vertical plane B-B′ is the cut plane of the vertical cross-sectional view of FIG. 23B.

FIG. 24A is a first vertical cross-sectional view along a first vertical plane of the fourth configuration of the exemplary structure after performing a set of processing steps that include K anisotropic etch processes interlaced with (K−1) photoresist trimming processes according to an embodiment of the present disclosure.

FIG. 24B is a second vertical cross-sectional view along a second vertical plane of the fourth configuration of the exemplary structure after the processing steps of FIG. 24A.

FIG. 24C is a top-down view of the fourth configuration of the exemplary structure of FIGS. 24A and 24B. The vertical plane A-A′ is the cut plane of the vertical cross-sectional view of FIG. 24A. The vertical plane B-B′ is the cut plane of the vertical cross-sectional view of FIG. 24B.

FIG. 25A is a first vertical cross-sectional view along a first vertical plane of the fourth configuration of the exemplary structure after performing a first masked vertical recess process according to an embodiment of the present disclosure.

FIG. 25B is a second vertical cross-sectional view along a second vertical plane of the fourth configuration of the exemplary structure after the processing steps of FIG. 25A.

FIG. 25C is a top-down view of the fourth configuration of the exemplary structure of FIGS. 25A and 25B. The vertical plane A-A′ is the cut plane of the vertical cross-sectional view of FIG. 25A. The vertical plane B-B′ is the cut plane of the vertical cross-sectional view of FIG. 25B.

FIG. 26A is a first vertical cross-sectional view along a first vertical plane of the fourth configuration of the exemplary structure after performing a last masked vertical recess process according to an embodiment of the present disclosure.

FIG. 26B is a second vertical cross-sectional view along a second vertical plane of the fourth configuration of the exemplary structure after the processing steps of FIG. 26A.

FIG. 26C is a top-down view of the fourth configuration of the exemplary structure of FIGS. 26A and 26B. The vertical plane A-A′ is the cut plane of the vertical cross-sectional view of FIG. 26A. The vertical plane B-B′ is the cut plane of the vertical cross-sectional view of FIG. 26B.

FIG. 27A is a first vertical cross-sectional view along a first vertical plane of the fourth configuration of the exemplary structure after formation of retro-stepped dielectric material portions and dielectric moat structures according to an embodiment of the present disclosure.

FIG. 27B is a second vertical cross-sectional view along a second vertical plane of the fourth configuration of the exemplary structure after the processing steps of FIG. 27A.

FIG. 27C is a top-down view of the fourth configuration of the exemplary structure of FIGS. 27A and 27B. The vertical plane A-A′ is the cut plane of the vertical cross-sectional view of FIG. 27A. The vertical plane B-B′ is the cut plane of the vertical cross-sectional view of FIG. 27B.

FIG. 28A is a vertical cross-sectional view of the exemplary structure after formation of retro-stepped dielectric material portions according to an embodiment of the present disclosure.

FIG. 28B is a top-down view of the exemplary structure of FIG. 28A.

FIG. 29A is a vertical cross-sectional view of the exemplary structure after formation of support pillar structures according to an embodiment of the present disclosure.

FIG. 29B is a top-down view of the exemplary structure of FIG. 29A.

FIG. 30A is a vertical cross-sectional view of the exemplary structure after formation of memory openings according to an embodiment of the present disclosure.

FIG. 30B is a top-down view of the exemplary structure of FIG. 30A.

FIGS. 31A-31F are sequential vertical cross-sectional views of a memory opening during formation of a memory opening fill structure according to an embodiment of the present disclosure.

FIG. 32A is a vertical cross-sectional view of the exemplary structure after formation of memory opening fill structures according to an embodiment of the present disclosure.

FIG. 32B is a top-down view of the exemplary structure of FIG. 32A.

FIG. 33A is a first vertical cross-sectional view along a first vertical plane of the exemplary structure after formation of lateral isolation trenches according to an embodiment of the present disclosure.

FIG. 33B is a second vertical cross-sectional view along a second vertical plane of the fourth configuration of the exemplary structure after the processing steps of FIG. 33A.

FIG. 33C is a top-down view of the exemplary structure of FIGS. 33A and 33B. The vertical plane A-A′ is the cut plane of the vertical cross-sectional view of FIG. 33A. The vertical plane B-B′ is the cut plane of the vertical cross-sectional view of FIG. 33B.

FIG. 33D is a vertical cross-sectional view of the exemplary structure along the vertical plane D-D′ of FIG. 33C.

FIG. 34A is a first vertical cross-sectional view along a first vertical plane of the exemplary structure after replacement of sacrificial material layers with electrically conductive layers according to an embodiment of the present disclosure.

FIG. 34B is a second vertical cross-sectional view along a second vertical plane of the fourth configuration of the exemplary structure after the processing steps of FIG. 34A.

FIG. 34C is a top-down view of the exemplary structure of FIGS. 34A and 34B. The vertical plane A-A′ is the cut plane of the vertical cross-sectional view of FIG. 34A. The vertical plane B-B′ is the cut plane of the vertical cross-sectional view of FIG. 34B.

FIG. 34D is a vertical cross-sectional view of the exemplary structure along the vertical plane D-D′ of FIG. 34C.

FIG. 35A is a first vertical cross-sectional view along a first vertical plane of the exemplary structure after formation of a contact-level dielectric layer and contact via structures according to an embodiment of the present disclosure.

FIG. 35B is a second vertical cross-sectional view along a second vertical plane of the fourth configuration of the exemplary structure after the processing steps of FIG. 35A.

FIG. 35C is a top-down view of the exemplary structure of FIGS. 35A and 35B. The vertical plane A-A′ is the cut plane of the vertical cross-sectional view of FIG. 35A. The vertical plane B-B′ is the cut plane of the vertical cross-sectional view of FIG. 35B.

FIG. 35D is a vertical cross-sectional view of the exemplary structure along the vertical plane D-D′ of FIG. 35C.

FIG. 35E is a top-down view of a portion of the semiconductor wafer after the processing steps of FIGS. 35A-35D. The region M1 corresponds to the area of the top-down view of FIG. 35C.

FIG. 35F is a vertical cross-sectional view of the semiconductor wafer along the vertical plane F-F′ of FIG. 35E.

### DETAILED DESCRIPTION

As discussed above, the embodiments of the present disclosure are directed to three-dimensional memory devices having compact staircase regions in which electrical contacts are provided to word lines and select gate electrodes and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or to each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

The various three-dimensional memory devices of the present disclosure include a monolithic three-dimensional NAND string memory device, and may be fabricated using the various embodiments described herein. The monolithic three-dimensional NAND string is located in a monolithic, three-dimensional array of NAND strings located over the substrate. At least one memory cell in the first device level of the three-dimensional array of NAND strings is located over another memory cell in the second device level of the three-dimensional array of NAND strings.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

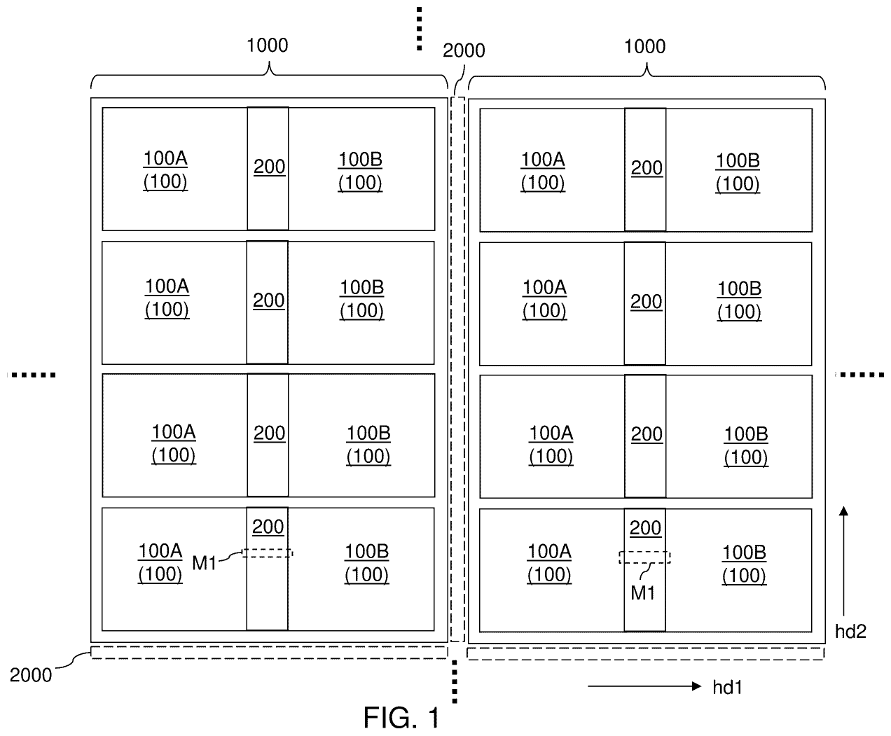

Referring to FIG. 1, a portion of an exemplary semiconductor wafer is illustrated in a plan view. The illustrated portion of the exemplary semiconductor wafer includes areas of two semiconductor dies 1000 and a kerf region 2000 located therebetween. Generally, a two-dimensional periodic array of semiconductor dies 1000 can be formed on a semiconductor wafer, and kerf regions 2000 can be formed between each neighboring pair of semiconductor dies 1000 on the semiconductor wafer. In one embodiment, each semiconductor die 1000 may have a rectangular area in a plan view, such as a top-down view. In one embodiment, edges of the semiconductor dies 1000 may be parallel to a first horizontal direction hd1 or a second horizontal direction hd2 that is perpendicular to the first horizontal direction hd1. Repetition of the illustrated portion of the exemplary structure in a two-dimensional periodic array along the first horizontal direction hd1 and the second horizontal direction hd2 is schematically represented by dotted lines.

Each semiconductor die 1000 may include multiple planes, each of which includes two memory array regions 100, such as a first memory array region 100A and a second memory array region 100B that are laterally spaced apart by a respective inter-array region 200. Generally, a semiconductor die 1000 may include a single plane or multiple planes. The total number of planes in the semiconductor die 1000 may be selected based on performance requirements on the semiconductor die 1000. A pair of memory array regions 100 in a plane may be laterally spaced apart along a first horizontal direction hd1 (which may be the word line direction). For example, each pair of memory array regions 100 in a plane may include first memory array region 100A and a second memory array region 100B that are laterally spaced apart along the first horizontal direction hd1 by an inter-array region 200. A second horizontal direction hd2 (which may be the bit line direction) can be perpendicular to the first horizontal direction hd1.

The semiconductor dies 1000 illustrated in FIG. 1 can be manufactured employing various embodiments of the present disclosure to be described below. Four exemplary configurations are shown to provide exemplary sequences of processing steps for forming the exemplary semiconductor die 1000 of FIG. 1. Region M1 in FIG. 1 is illustrated in detail in subsequent figures.

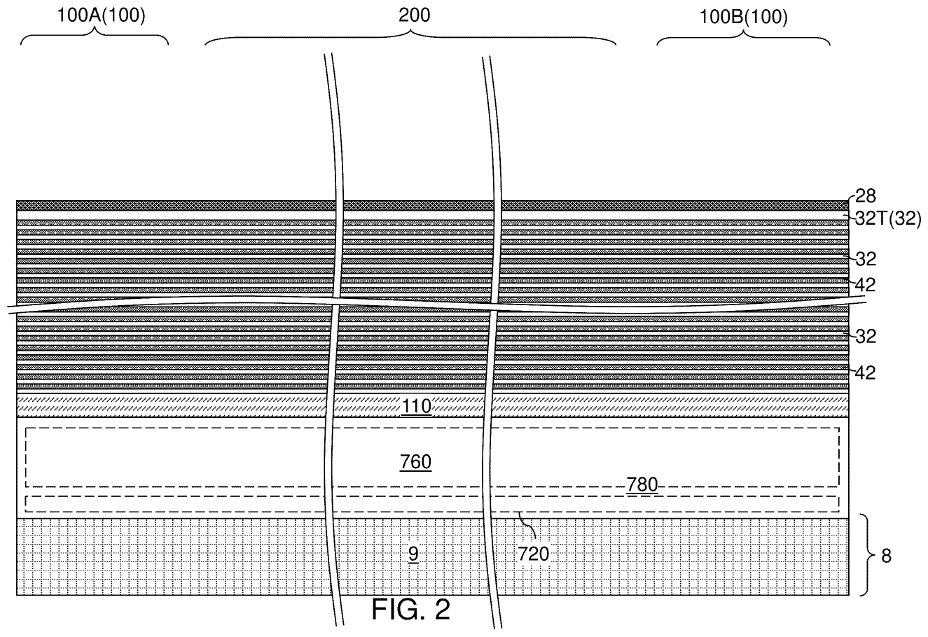

FIG. 2 is a vertical cross-sectional view of region M1 of FIG. 1 of a first configuration of an exemplary structure is illustrated after formation of optional semiconductor devices 720, optional lower-level dielectric material layers 760, optional lower-level metal interconnect structures 780, a semiconductor material layer 110, an alternating layer stack of insulating layers 32 and sacrificial material layers 42, and a patterned hard mask layer 28 over a substrate 8.

The substrate 8 may be a single crystalline silicon wafer, a silicon on insulator (SOI) substrate, or an insulating (e.g., glass or quartz) substrate. The substrate 8 comprises a substrate semiconductor layer 9 at a top portion thereof. The substrate semiconductor layer 9 may be a single crystalline semiconductor material layer such as a single crystalline silicon layer that is epitaxially grown on a silicon wafer or SOI substrate, or a doped well in an upper portion of a silicon wafer or SOI substrate.

The semiconductor devices 720 can be formed on the top surface of the substrate semiconductor layer 9. For example, the semiconductor devices 720 may include field effect transistors, resistors, capacitors, diodes, and/or various other semiconductor devices known in the art. In one embodiment, the semiconductor devices 720 may include a peripheral (i.e., driver) circuit for controlling the operation of three-dimensional memory arrays to be subsequently formed thereabove. Metal interconnect structures embedded in dielectric material layers can be formed above the semiconductor devices. The metal interconnect structures are herein referred to as lower-level metal interconnect structures 780, and the dielectric material layers are herein referred to as lower-level dielectric material layers 760. The lower-level metal interconnect structures 780 are electrically connected to various nodes of the semiconductor devices 720, and can include metal line structures and metal via structures located at various levels of the lower-level dielectric material layers 760.

A semiconductor material layer 110 can be formed on the top surface of the lower-level dielectric material layers 760. The semiconductor material layer 110 may be single crystalline or polycrystalline, and may be formed by a layer transfer from a source substrate (such as a single crystalline silicon layer including a buried hydrogen implantation layer), or may be formed by deposition of a semiconductor material (which may be a polycrystalline semiconductor material, such as polysilicon).

An alternating stack of insulating layers 32 and sacrificial material layers 42 can be formed over the semiconductor material layer 110. As used herein, an alternating stack refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. An alternating stack refers to a sequence of multiple instances of a first material layer and multiple instances of a second material layer such that the instances of the first material layer and the instances of the second material layer are interlaced.

The insulating layers 32 can be composed of the first material, and the sacrificial material layers 42 can be composed of the second material, which is different from the first material. Each of the insulating layers 32 continuously extends over the entire area of the substrate 8, and may have a uniform thickness throughout. Each of the sacrificial material layers 42 includes a sacrificial dielectric material and continuously extends over the entire area of the substrate 8, and may have a uniform thickness throughout. Insulating materials that may be used for the insulating layers 32 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 may be silicon oxide.

The second material of the sacrificial material layers 42 is a dielectric material, which is a sacrificial material that may be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material. The second material of the sacrificial material layers 42 may be subsequently replaced with electrically conductive electrodes which may function, for example, as control gate electrodes of a vertical NAND device. In one embodiment, the sacrificial material layers 42 may be material layers that comprise silicon nitride.

Each insulating layer 32 may have a first thickness, which may be in a range from 15 nm to 60 nm, although lesser and greater thicknesses may also be employed. Each sacrificial material layer 42 may have a second thickness, which may be in a range from 15 nm to 60 nm, although lesser and greater thicknesses may also be employed. The total number of repetitions of a pair of an insulating layer 32 and a sacrificial material layer 42 in the alternating stack (32, 42) may be in a range from 16 to 1,024, such as from 64 to 512, although lesser and greater numbers may also be employed. The topmost layer of the insulating layers 32 is herein referred to as a topmost insulating layer 32T.

A hard mask layer 28 can be formed over the alternating stack (32, 42). The hard mask layer 28 comprises a material that can be removed selective to the material of the topmost insulating layer 32T. In one embodiment, the hard mask layer 28 comprises silicon nitride or a conductive material, such as titanium nitride. The thickness of the hard mask layer 28 may be in a range from 100 nm to 300 nm, although lesser and greater thicknesses may also be employed.

In an alternative embodiment, the semiconductor devices 720, the lower-level metal interconnect structures 780, and the lower-level dielectric material layers 760 may be located next to the alternating stack (32, 42) over the substrate 8 rather than underneath the alternating stack (32, 42). In yet another alternative embodiment, the semiconductor devices 720, the lower-level metal interconnect structures 780, and the lower-level dielectric material layers 760 may be omitted and not formed over the substrate 8. Instead, the semiconductor devices 720 of the peripheral (i.e., driver) circuit may be formed over a separate substrate and then bonded over the three-dimensional memory device. Optionally, the semiconductor material layer 110 may also be omitted in case the substrate 8 is later removed and a top source contact layer is formed on an exposed surface of the memory device, or it may be modified to function as part of a lateral source contact (e.g., direct strap contact) which is subsequently formed under the alternating stack.

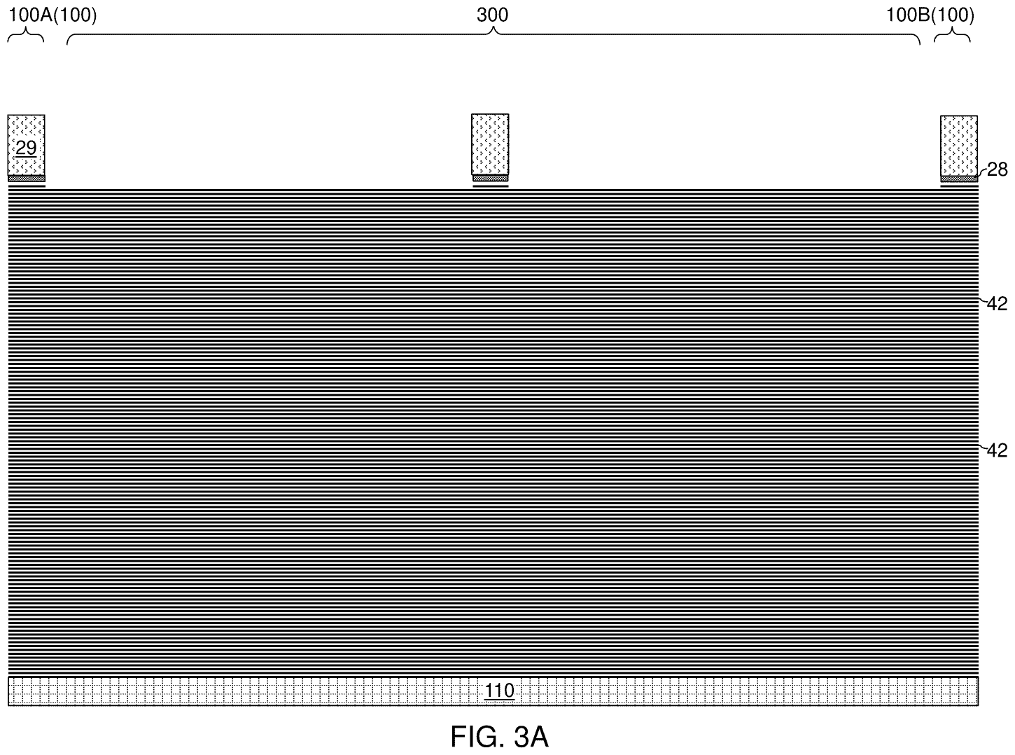

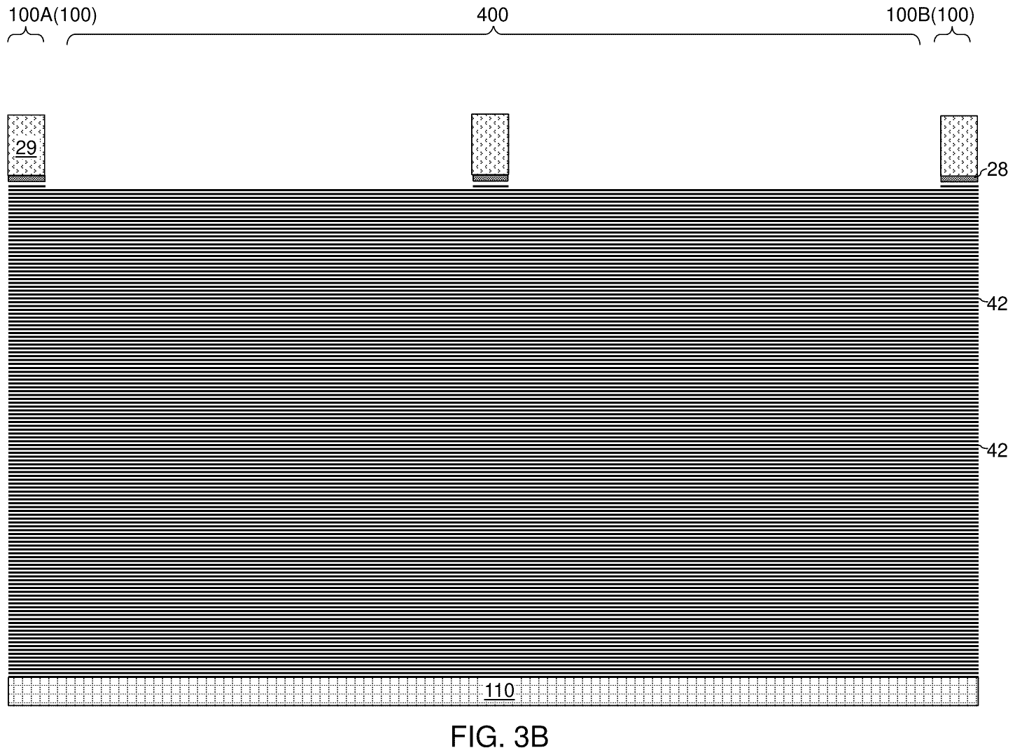

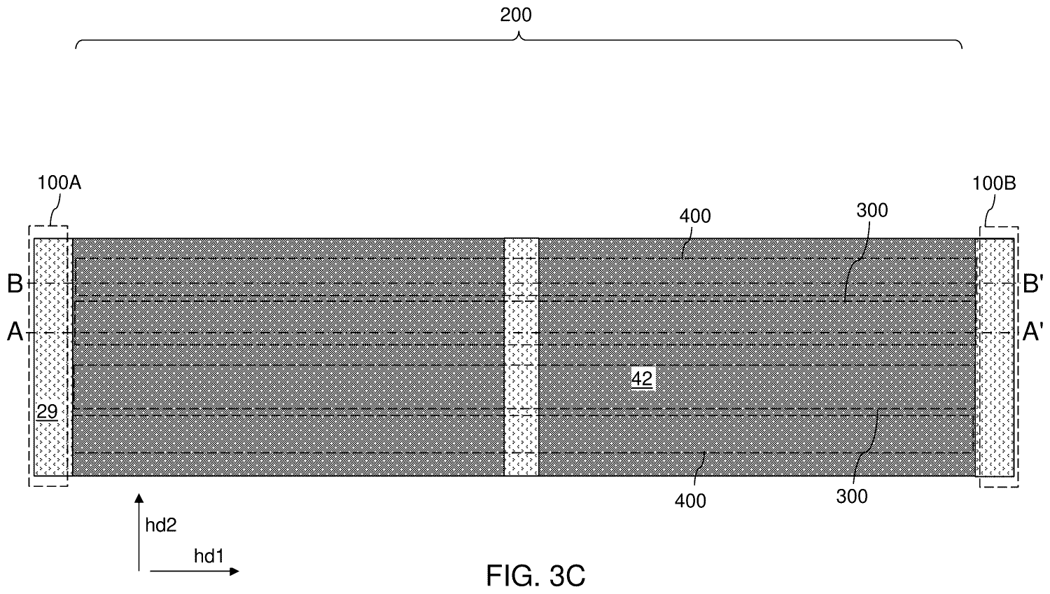

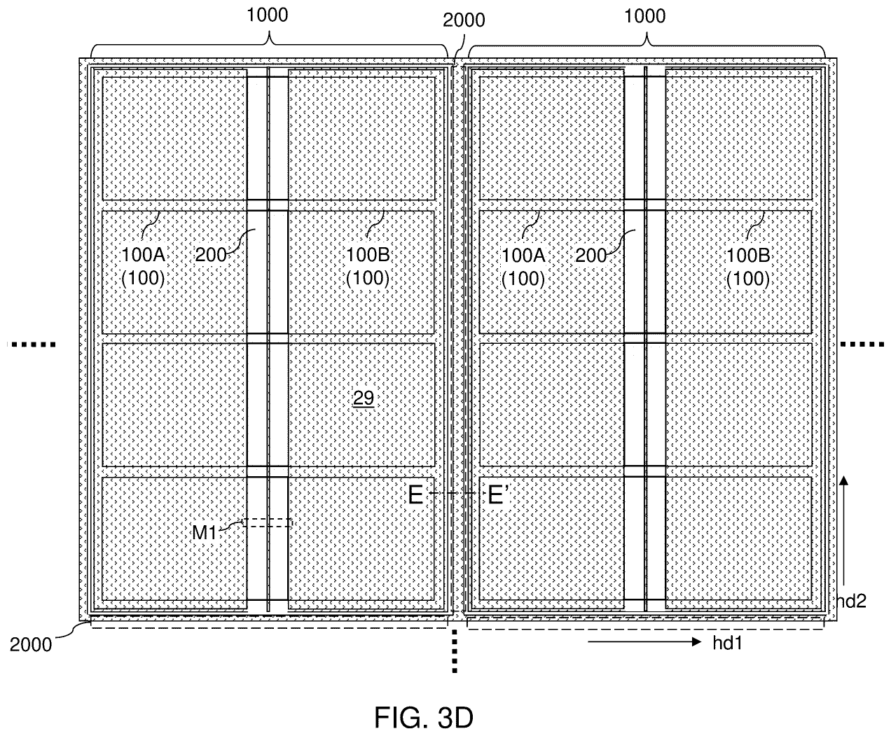

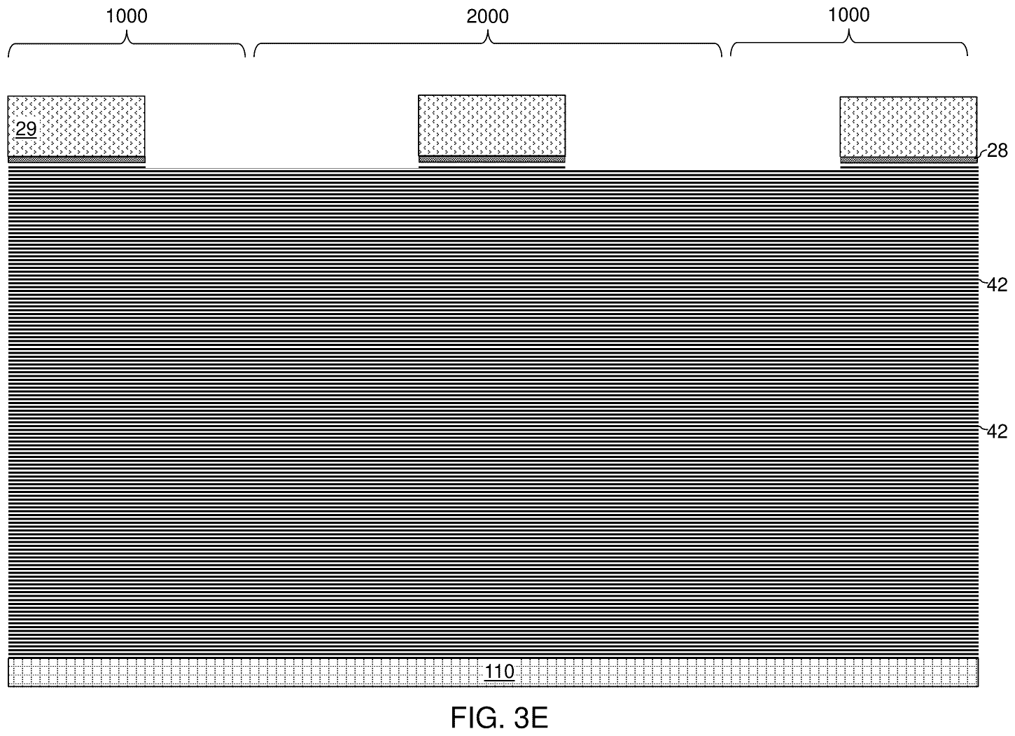

Referring to FIGS. 3A-3E, the exemplary structure is illustrated after formation of a patterned first photoresist layer 29. It is noted that insulating layers 32 are not shown for the purpose of clarity in FIGS. 3A, 3B, and 3E and in subsequent drawings showing similar views. Unless expressly described otherwise, anisotropic etch processes that pattern the sacrificial material layers 42 can terminate on a top surface of a respective one of the insulating layers 32 in subsequent processing steps. Thus, the sidewalls of the insulating layers 32 can be vertically coincident with (i.e., located within same vertical planes as) sidewalls of immediately underlying insulating layer 32, and bottom surfaces of any recessed region may include physically exposed top surface segments of an immediately underlying insulating layer 32 in the drawings of the present disclosure.

The lateral dimension of the illustrated area in FIG. 3C corresponds to the periodicity of patterned structures to be subsequently formed within a plane (100A, 200, 100B) in a semiconductor die 1000. In other words, the lateral dimension of the illustrated area in FIG. 3C equals the width of a repetition unit along the second horizontal direction hd2 within a memory plane (100A, 200, 100B). Each repetition unit may include a pair of contact regions 300 and a pair of connection regions 400, which can be located entirely within an inter-array region 200. Each contact region 300 is a region in which staircase structures and layer contact via structures are to be subsequently formed. Each connection region 400 is a region in which a predominant fraction (e.g., greater than 50%, such as greater than 80%, but less than 100%, such as 90 to 99% for example) of electrically conductive layers to be subsequently formed provides electrical connection between a first memory array region 100A and a second memory array region 100B.

The first photoresist layer 29 can be applied over the hard mask layer 28, and can be lithographically patterned to form openings within the inter-array regions 200 and in the kerf regions 2000. The openings in the hard mask layer 28 in the inter-array region 200 are formed in areas in which retro-stepped dielectric material portions are to be subsequently formed. The openings in the hard mask layer 28 in the kerf regions 2000 are formed in areas in which dielectric moat structures are to be subsequently formed.

In one embodiment, the areas of the openings in the hard mask layer 28 may occupy an entirety or a predominant fraction of the area of the inter-array regions 200. In the illustrated example of FIGS. 3A-3E, the openings in the hard mask layer 28 includes a predominant fraction of the area of the inter-array regions 200 that excludes central strip areas that laterally extend along the second horizontal direction hd2 (e.g., bit line direction). In this case, the ratio of the area of the openings in the hard mask layer 28 in the inter-array region 200 to the total area of the inter-array region 200 may be in a range from 0.90 to 0.99, although lesser and greater ratios may also be employed. In one embodiment, a strip-shaped portion of the first photoresist layer 29 may laterally extend along the second horizontal direction hd2 over a plurality of inter-array regions 200.

The openings in the hard mask layer 28 within the kerf regions 2000 can be configured to laterally surround a respective semiconductor die 1000, as shown in FIG. 3E. In this case, each opening in the hard mask layer 28 in the kerf regions 2000 may have a shape of a rectangular frame. Neighboring pairs of rectangular frame-shaped openings in the hard mask layer 28 can be laterally spaced from each other by a respective strip portion of the first photoresist layer 29. The strip portions of the first photoresist layer 29 in the kerf regions 2000 can be located between neighboring pairs of frame-shaped openings in the first photoresist layer 29.

An anisotropic etch process can be performed to etch through unmasked portions of the hard mask layer 28, the topmost insulating layer 32T, and a topmost one of the sacrificial material layers 42 within the alternating stack (32, 42). Recess regions are formed in the areas that are not covered by the patterned first photoresist layer 29. A top surface segment of an insulating layer 32, which is a second insulating layer 32 within the alternating stack (32, 42) as counted downward from top, can be physically exposed at the bottom of each recess region after the anisotropic etch process. The patterned first photoresist layer 29 can be removed, for example, by ashing.

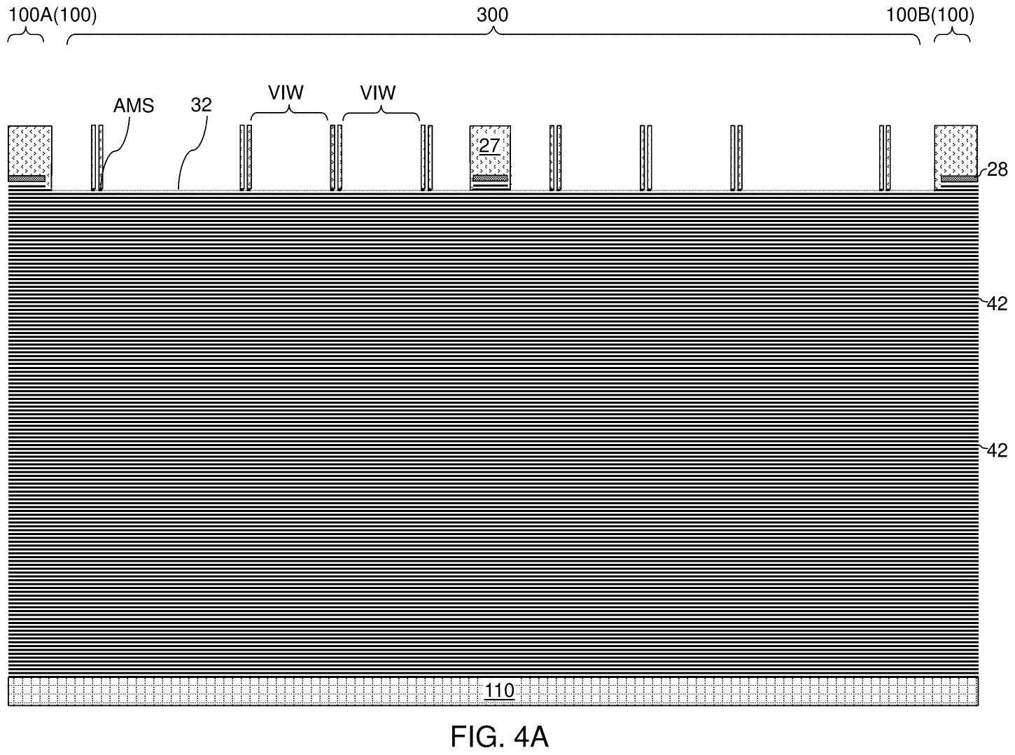

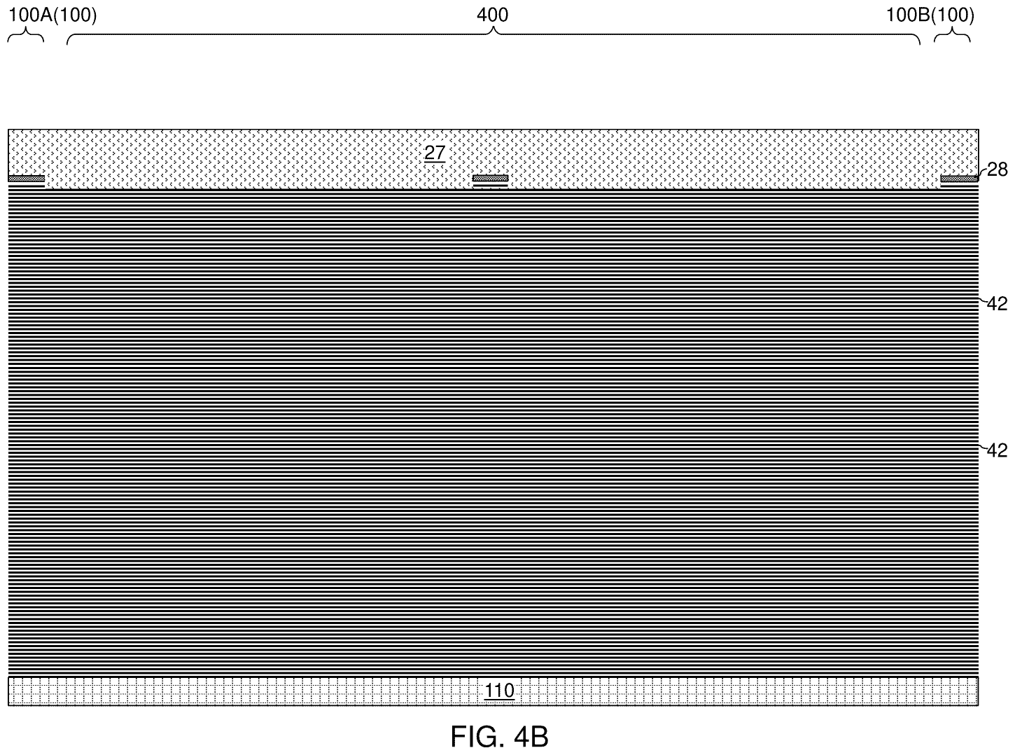

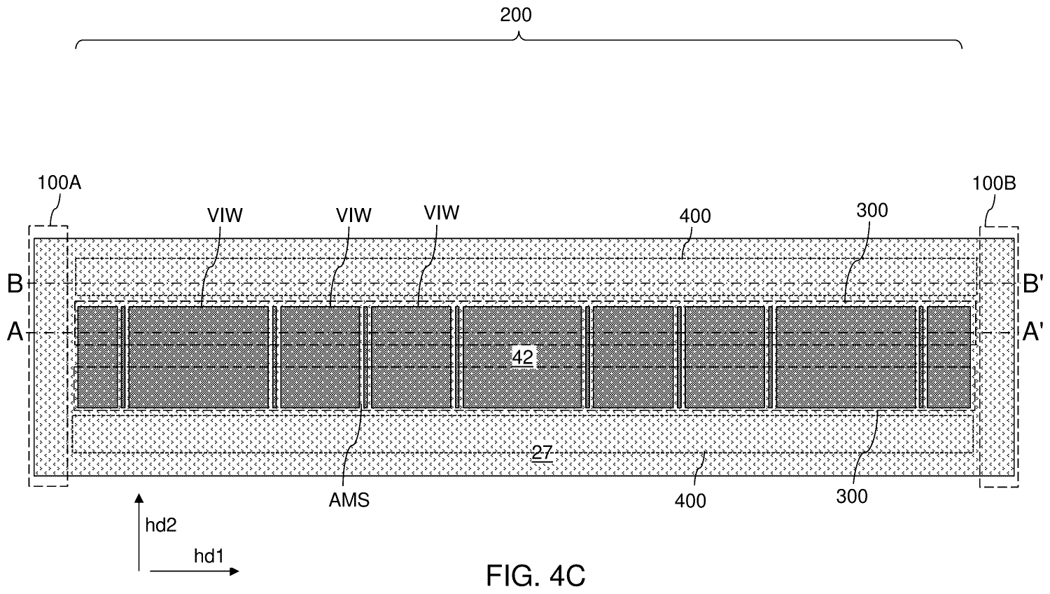

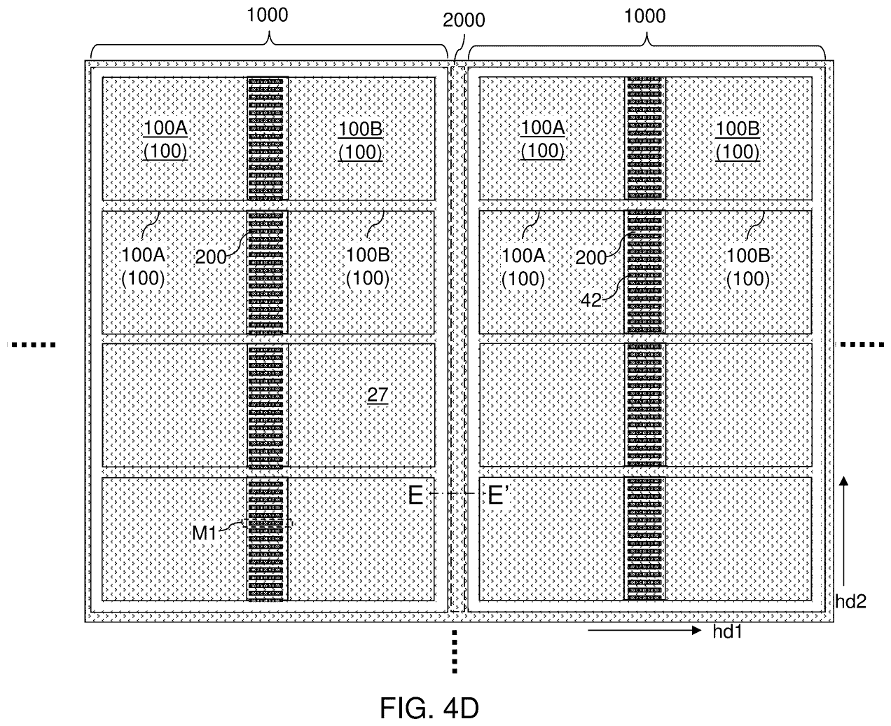

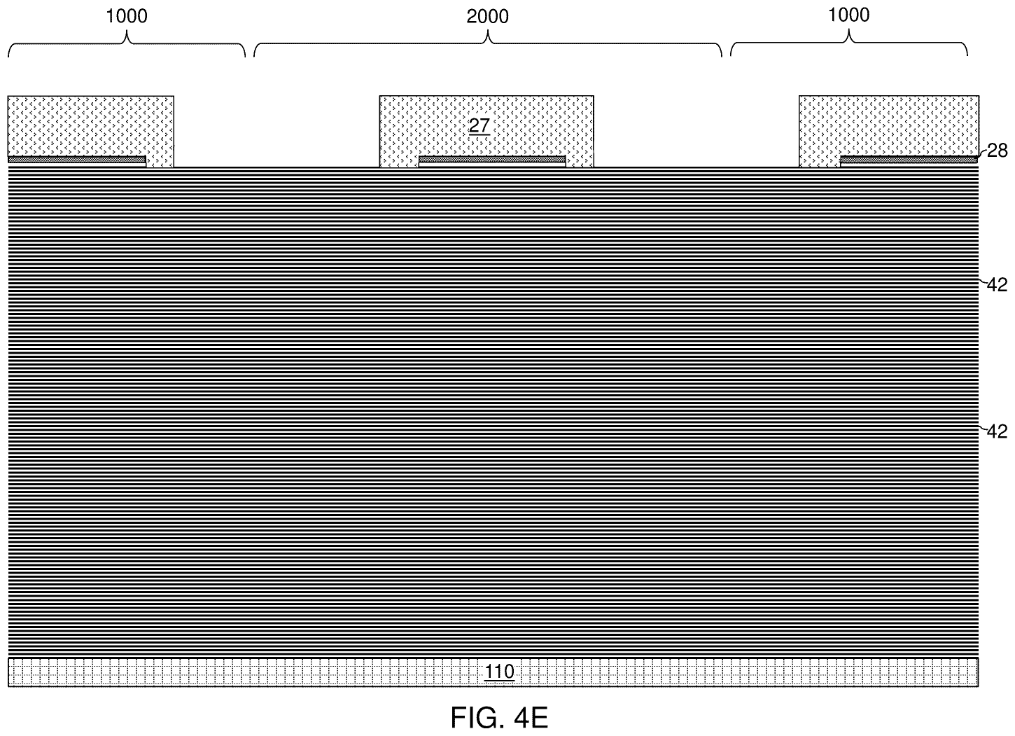

Referring to FIGS. 4A-4E, a second photoresist layer 27 can be applied over the exemplary structure, and can be lithographically patterned to form openings in the inter-array regions 200 without any opening in the memory array regions 100 or in the kerf regions 2000. In one embodiment, the openings in the second photoresist layer 27 can be formed entirely within the areas of the contact regions 300, while no opening in the second photoresist layer 27 is formed within the areas of the connection regions 400 or the memory array regions 100.

In one embodiment, the openings in the second photoresist layer 27 may be arranged as rows of rectangular openings arranged along the first horizontal direction hd1 (e.g., word line direction). Each row of rectangular openings in the second photoresist layer 27 may laterally extend between a neighboring pair of memory array regions (100A, 100B), and may be formed within the areas of a neighboring pair of contact regions 300 that are located between a pair of connection regions 400, as shown in FIG. 4C. Each row of rectangular openings may comprise a plurality of rectangular openings having a same width along the second horizontal direction hd2, and having different lengths along the first horizontal direction hd1. In one embodiment, each row of rectangular openings may comprise primary rectangular openings and supplementary rectangular openings that are interlaced along the first horizontal direction hd1. The primary rectangular openings may have a length-to-width ratio in a range from 0.5 to 10, although lesser and greater length-to-width ratios may also be employed. The supplementary rectangular openings may have a length-to-width ratio in a range from 0.001 to 0.1, such as from 0.002 to 0.05, although lesser and greater length-to-width ratios may also be employed.

An anisotropic etch process can be performed to transfer the pattern of the openings in the second photoresist layer 27 through a pair of and insulating layer 32 and a sacrificial material layer 42, which includes a second insulating layer 32 as counted downward from top within the alternating stack (32, 42) and a second sacrificial material layer 42 as counted downward from top within the alternating stack (32, 42). The pattern of the rectangular openings in the patterned second photoresist layer 27 can be transferred through the pair of insulating layer 32 and the sacrificial material layer 42 to form vertical indentation wells VIW. Each of the vertical indentation wells VIW is a well having a configuration of a rectangular vertical indentation relative to an unrecessed portion of the second insulating layer 32 as counted downward from top within the alternating stack (32, 42).

In one embodiment, a first subset of the vertical indentation wells VIW that underlies a first subset of the primary rectangular openings in the patterned second photoresist layer 27 has a first length along the first horizontal direction hd1, and a second subset of the vertical indentation wells VIW that underlies as second subset of the primary rectangular openings in the patterned second photoresist layer 27 has a second length along the first horizontal direction hd1. The second length can be greater than the first length. A third subset of the vertical indentation wells VIW that underlies the supplementary rectangular openings in the patterned second photoresist layer 27 has a third length along the first horizontal direction hd1, which may be less than 0.1 times the width of each of the vertical indentation wells VIW along the second horizontal direction.

In one embodiment, at least one strip portion (e.g., a pair of strip portions) of the second photoresist layer 27 can be provided between a neighboring pair of primary rectangular openings in the second photoresist layer 27. In this case, a pair of strip-shaped portions of the second insulating layer 32 as counted downward from top within the alternating stack (32, 42) and the second sacrificial material layer 42 as counted downward from top within the alternating stack (32, 42) may be present around each third subset of the vertical indentation wells VIW. Each pair of strip-shaped remaining portions of the second insulating layer 32 as counted downward from top within the alternating stack (32, 42) and the second sacrificial material layer 42 as counted downward from top within the alternating stack (32, 42) can be subsequently used as a reference structure (e.g., a “scale” or alignment mark) for measuring trimming distances of trimmable photoresist material portions, and is herein referred to as alignment mark strips AMS. The alignment mark strips AMS may be subsequently employed as reference structures during measurement of trimming distances during trimming of trimmable photoresist material portions.

Thus, an array of vertical indentation wells VIW that are arranged along the first horizontal direction hd1 can be patterned in upper portion of the alternating stack (32, 42) in a contact region 300 without patterning the alternating stack (32, 42) in a connection region 400. In other words, the connection regions 400 can be free of any vertical indentation wells VIW and the alignment mark strips AMS. As a result, a vertical step which laterally extends along the first horizontal direction hd1 can be formed formed between each of the vertical indentation wells VIW and an adjoining portion of the alternating stack (32, 46) located in a connection region 400. Thus, patterned structures that are formed during the processing steps of FIGS. 4A-4E can be formed entirely within the areas of the contact regions 300. The entirety of the memory array regions 100 and the connection regions 400 can be covered by the second photoresist layer 27. The second photoresist layer 27 can be subsequently removed, for example, by ashing.

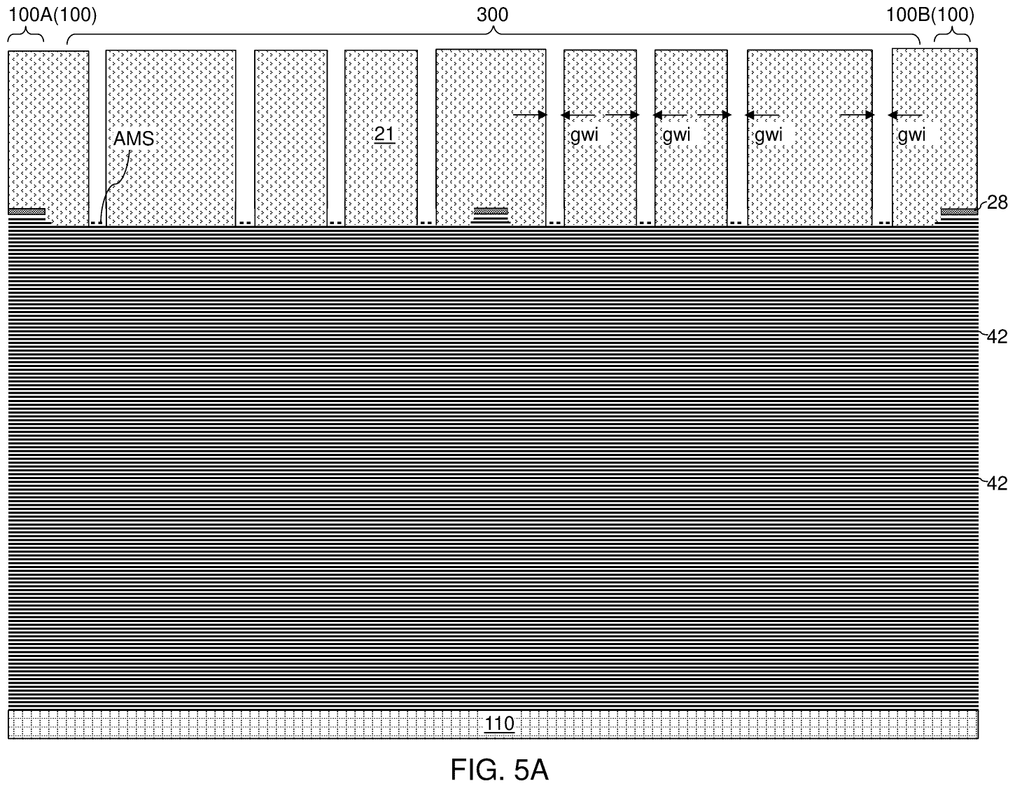

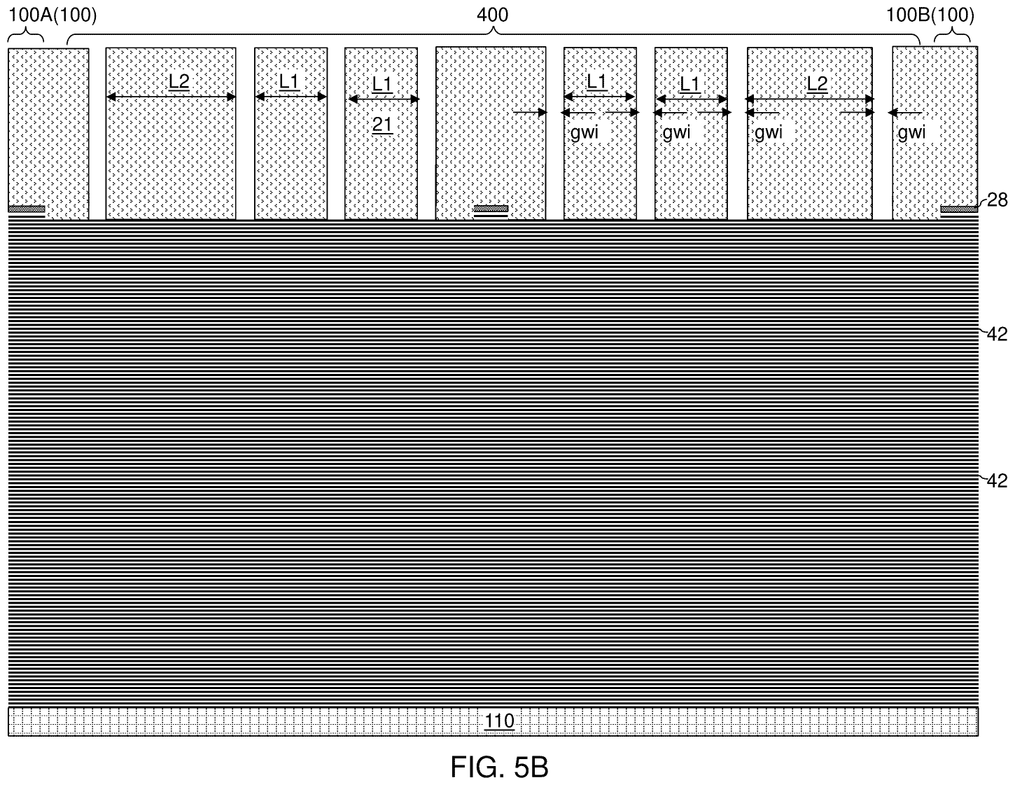

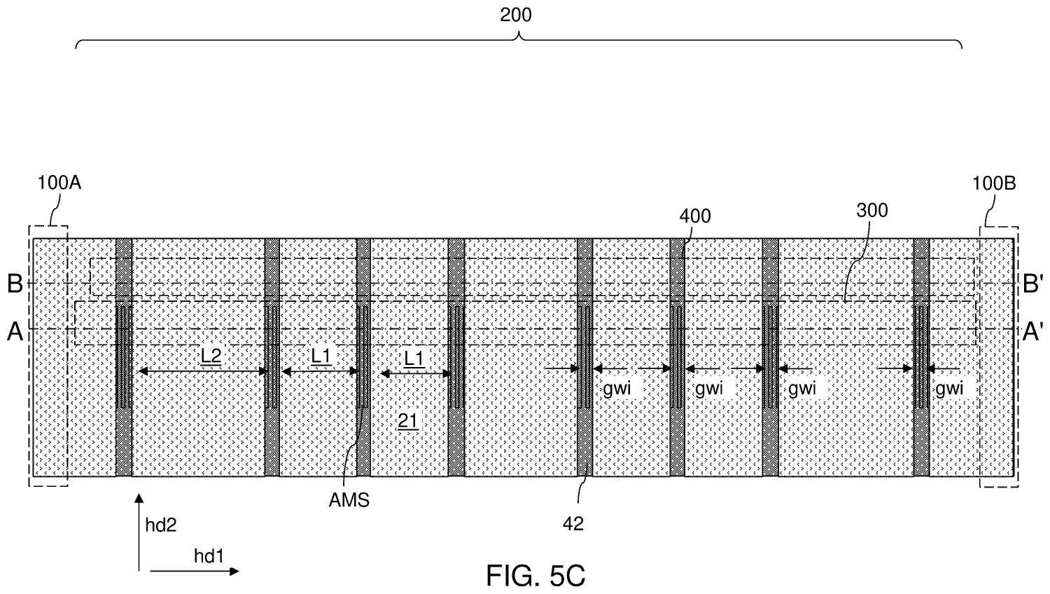

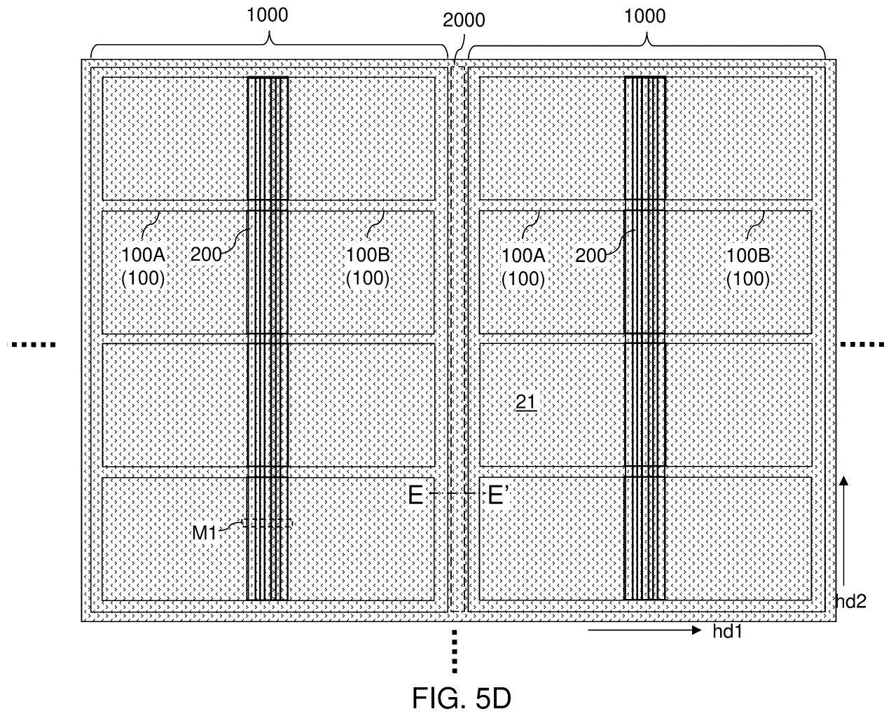

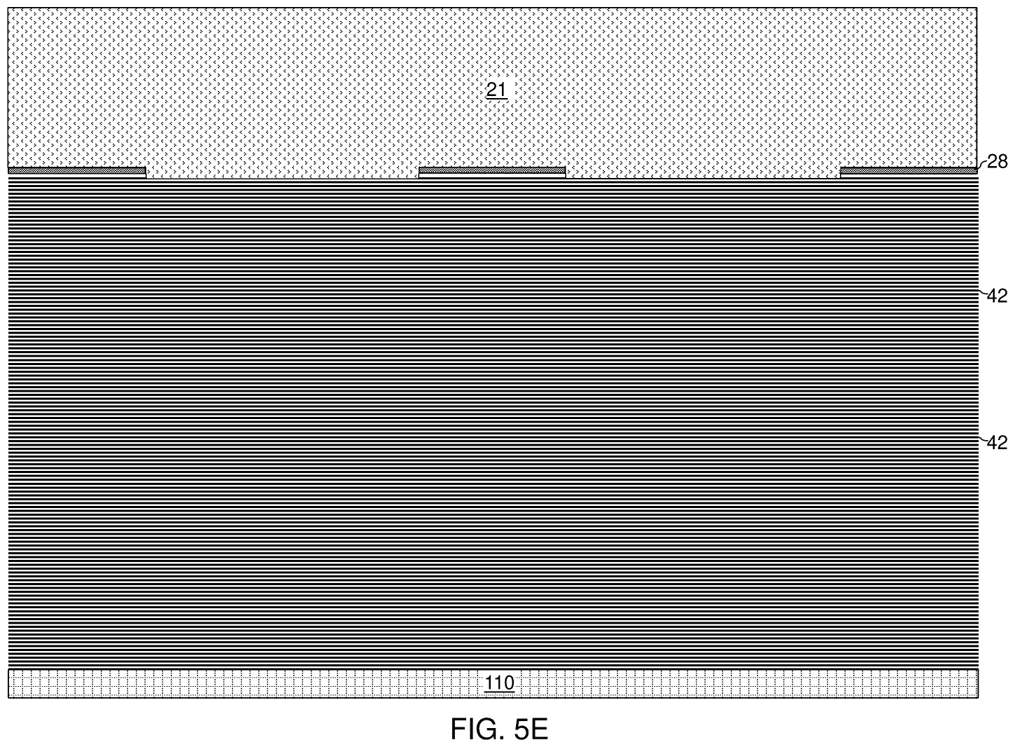

Referring to FIGS. 5A-5E, a trimmable photoresist material can be applied over the exemplary structure, and can be lithographically patterned to form patterned trimmable photoresist material portions 21. A trimmable photoresist material refers to a photoresist material that may be trimmed at a controlled trim rate under a suitable oxidation condition, such as an ashing condition at a relatively low temperature in a range from 100 degrees Celsius to 200 degrees Celsius. In one embodiment, the patterned trimmable photoresist material portions 21 may cover the entirety of the memory array regions 100 and the kerf regions 2000, and may have straight edges that laterally extend through inter-array regions 200 within the area of a respective semiconductor die 1000.

In one embodiment, each neighboring pair of trimmable photoresist material portions 21 of the trimmable photoresist material portions 21 overlying a respective semiconductor die 1000 may be laterally spaced from each other along the first horizontal direction hd1 by a respective gap having a same initial gap width gwi that is invariant along the second horizontal direction hd2. In one embodiment, the locations of the gaps between each neighboring pair of trimmable photoresist material portions 21 can be selected such that a pair of alignment mark strips AMS is located entirely within the area of an overlying gap.

The uniform value of the initial gap width gwi for each gap between the trimmable photoresist material portions 21 provides the advantage of generating uniform photoresist trimming distance in subsequent photoresist trimming processes. Specifically, the trimming of the trimming photoresist material portions 21 employs a process condition in which an insufficient supply of an oxidant gas (such as oxygen) is supplied during trimming. In this case, differences in the dimensions of the gaps between neighboring pairs of trimmable photoresist material portions 21 can induce differences in the trimming distances for the trimmable photoresist material portions 21. According to one embodiment, use of the same value for the initial gap width gwi for each gap of the trimmable photoresist material portions 21 provides uniform trimming distance at each gap between neighboring pairs of trimmable photoresist material portions 21.

In one embodiment shown in FIG. 5B, first trimmable photoresist material portions 21 have a first length L1 along the first horizontal direction hd1, and at least one second trimmable photoresist material portion 21 has a second length L2 along the first horizontal direction hd1 that is greater than the first length L1. Thus, trimmable photoresist material portions 21 having different lengths along the first horizontal direction hd1 may be formed such that each neighboring pair of the trimmable photoresist material portions 21 is laterally spaced from each other by the uniform initial gap width gwi, and such that a pair of alignment mark strips AMS is located entirely within the area of an overlying gap within each contact region 300. In one embodiment, straight edges of the trimmable photoresist material portions 21 may laterally extend along the second horizontal direction hd2 through a plurality of contact regions 300 and a plurality of connection regions 400. In one embodiment, straight edges of the trimmable photoresist material portions 21 may laterally extend along the second horizontal direction hd2 through each contact region 300 and each connection region 400 in a semiconductor die 1000.

In one embodiment, the total number of gaps overlying each contact region 300 may be in a range from 2 to 12, and/or may be in a range from 4 to 10, and/or may be in a range from 6 to 9, although lesser and greater numbers of gaps may also be employed. In one embodiment, the initial gap width gwi may be in a range from 0.5 microns to 6 microns, such as from 1 micron to 3 microns, although lesser and greater dimensions may also be employed.

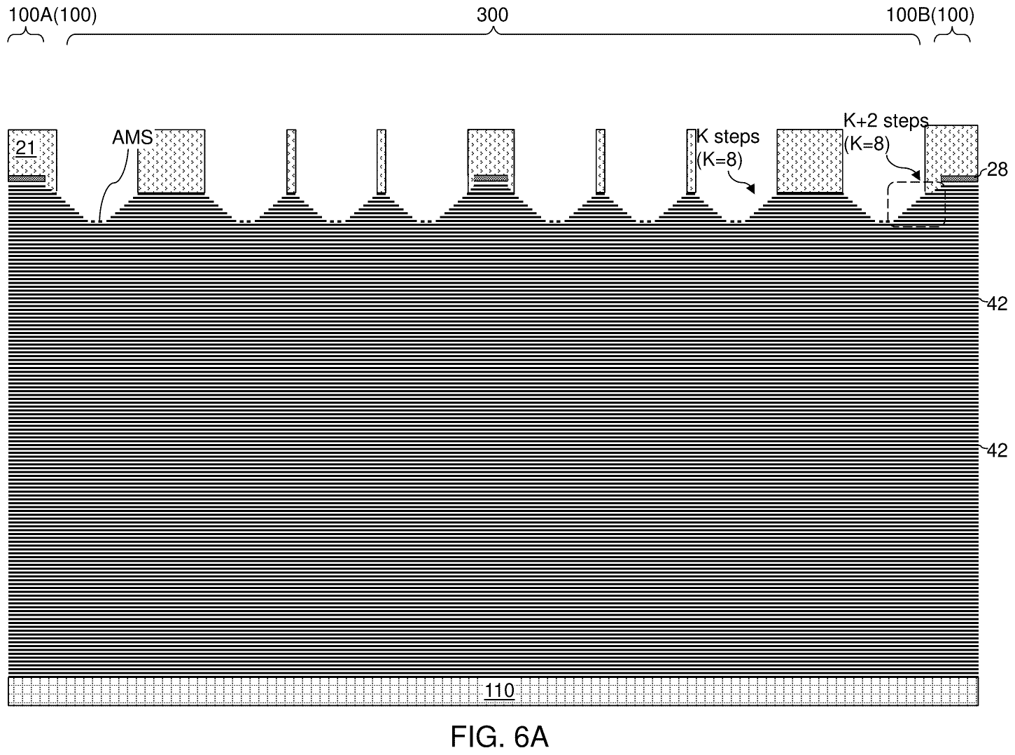

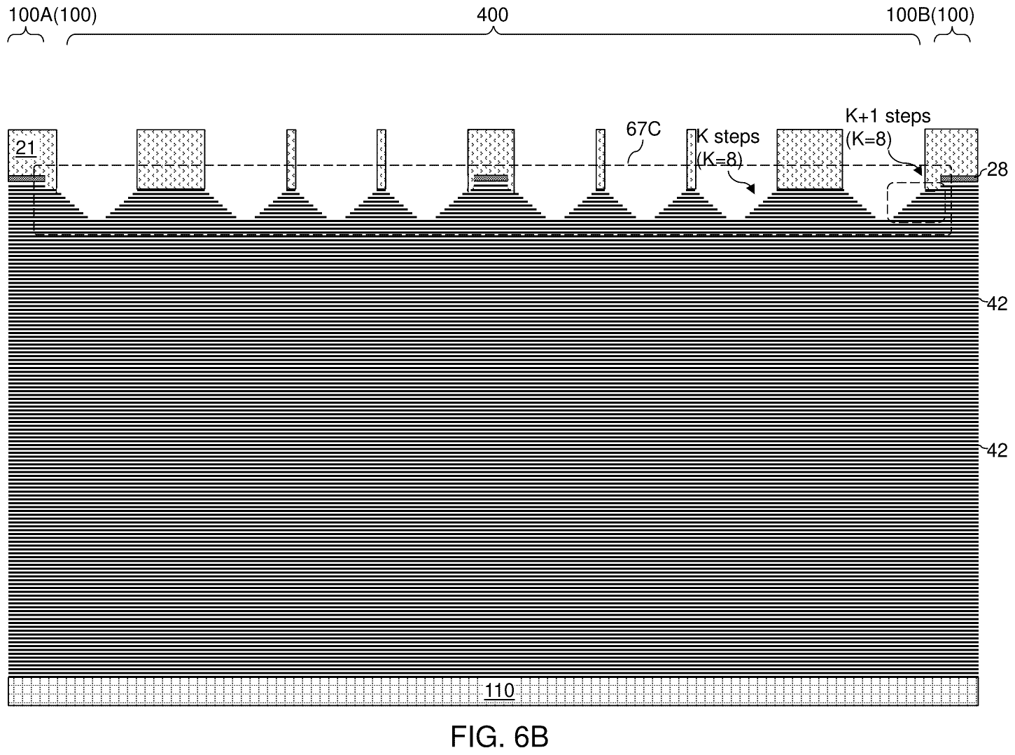

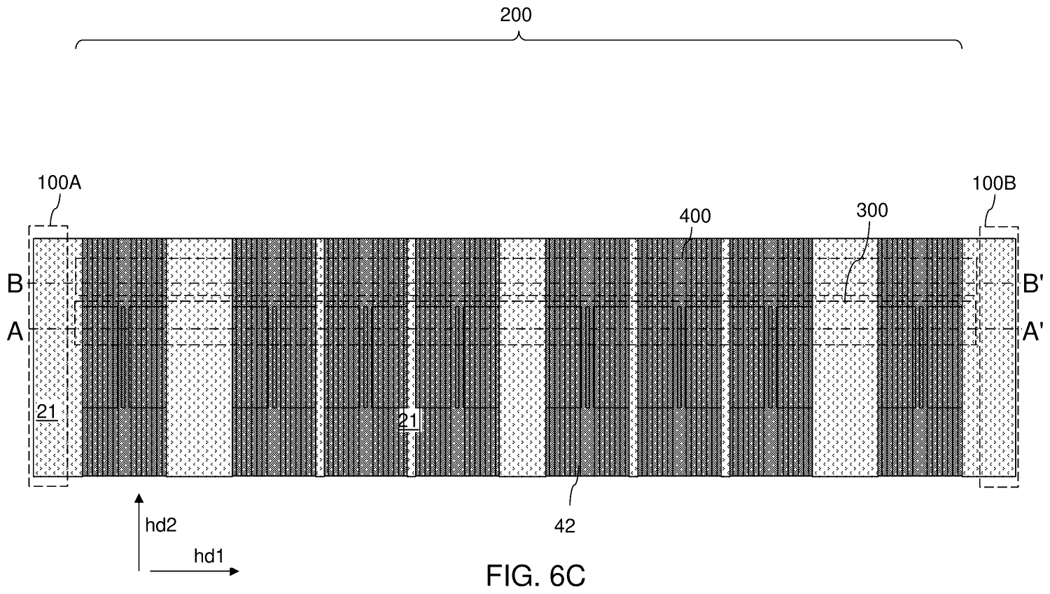

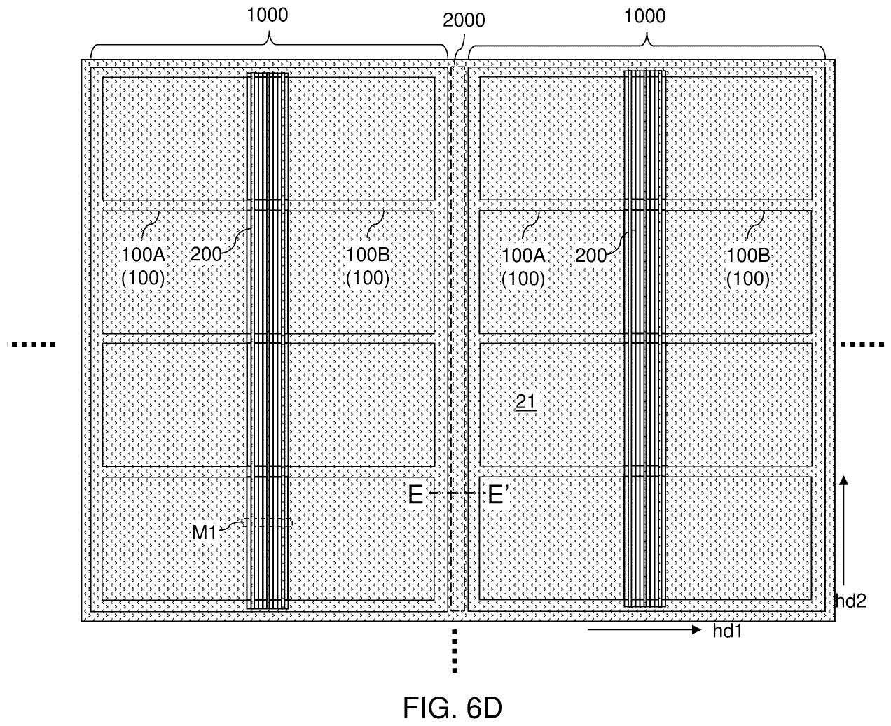

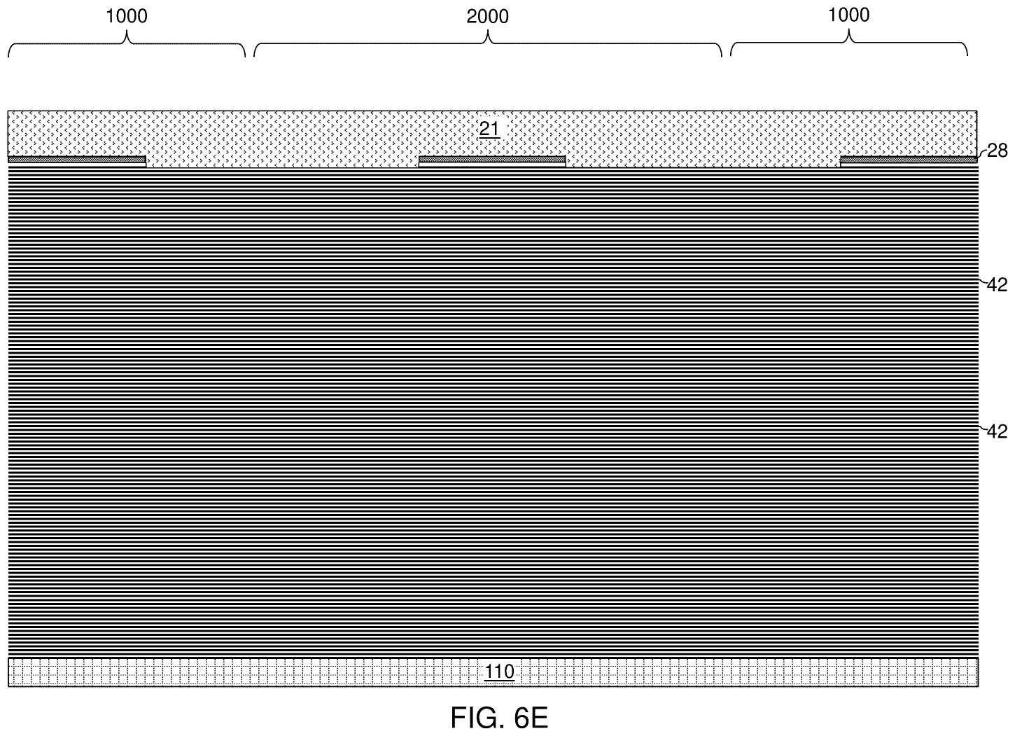

Referring to FIGS. 6A-6E, a set of processing steps that include K anisotropic etch processes interlaced with (K−1) photoresist trimming processes can be performed. K is an integer greater than 2. In one embodiment, the value of the integer K may be in a range from 3 to 16, such as from 4 to 12, although lesser and greater values may also be employed. In one embodiment, a combination of processing steps including an anisotropic etch step and a photoresist trimming step may be repeated (K−1) times, and a terminal anisotropic etch process may be subsequently performed to provide the K anisotropic etch processes and the (K−1) photoresist trimming processes.

In one embodiment, each anisotropic etch process of the K anisotropic etch process may have a first anisotropic etch step that etches the and a second anisotropic etch step that etches the material of the sacrificial material layers 42 within the alternating stack (32, 42) selective to the material of the insulating layers 32 within the alternating stack (32, 42). The duration of the first anisotropic etch step can be selected such that the first anisotropic etch step etches a single insulating layer 32 without significantly etching any underlying sacrificial material layer 42. The duration of the second anisotropic etch step can be selected such that the second anisotropic etch step etches a single sacrificial material layer 42 without significantly etching any underlying insulating layer 32. For example, the etch depth of each first anisotropic etch process for the material of the insulating layers 32 may be in a range from 100% to 150% of a thickness of an insulating layer 32, and the etch depth of each second anisotropic etch process for the material of the sacrificial material layers 42 may be in a range from 100% to 150% of a thickness of an sacrificial material layer 42.

In one embodiment, each photoresist trimming process of the (K−1) photoresist trimming processes may isotropically trim the trimmable photoresist material portions 21 by a trimming distance. The trimming distance may be in about a distance obtained by dividing the first length L1 by (2K). The K anisotropic etch processes and the (K−1) photoresist trimming processes form sets of connected surfaces. Each set of connected surfaces may comprise K physically-exposed horizontally-extending surface segments located at K different levels, K physically-exposed vertically-extending surface segments, and one horizontally-extending surface segment that is covered by a remaining trimmable photoresist material portion 21. Each set of connected surfaces including (K+1) horizontally-extending surface segments and K vertically-extending surface segments constitutes a staircase structure, or a portion of a staircase structure. As discussed above, use of the same value for the initial gap width gwi for each gap of the trimmable photoresist material portions 21 at the processing steps of FIGS. 5A-5E provides uniform trimming distance at each gap between neighboring pairs of trimmable photoresist material portions 21 during each photoresist trimming process.

The staircase structures comprise contact-region staircase structures that are formed in the contact regions 300, and connection-region staircase structures 67C that are formed in the connection regions 400. Each staircase structure comprises K vertically-extending surface segments. In one embodiment, each staircase structure located in a contact region 300 and laterally spaced from that are distal from the hard mask layer 28 by at least one alignment mark strip AMS may consist of K vertically-extending surface segments and (K+1) horizontally-extending surface segments. Such staircase structures are herein referred to as first-type contact-region staircase structures. Each staircase structure located in a contact region 300 and is more proximal to the hard mask layer 28 than any alignment mark strip AMS may include (K+2) vertically-extending surface segments (“K+2 steps”) and (K+3) horizontally-extending surface segments. Such staircase structures are herein referred to as second-type contact-region staircase structures. In one embodiment, each staircase structure located in a connection region 400 and laterally offset from a first-type contact-region staircase structure along the second horizontal direction hd2 may consist of K vertically-extending surface segments and (K+1) horizontally-extending surface segments. Such staircase structures are herein referred to as first-type connection-region staircase structures. Each staircase structure located in a connection region 400 and laterally offset from a second-type contact-region staircase structure along the second horizontal direction hd2 may include (K+1) vertically-extending surface segments and (K+2) horizontally-extending surface segments. Such staircase structures are herein referred to as second-type connection-region staircase structures. The trimmable photoresist material portions 21 can be subsequently removed, for example, by ashing.

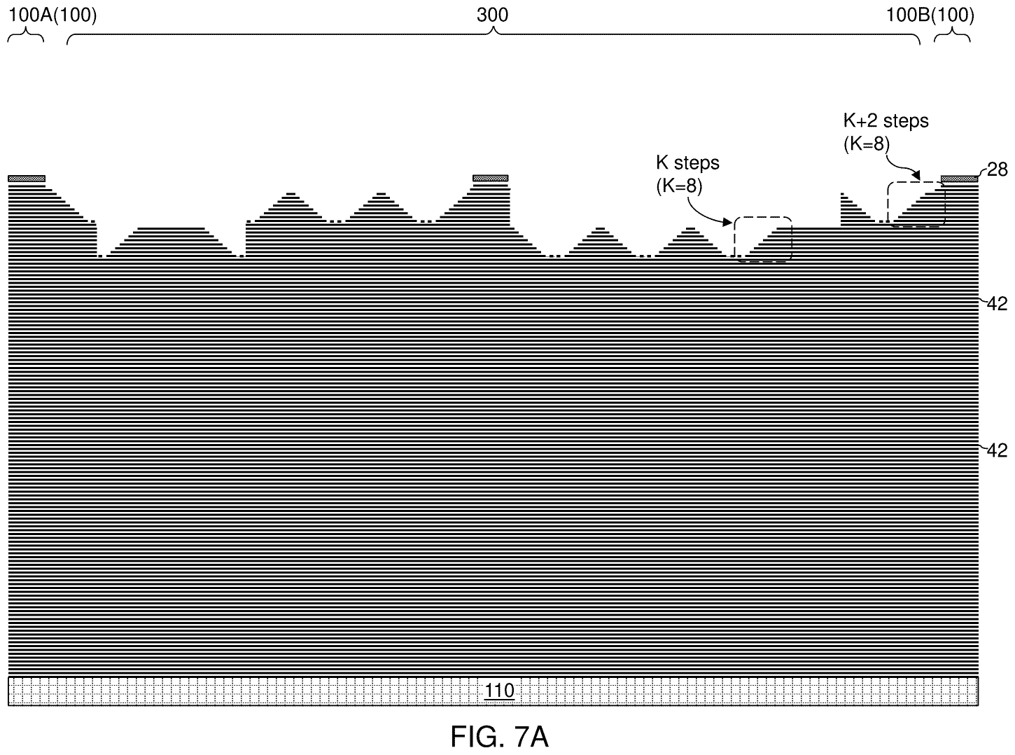

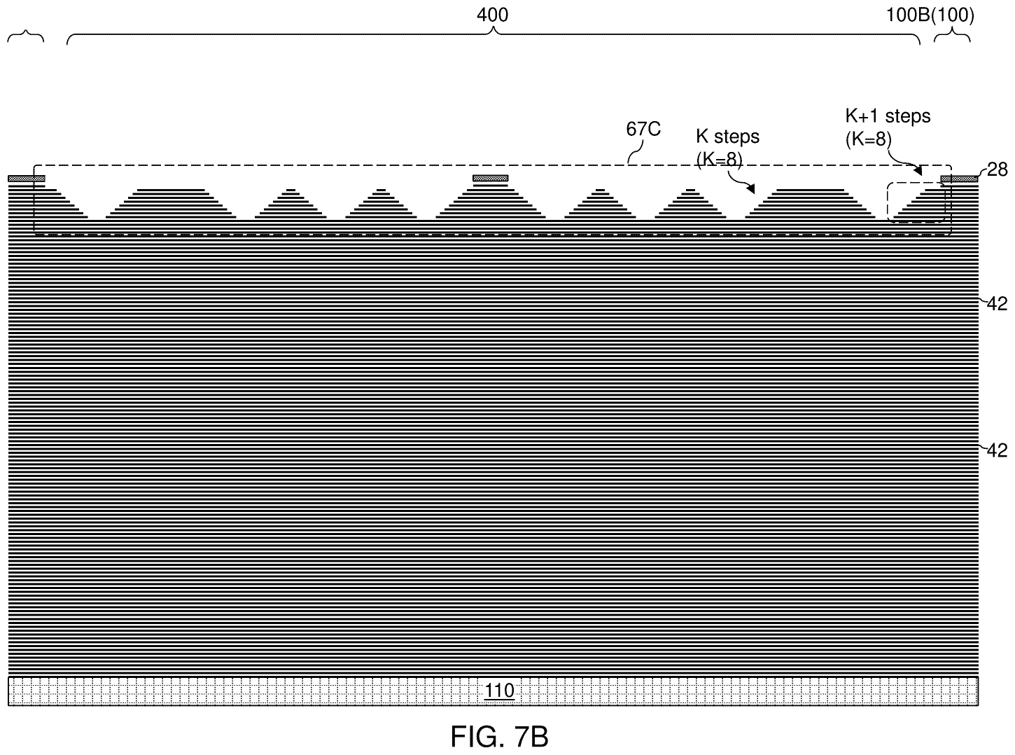

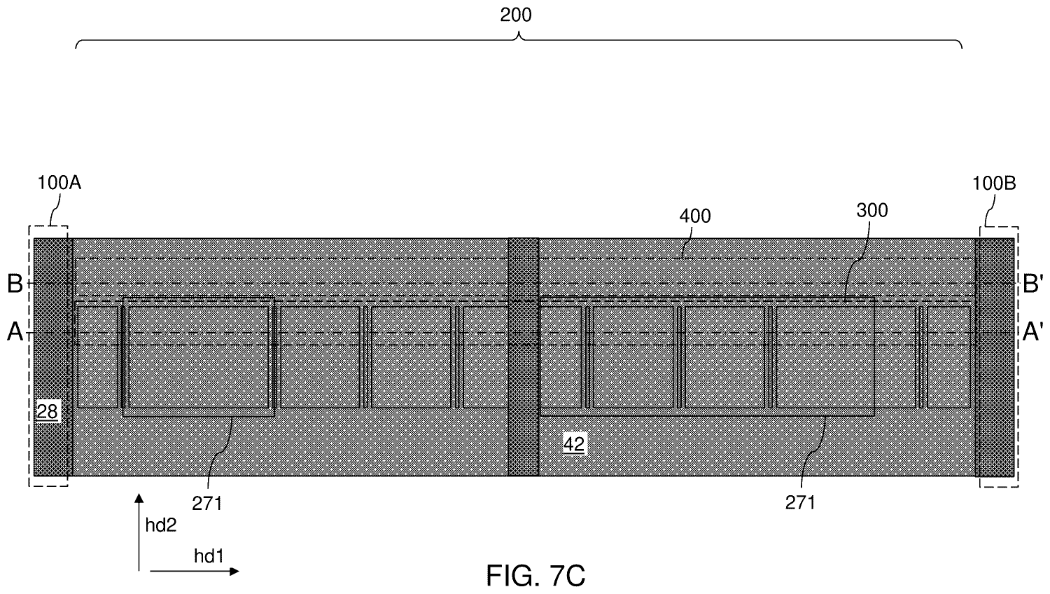

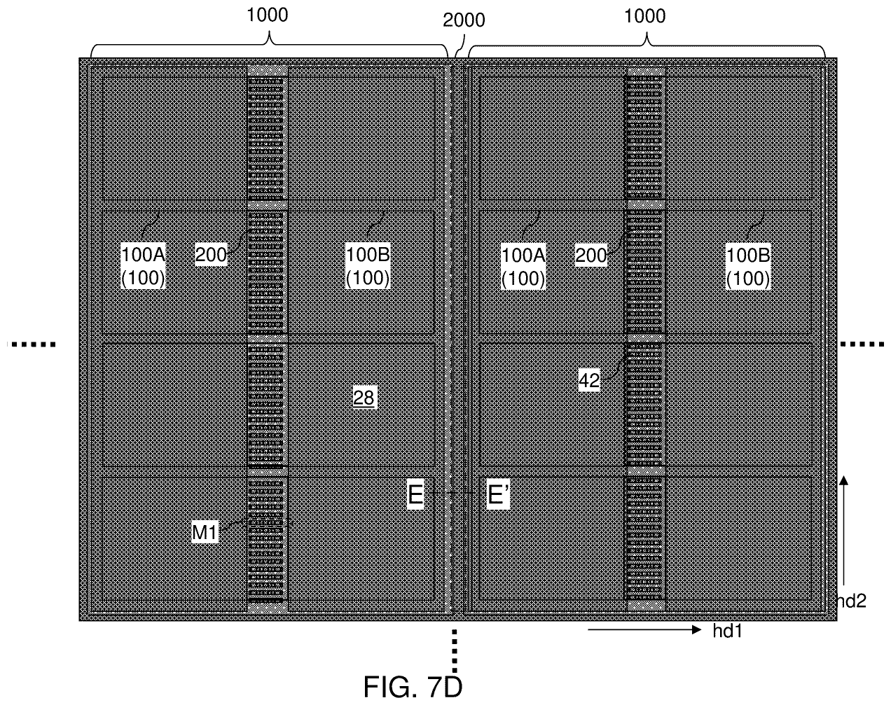

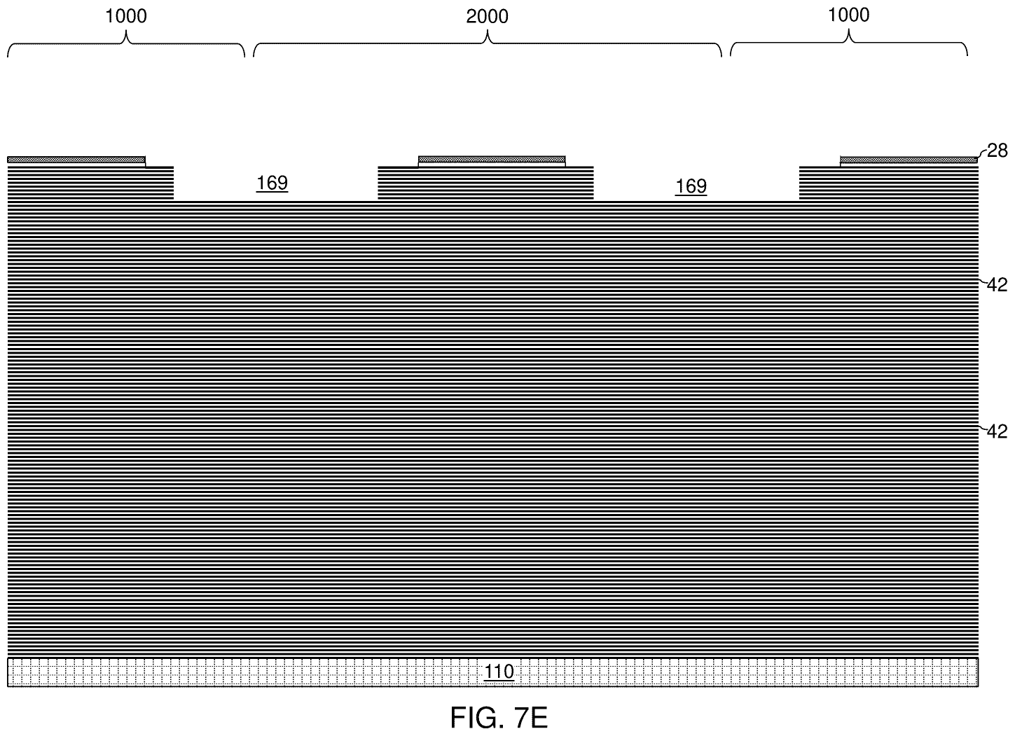

Referring to FIGS. 7A-7E, a first masked vertical recess process can be performed. Specifically, a first mask-level photoresist layer (not shown) can be applied over the exemplary structure, and can be lithographically patterned to cover all of the memory array regions 100, the connection regions 400, and a first primary subset of the contact-region staircase structures without covering a first complementary subset of the contact region staircase structures and without covering boundary regions around each periphery of the semiconductor dies 1000. In one embodiment, the first primary subset of the contact-region staircase structures may comprise about one half of all contact-region staircase structures, and the first complementary subset of the contact-region staircase structures may be a complementary subset of the first primary subset. In other words, the union of the first primary subset and the first complementary subset may include all of the contact-region staircase structures. Each boundary region may include an outer periphery of a semiconductor die 1000 and an adjacent portion of the kerf regions 2000 around the semiconductor die 1000. Each boundary region may have a respective frame shape in a top-down view, and may be located entirely within a frame-shaped opening in the hard mask layer 28. The pattern of the openings in the first mask-level photoresist layer defines a first mask opening pattern 271.

A first masked vertical recess process can be performed to vertically recess the unmasked portions of the alternating stack (32, 42) by a first vertical recess distance. The first masked vertical recess process may comprise an anisotropic etch process that etches (K+1) pairs of an insulating layers 32 and a sacrificial material layer 42. The anisotropic etch process may comprise a reactive ion etch process. Unmasked portions of the alternating stack (32, 42) can be vertically recessed by the first vertical recess distance, which may be (K+1) times the sum of a thickness of an insulating layer 32 and a thickness of a sacrificial material layer 42. The first complementary subset of the contact-region staircase structures can be vertically recessed by the first vertical recess distance, while the first primary subset of the contact-region staircase structures is not vertically recessed. A moat cavity 169 can be formed in each boundary region at the peripheries of the semiconductor dies 1000. The first mask-level photoresist layer can be subsequently removed, for example, by ashing.

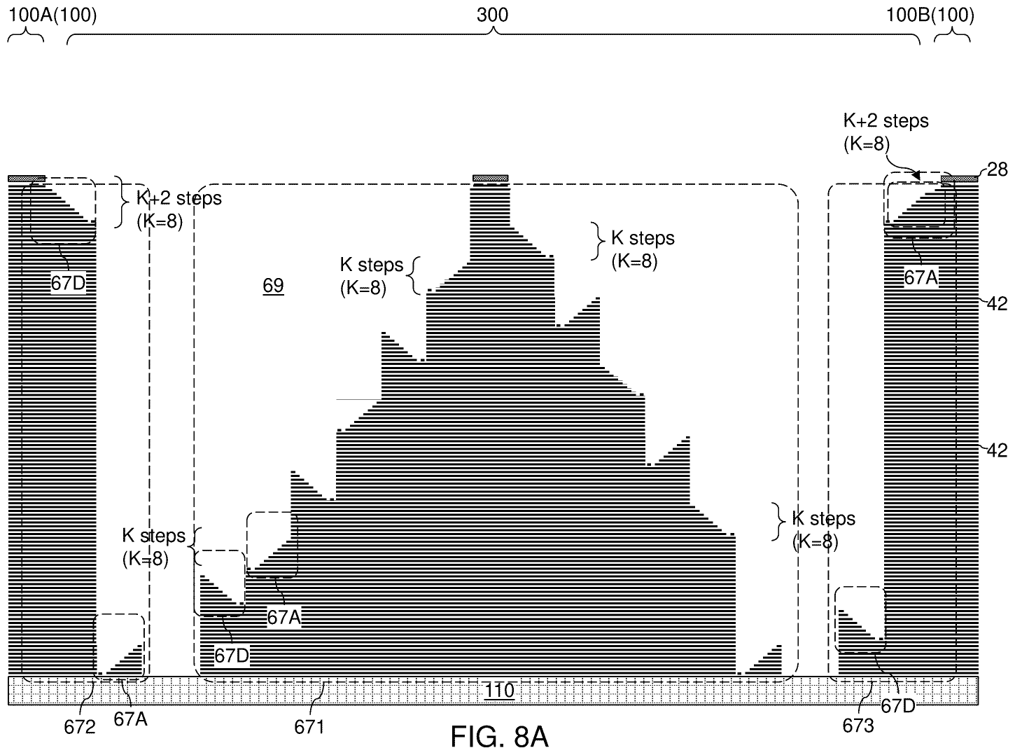

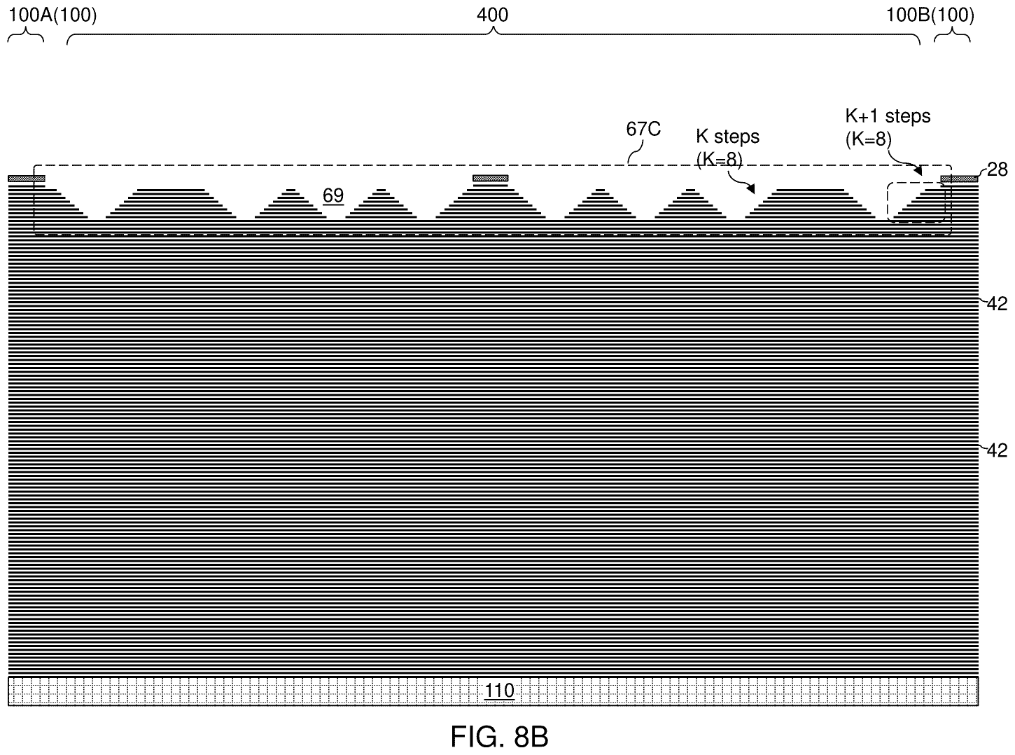

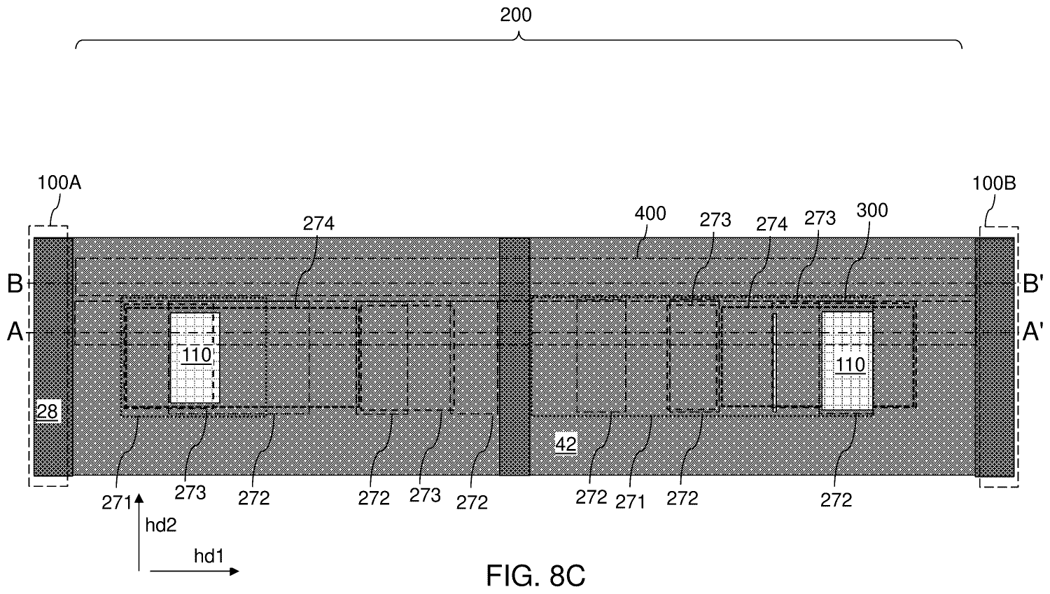

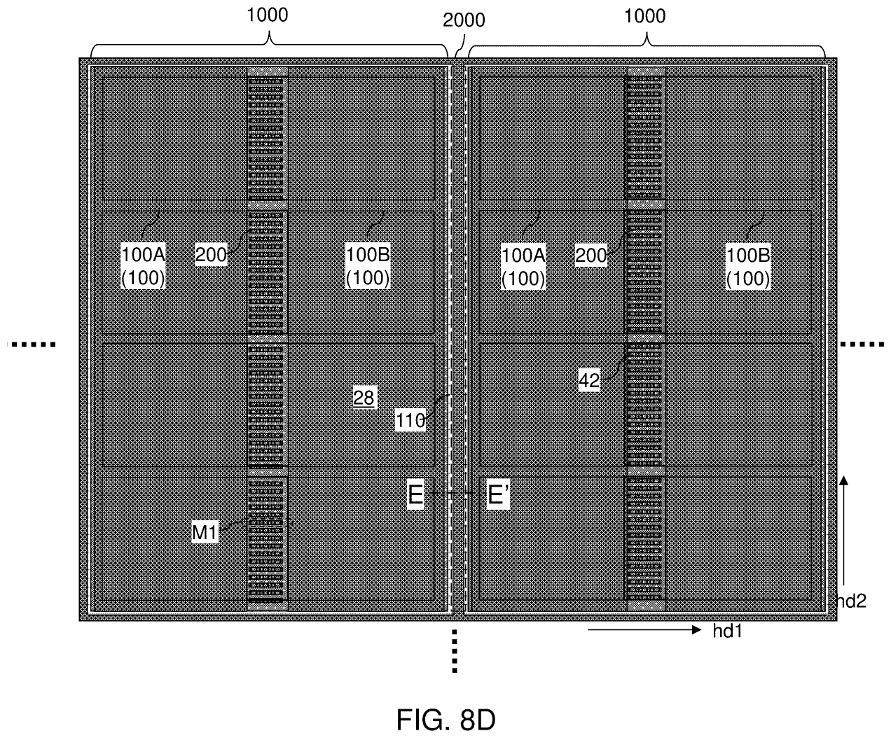

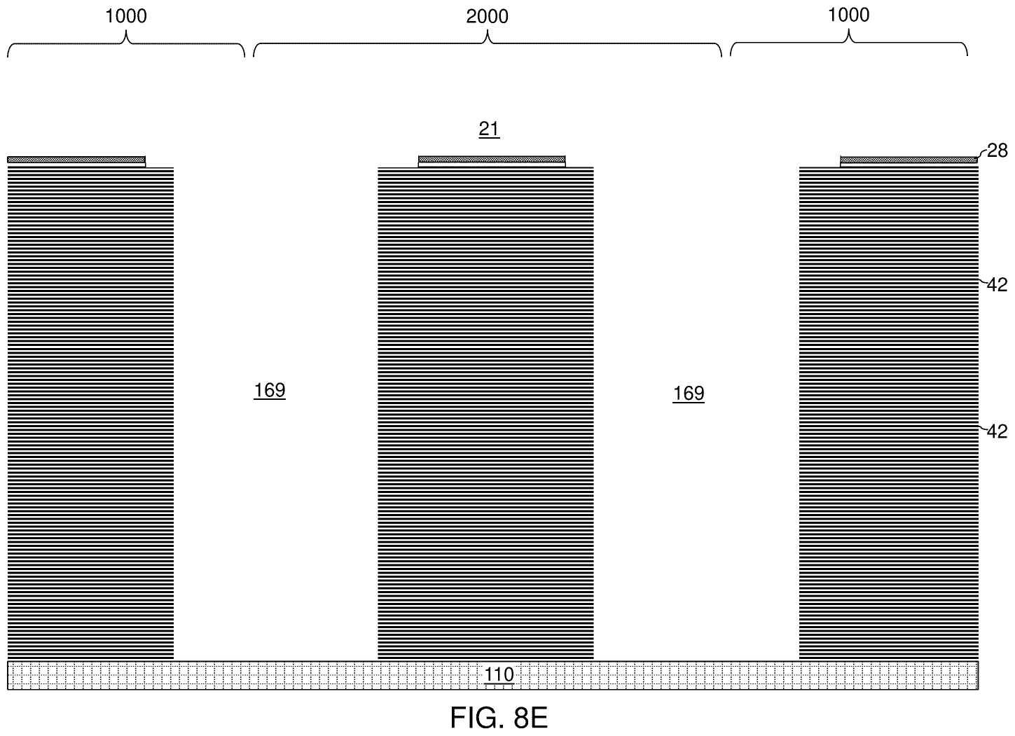

Referring to FIGS. 8A-8E, the set of processing steps described with reference to FIGS. 7A-7E can be repeated performed with changes in the pattern of the masked areas and with changes in the vertical recess distance (i.e., the etch depth) of the vertical recess processed. The total number of iterations of the processing steps described with reference to FIGS. 7A-7E with accompanying modifications in process parameters may be an integer N, which may be any positive integer greater than 1. In the illustrated example in FIGS. 8A-8E, the integer N is 4. Generally, the integer N may have a value in a range from 2 to 6, although lesser and greater values may also be employed. FIGS. 8A-8E illustrate the first configuration of the exemplary structure after performing a last (i.e., N-th) masked vertical recess process. Retro-stepped cavities 69 can be formed in the volumes from which materials of the alternating stack (32, 42) are removed. As used herein, a retro-stepped cavity refers to a cavity having at least one stepped bottom surface.

Generally, N masked vertical recess processes can be sequentially performed. Thus, for each integer j in a range from 1 to N, a j-th masked vertical recess process can be performed. Specifically, a j-th mask-level photoresist layer (not shown) can be applied over the exemplary structure, and can be lithographically patterned to cover all of the memory array regions 100, the connection regions 400, and a j-th primary subset of the contact-region staircase structures without covering a j-th complementary subset of the contact region staircase structures and without covering boundary regions around each periphery of the semiconductor dies 1000. In one embodiment, the j-th primary subset of the contact-region staircase structures may comprise about one half of all contact-region staircase structures, and the j-th complementary subset of the contact-region staircase structures may be a complementary subset of the j-th primary subset. In other words, the union of the j-th primary subset and the j-th complementary subset may include all of the contact-region staircase structures. A frame-shaped opening may be provided in the j-th mask-level photoresist layer for each boundary region around a respective semiconductor die 1000. The pattern of the openings in the j-th mask-level photoresist layer defines a j-th mask opening pattern, such as a first mask opening pattern 271, a second mask opening pattern 272, a third mask opening pattern 273, a fourth mask opening pattern 274, etc. Generally, the various mask opening patterns (271, 272, 273, 274) may be selected to provide up to 2N different types of masking schemes, each corresponding to a combination of coverage or lack of coverage by each of the N mask-level photoresist layers.

A j-th masked vertical recess process can be performed to vertically recess the unmasked portions of the alternating stack (32, 42) by a j-th vertical recess distance. In an illustrative example, the j-th masked vertical recess process may comprise an anisotropic etch process that etches (K+1)×2^{(j-1)} pairs of an insulating layers 32 and a sacrificial material layer 42. The anisotropic etch process may comprise a reactive ion etch process that is selective to the semiconductor material of the semiconductor material layer 110. Unmasked portions of the alternating stack (32, 42) can be vertically recessed by the j-th vertical recess distance, which may be {(K+1)×2^{(j-1)}} times the sum of a thickness of an insulating layer 32 and a thickness of a sacrificial material layer 42. The j-th complementary subset of the contact-region staircase structures can be vertically recessed by the j-th vertical recess distance, while the j-th primary subset of the contact-region staircase structures is not vertically recessed. Each moat cavity 169 can be vertically extended by each anisotropic etch process until a frame-shaped top surface segment the semiconductor material layer 110 is physically exposed underneath the moat cavities 169. Each j-th mask-level photoresist layer can be subsequently removed, for example, by ashing.

In summary, different staircase structures within the contact regions 300 can be vertically recessed by different recess depths by performing a series of masked vertical recess processes. In one embodiment, the recess depths may be {(K+1)×2^{(j-1)}} times the sum of a thickness of an insulating layer 32 and a thickness of a sacrificial material layer 42, in which j is a positive integer not greater than N. The masking pattern of the mask-level photoresist layers can be selected such that the set of all staircase structures in each contact region 300 comprise a physically exposed top surface segment of each sacrificial material layer 42 within an alternating stack of insulating layers 32 and sacrificial material layers 42.

According to an embodiment of the present disclosure, a first surface segment of a top surface of the semiconductor material layer 110 and a second surface segment of the top surface of the surface of the semiconductor material layer 110 may be exposed in a contact region 300 after the series of masked vertical recess processes. In one embodiment, the first surface segment and the second surface segment are laterally spaced from each other along the first horizontal direction hd1. In one embodiment, the set of all staircase structures in a contact region 300 after the series of masked vertical recess processes comprise first staircase structures 671 located between the first surface segment and the second surface segment of the semiconductor material layer 110, second staircase structures 672 laterally spaced from the first staircase structures by the first surface segment of the semiconductor material layer 110, and third staircase structures 673 laterally spaced from the first staircase structures by the second surface segment of the semiconductor material layer 110.

At this stage of the process, the exemplary structure comprises an alternating stack (32, 42) of insulating layers 32 and sacrificial material layers 42 overlying a semiconductor material layer 110. The alternating stack (32, 42) comprises multiple staircase structures (671, 672, 673) that are arranged along a first horizontal direction hd1. The multiple staircase structures (671, 672, 673) can be located in a contact region 300, which is located between the first memory array region 100A and the second memory array region 100B. A predominant subset of the sacrificial material layers 42 (such as all sacrificial material layers 42 other than (K+1) topmost sacrificial material layers 42 shown in FIG. 8B) extends continuously between the first memory array region 100A and the second memory array region 100B within a connection region 400 that is located between the first memory array region 100A and the second memory array region 100B and laterally offset from the contact region 300 along a second horizontal direction hd2. As used herein, a “predominant subset” of a set refers any subset that includes at least one half of all elements within the set, such as greater than 80% and less than 100%, for example 90% to 99%. A portion of the alternating stack (32, 42) located in the connection region 400 comprises connection-region staircase structures 67C, as shown in FIG. 8B. Each horizontally-extending surface segment within the multiple staircase structures (671, 672, 673) in the contact region 300 can be vertically offset downward from a respective most proximal horizontally-extending surface segment in the connection-region staircase structures 67C at least by a sum of a thickness of an insulating layer 32 in the alternating stack (32, 42) and a thickness of an sacrificial material layer 42 within the alternating stack (32, 42), due to extending of the photoresist layer 27 used to form the scales (i.e., alignment mark structures) AMS in the contact region 300 into the connection region 400, as shown in FIG. 4B. Thus, the depth of the connection-region staircase structures 67C is reduced by one sacrificial material layer due to the step shown in FIG. 4B. In other words, the number of sacrificial material layers 42 that do not continuously extend from the first memory array region 100A to the second memory array region 100B through the connection region 400 is reduced by one due to the step shown in FIG. 4B.

In one embodiment, each staircase structure of the multiple staircase structures (671, 672, 673) comprises a respective set of (K+1) horizontally-extending surface segments that are adjoined each other by a respective set of K vertically-extending surface segments, where K is an integer greater than 2. In one embodiment, the total number of horizontally-extending surface segments within each staircase structure within a primary subset of the multiple staircase structures (671, 672, 673) is (K+1); and a total number of horizontally-extending surface segments within each staircase structure within a complementary subset of the multiple staircase structures (671, 672, 673) is (K+3). In the illustrated example in FIGS. 8A-8E, all staircase structures of the first staircase structures 671, one staircase structure of the second staircase structures 672, and one staircase structure of the third staircase structures 673 belong to the primary subset of the multiple staircase structures (671, 672, 673). Another staircase structure of the second staircase structures 672, and another staircase structure of the third staircase structures 673 belong to the complementary subset of the multiple staircase structures (671, 672, 673).

In one embodiment, a total number of horizontally-extending surface segments within each staircase structure within a primary subset of the connection-region staircase structures 67C is (K+1); and a total number of horizontally-extending surface segments within each staircase structure within a complementary subset of the connection-region staircase structures 67C is (K+2). In the illustrated example in FIGS. 8A-8E, each connection region 400 comprises 12 staircase structures that belong to the primary subset of the connection-region staircase structures 67C, and 4 staircase structures that belong to the complementary subset of the connection-region staircase structures 67C. Each staircase structure that belong to the complementary subset of the connection-region staircase structures 67C is located adjacent to a respective sidewall of the hard mask layer 28. In one embodiment, each staircase structure within the primary subset of the connection-region staircase structures 67C has a same lateral extent along the first horizontal direction hd1 as a respective staircase structure within the primary subset of the multiple staircase structures (671, 672, 673); and each staircase structure within the complementary subset of the connection-region staircase structures 67C has a same lateral extent along the first horizontal direction hd1 as a respective staircase structure within the complementary subset of the multiple staircase structures (671, 672, 673).

In one embodiment, all horizontally-extending surface segments within the primary subset of the connection-region staircase structures 67C are located entirely within a set of (K+1) horizontal planes. Each horizontally-extending surface segment within the primary subset of the multiple staircase structures (671, 672, 673) is located below a bottommost horizontal plane of the set of (K+1) horizontal planes, and is vertically spaced from the bottommost horizontal plane by at least two insulating layers 32 within the alternating stack (32, 42). In one embodiment, all horizontally-extending surface segments within the connection-region staircase structures 67C are located entirely within a set of (K+2) horizontal planes including a topmost set of (K+2) sacrificial material layers 42 within the alternating stack (32, 42). All horizontally-extending surface segments within the complementary subset of the multiple staircase structures (671, 672, 673) are located entirely within a set of (K+3) horizontal planes including the set of (K+2) horizontal planes and including a horizontal plane including a top surface of a (K+3)-th sacrificial material layer 42 as counted downward from top within the alternating stack (32, 42). In one embodiment, all horizontally-extending surface segments within the primary subset of the multiple staircase structures (671, 672, 673) are located entirely below a horizontal plane including a top surface of a (K+4)-th sacrificial material layer 42 as counted downward from top within the alternating stack (32, 42).

In one embodiment, each horizontally-extending surface segment within the complementary subset of the multiple staircase structures (671, 672, 673) are vertically offset from a respective horizontally-extending surface segment by a respective vertical step that extends along the first horizontal direction hd1 and having a height that equals a vertical distance between a top surface of an overlying sacrificial material layer 42 and a top surface of an underlying sacrificial material layer 42 within a vertically neighboring pair of sacrificial material layers 42 in the alternating stack (32, 42). In one embodiment, the complementary subset of the multiple staircase structures (671, 672, 673) comprises a pair of outermost staircase structures in a vertical cross-sectional view along a vertical plane that is perpendicular to the second horizontal direction hd2 (such as the vertical cross-sectional view of FIG. 8A).

In one embodiment, the total number of horizontally-extending surface segments within each staircase structure within a primary subset of the multiple staircase structures (671, 672, 673) is (K+1), and the total number of horizontally-extending surface segments within each staircase structure within a complementary subset of the multiple staircase structures (671, 672, 673) is (K+3). In one embodiment, the second staircase structures 672 comprise a staircase structure within the complementary subset of the multiple staircase structures (671, 672, 673) and a staircase structure within the primary subset of the multiple staircase structures (671, 672, 673). In one embodiment, the third staircase structures 673 comprise a staircase structure within the complementary subset of the multiple staircase structures (671, 672, 673) and a staircase structure within the primary subset of the multiple staircase structures (671, 672, 673).

As used herein, a staircase structure is an ascending staircase structure if the height of horizontally-extending surface segments of the staircase structure increases stepwise along a horizontal direction, which is a fixed horizontal direction such as the first horizontal direction hd1. As used herein, a staircase structure is a descending staircase structure if the height of horizontally-extending surface segments of the staircase structure decreases stepwise along a horizontal direction, which is a fixed horizontal direction such as the first horizontal direction hd1. As such, each ascending staircase structure for a given reference horizontal direction can be a descending staircase structure if a different horizontal direction that is an opposite direction of the reference horizontal direction is employed as a new reference horizontal direction, and vice versa.

In one embodiment, the multiple staircase structures (671, 672, 673) comprise ascending staircase structures 67A of which horizontally-extending surface segments have a stepwise-increasing height profile that increases stepwise along the first horizontal direction hd1; and descending staircase structures 67D of which horizontally-extending surface segments have a stepwise-decreasing height profile that decreases stepwise along the first horizontal direction hd1. In one embodiment, the first staircase structures 671 comprise a laterally alternating sequence of first descending staircase structures 67D and first ascending staircase structures 67A that alternate along the first horizontal direction hd1; the second staircase structures 672 consist of a second descending staircase structure 67D and a second ascending staircase structure 67A; and the third staircase structures 673 consist of a third descending staircase structure 67D and a third ascending staircase structure 67A. In one embodiment, each of the first ascending staircase structures 67A comprises a respective set of (K+1) horizontally-extending surface segments; each of the first descending staircase structures 67D comprises a respective set of (K+1) horizontally-extending surface segments; the second ascending staircase structure 67A comprises a set of (K+1) horizontally-extending surface segments; and the third descending staircase structure 67D comprises a set of (K+1) horizontally-extending surface segments.

In one embodiment, the alternating stack (32, 42) comprises multiple staircase structures (671, 672, 673) that are arranged along a first horizontal direction hd1. In one embodiment, the multiple staircase structures (671, 672, 673) comprises first staircase structures 671 that are interconnected to each other by widthwise sidewalls that laterally extend along a second horizontal direction hd2 that is perpendicular to the first horizontal direction hd1, second staircase structures 672 that are laterally spaced from the first staircase structures 671, and third staircase structures 673 that are laterally spaced from the first staircase structures 671 and from the second staircase structures 672.

In one embodiment, each staircase structure within the multiple staircase structures (671, 672, 673) comprises a respective set of (K+1) horizontally-extending surface segments that are adjoined to each other by a respective set of K vertically-extending surface segments, and K is an integer greater than 2. In one embodiment, each vertically-extending surface segment within the multiple staircase structures (671, 672, 673) has a height that equals a vertical spacing between a bottom surface of an overlying insulating layer 32 within a respective vertically neighboring pair of insulating layers 32 within the alternating stack (32, 42) and a bottom surface of an underlying insulating layer 32 within the respective vertically neighboring pair. In one embodiment, each laterally neighboring pair of staircase structures along the second horizontal direction hd2 is vertically offset relative to each other by at least a respective set of (K+1) insulating layers 32 within the alternating stack (32, 42).

As discussed above, use of the same value for the initial gap width gwi for each gap of the trimmable photoresist material portions 21 at the processing steps of FIGS. 5A-5E provides uniform trimming distance at each gap between neighboring pairs of trimmable photoresist material portions 21 during each photoresist trimming process. In one embodiment, a lateral extent of 2(K+1) horizontally-extending surface segments of the third staircase structures 673 along the first horizontal direction hd1 is the same as a lateral extent of 2(K+1) horizontally-extending surface segments of the second staircase structures 672 along the first horizontal direction hd1.

In one embodiment, the multiple staircase structures (671, 672, 673) comprises ascending staircase structures 67A of which horizontally-extending surface segments have a stepwise-increasing height profile that increases stepwise along the first horizontal direction hd1; and descending staircase structures 67D of which horizontally-extending surface segments have a stepwise-decreasing height profile that decreases stepwise along the first horizontal direction hd1. In one embodiment, the first staircase structures 671 comprise a laterally alternating sequence of first descending staircase structures 67D and first ascending staircase structures 67A that alternate along the first horizontal direction hd1; the second staircase structures 672 consist of a second descending staircase structure 67D and a second ascending staircase structure 67A; and the third staircase structures 673 consist of a third descending staircase structure 67D and a third ascending staircase structure 67A. In one embodiment, each of the first ascending staircase structures 67A comprises a respective set of (K+1) horizontally-extending surface segments; each of the first descending staircase structures 67D comprises a respective set of (K+1) horizontally-extending surface segments; the second ascending staircase structure 67A comprises a set of (K+1) horizontally-extending surface segments; and the third descending staircase structure 67D comprises a set of (K+1) horizontally-extending surface segments.

In one embodiment, each of the first ascending staircase structures 67A, the first descending staircase structures 67D, the second ascending staircase structure 67A, and the third descending staircase structure 67D has a same lateral extent along the first horizontal direction hd1. In one embodiment, the second descending staircase structure 67D comprises a set of (K+3) horizontally-extending surface segments; and the third ascending staircase structure 67A comprises a set of (K+3) horizontally-extending surface segments.

In one embodiment, the first staircase structures 671, the second staircase structures 672, the third staircase structures 673, the first surface segment of the top surface of the semiconductor material layer 110, and the second surface segment of the top surface of the semiconductor material layer 110 are located in a contact region 300 located between the first memory array region 100A and the second memory array region 100B. In one embodiment, a predominant subset of the sacrificial material layers 42 extends continuously between the first memory array region 100A and the second memory array region 100B within a connection region 400 that is located between the first memory array region 100A and the second memory array region 100B and laterally offset from the contact region 300 along the second horizontal direction hd2.

In one embodiment, a portion of the alternating stack (32, 42) located in the connection region 400 comprises connection-region staircase structures 67C, wherein each horizontally-extending surface segment of the connection-region staircase structures 67C is located above a horizontal plane including a topmost horizontally-extending surface segment of the first staircase structures 671, and is vertically spaced from the horizontal plane by at least two insulating layers 32 within the alternating stack (32, 42). In one embodiment, each staircase structure within the multiple staircase structures (671, 672, 673) comprises a respective set of (K+1) horizontally-extending surface segments that are adjoined to each other by a respective set of K vertically-extending surface segments; one of the second staircase structures 672 comprises horizontally-extending surface segments that are located within a set of (K+3) horizontal planes; one of the third staircase structure comprises additional horizontally-extending surface segments that are located within the set of (K+3) horizontal planes; and an entirety of horizontally-extending surface segments of the connection-region staircase structures 67C is located within a set of (K+2) horizontal planes that includes each horizontal plane within the set of (K+3) horizontal planes except a bottommost horizontal plane within the set of (K+3) horizontal planes.

Each moat cavity 169 vertically extends through each layer in the alternating stack (32, 42). Each moat cavity 169 may comprise straight sidewalls that extend from the semiconductor material layer 110 to a top surface of a sacrificial material layer 42 which is a second sacrificial material layer 42 as counted downward from top within an alternating stack of insulating layers 32 and sacrificial material layers 42.

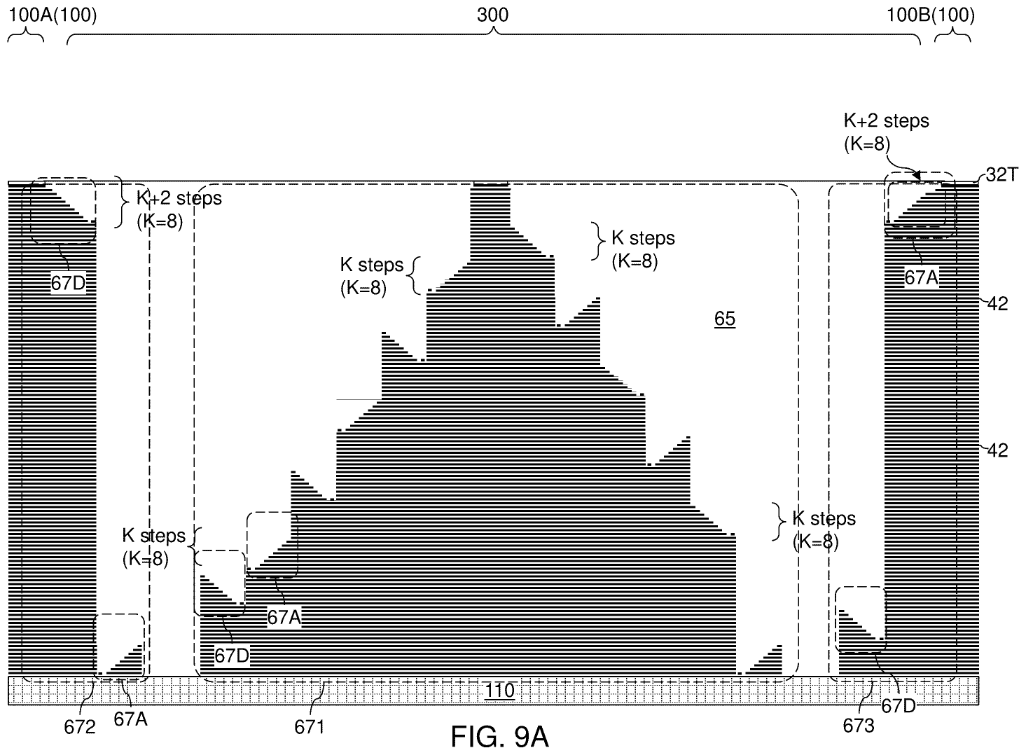

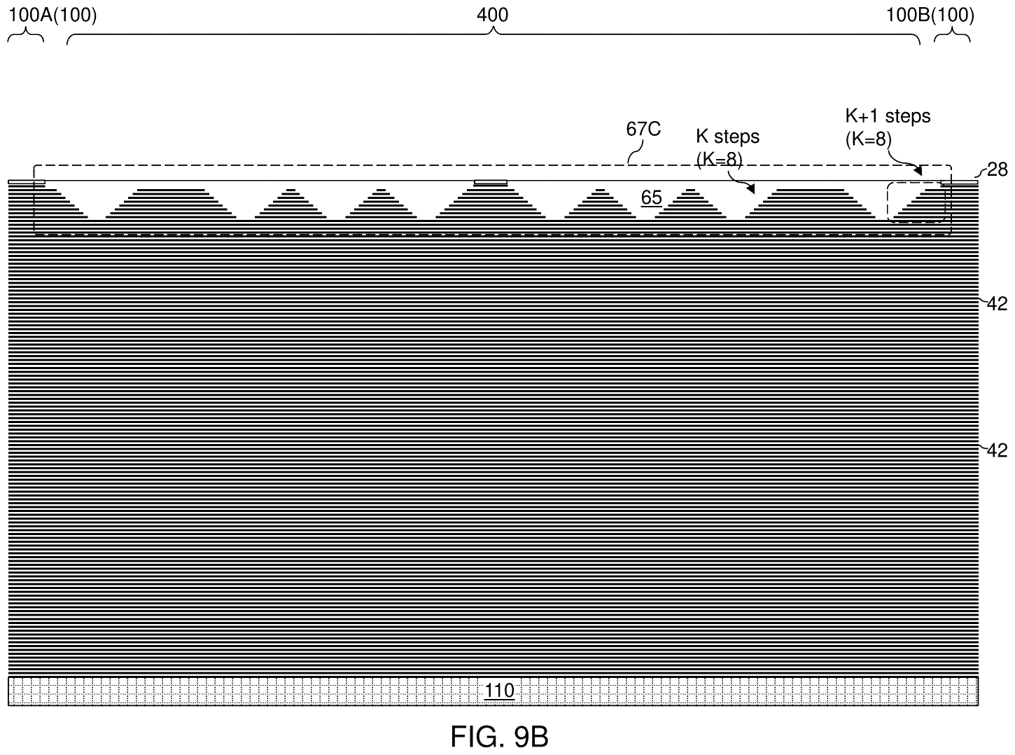

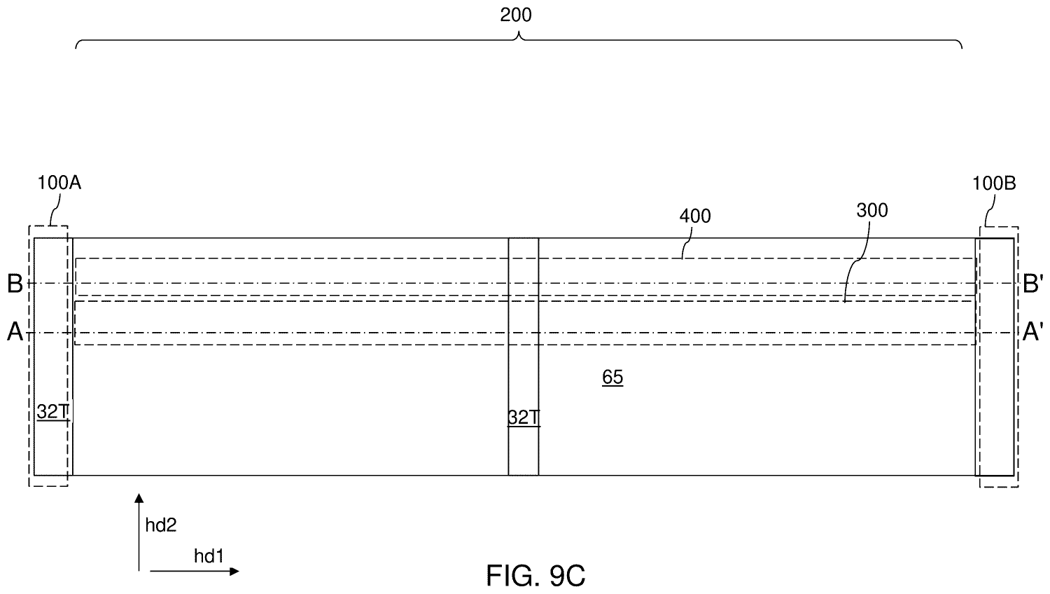

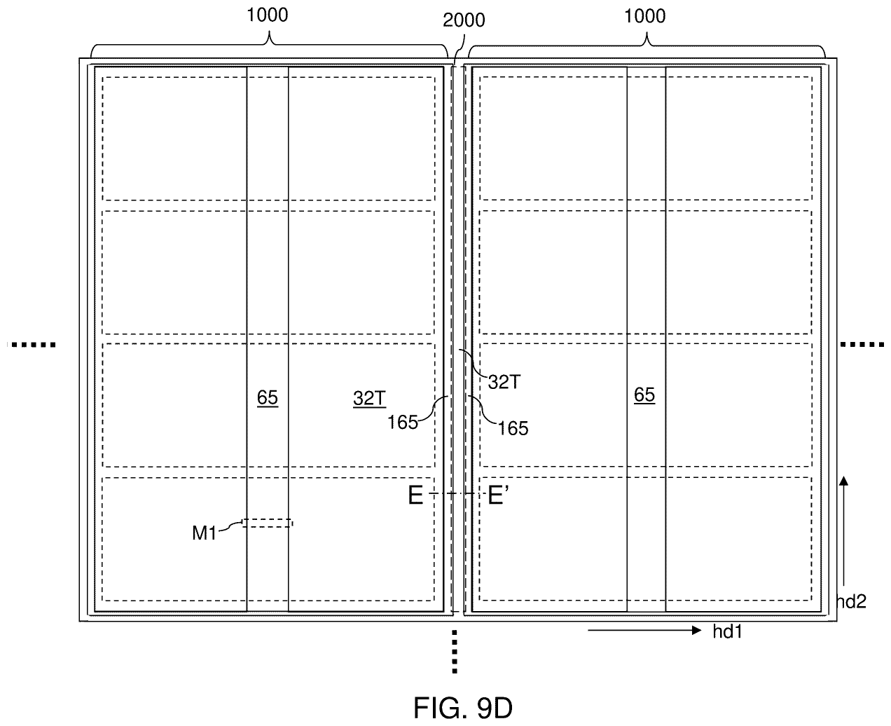

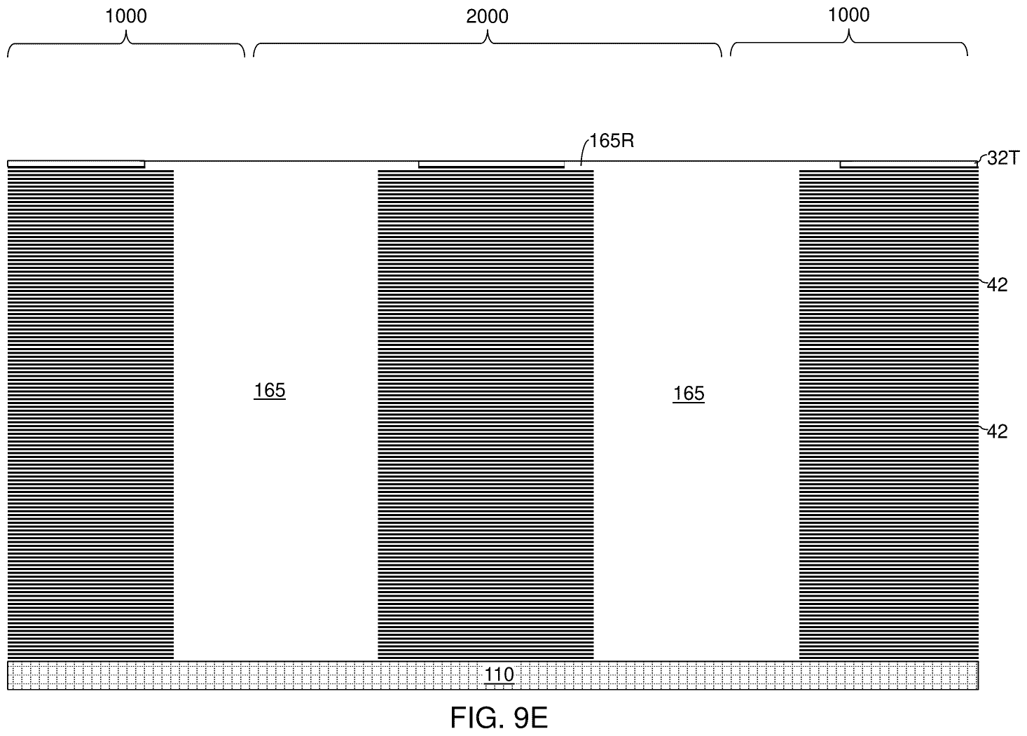

Referring to FIGS. 9A-9E, a dielectric fill material such as silicon oxide can be deposited in the retro-stepped cavities 69 and in the moat cavities 169. Excess portions of the dielectric fill material can be removed from above the horizontal plane including the top surface of the hard mask layer 28. The dielectric fill material can be subsequently vertically recessed such that remaining portions of the dielectric fill material have top surfaces located at, or about, the horizontal plane including the top surface of the topmost insulating layer 32T. Each dielectric fill material portion that fills a retro-stepped cavity 69 constitutes a retro-stepped dielectric material portion 65. Each dielectric fill material portion that fills a moat cavity 169 constitutes a dielectric moat structure 165.

At least one retro-stepped dielectric material portion 65 can be formed over the multiple staircase structures (671, 672, 673) and the connection-region staircase structures 67C. In one embodiment, a plurality of retro-stepped dielectric material portions 65 (e.g., two retro-stepped dielectric material portions 65 as illustrated in FIGS. 9A-9E) may be formed within each contact region 300 and within each connection region 400.

In one embodiment, the at least one retro-stepped dielectric material portion 65 contacts a first surface segment of a top surface of the semiconductor material layer 110 and a second surface segment of the top surface of the semiconductor material layer 110 that is laterally spaced from the first surface segment. In one embodiment, the multiple staircase structures (671, 672, 673) comprise first staircase structures 671 located between the first surface segment of the top surface of the semiconductor material layer 110 and the second surface segment of the top surface of the semiconductor material layer 110, second staircase structures 672 laterally spaced from the first staircase structures by the first surface segment, and third staircase structures 673 laterally spaced from the first staircase structures by the second surface segment.

In one embodiment, at least one retro-stepped dielectric material portion 65 may contact the first staircase structures 671, the second staircase structures 672, the third staircase structures 673, a first surface segment of a top surface of the semiconductor material layer 110 located between the first staircase structures 671 and the second staircase structures 672, and a second surface segment of the top surface of the semiconductor material layer 110 located between the first staircase structures 671 and the third staircase structures 673.

In one embodiment, a semiconductor die 1000 comprises a peripheral alternating stack (32, 42) of additional insulating layers 32 and spacer material layers (such as sacrificial material layers 42) located in a peripheral region of the semiconductor die 1000, and further comprises a dielectric moat structure 165 that laterally surrounds the peripheral alternating stack (32, 42). In one embodiment, the peripheral alternating stack (32, 42) has a same height as the alternating stack (32, 42); and a straight sidewall of the dielectric moat structure 165 contacts each additional insulating layer 32 within the peripheral alternating stack (32, 42) other than a topmost insulating layer 32 within the peripheral alternating stack (32, 42). In one embodiment shown in FIG. 9E, the dielectric moat structure 165 comprises a lateral protrusion region 165R that laterally protrudes inward from the straight sidewall and contacts a sidewall of the topmost insulating layer 32 within the peripheral alternating stack (32, 42) and contacts a sidewall of a topmost spacer material layer within the peripheral alternating stack (32, 42).

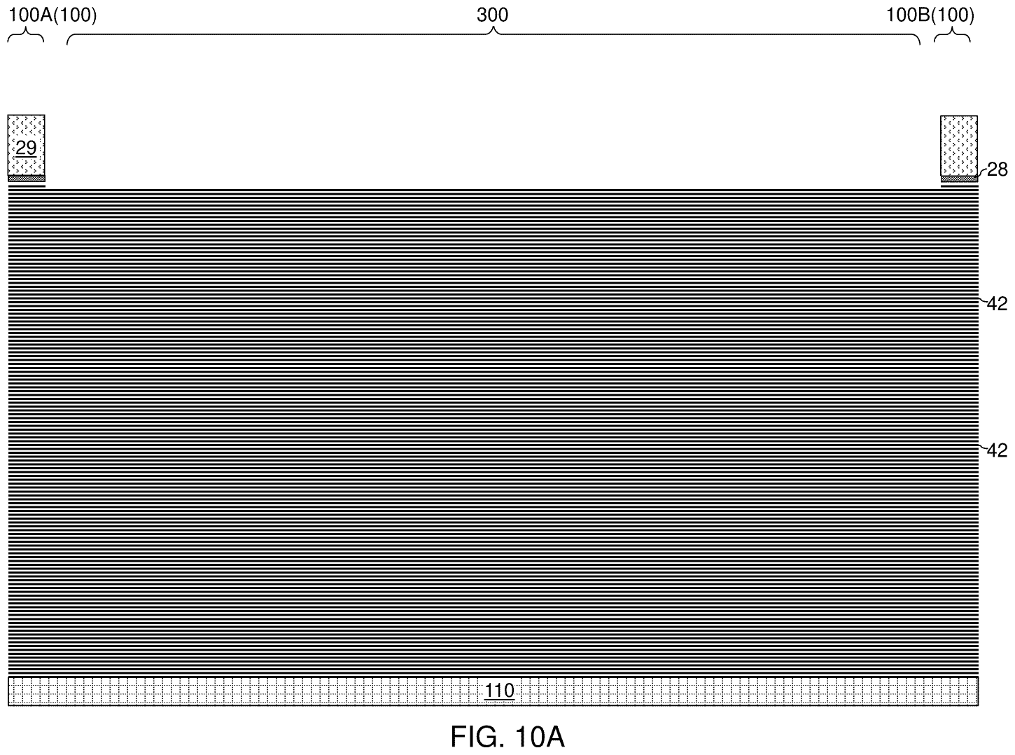

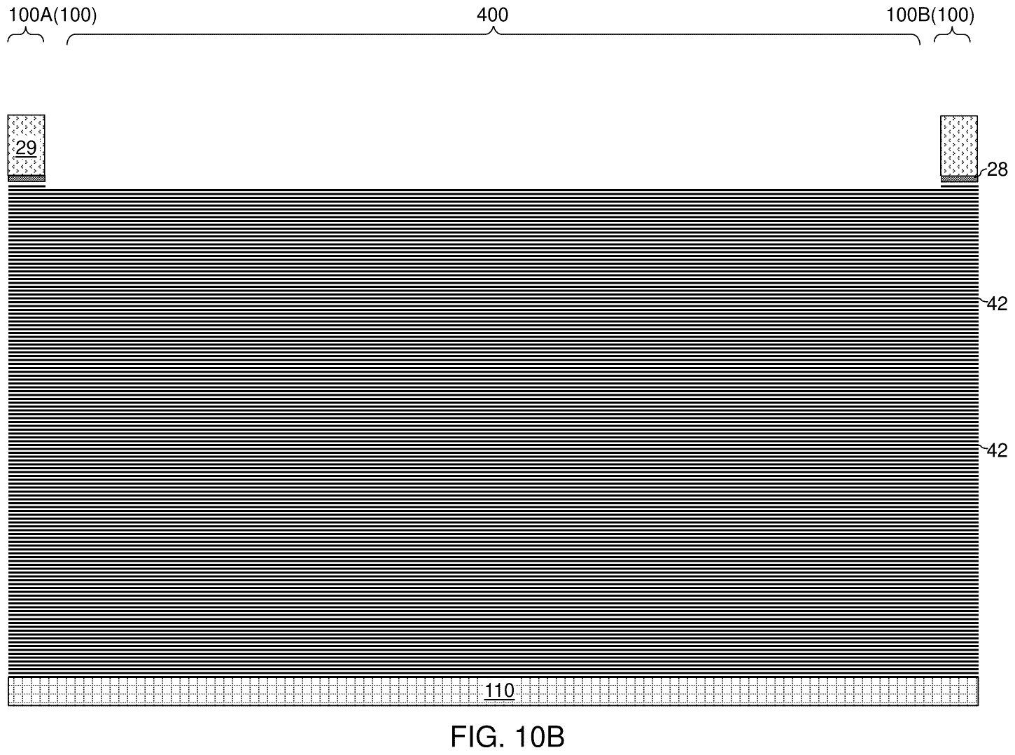

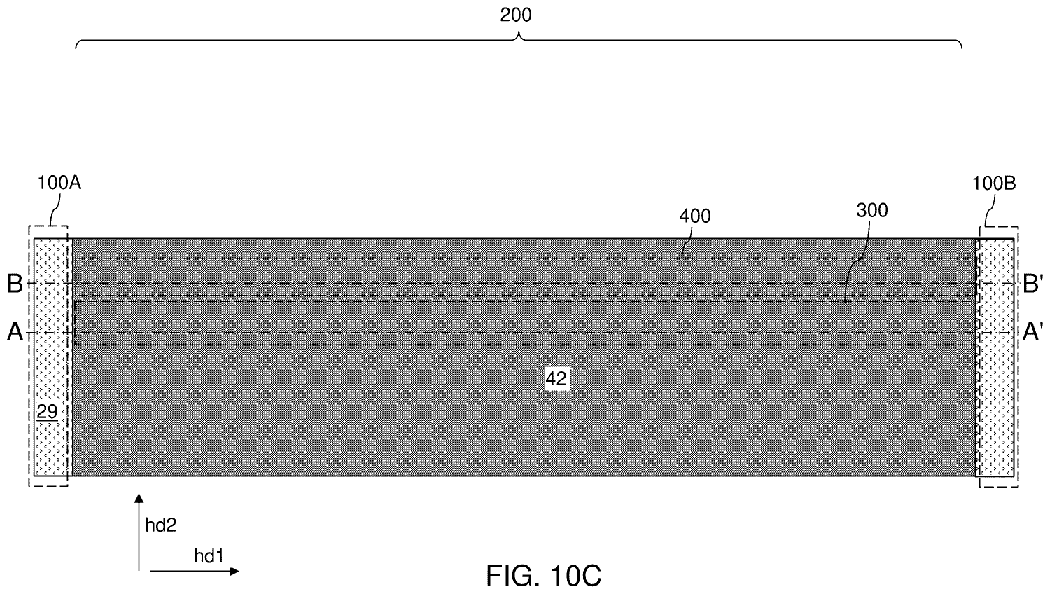

Referring to FIGS. 10A-10C, a second configuration of the exemplary structure is illustrated after patterning the alternating stack (32, 42) employing a first patterned photoresist layer 29. The second configuration of the exemplary structure can be derived from the first configuration of the exemplary structure illustrated in FIGS. 3A-3E by modifying the pattern of the first patterned photoresist layer 29 and the hard mask layer 28. Specifically, a single continuous opening in the first photoresist layer 29 can be formed within each inter-array region 200.

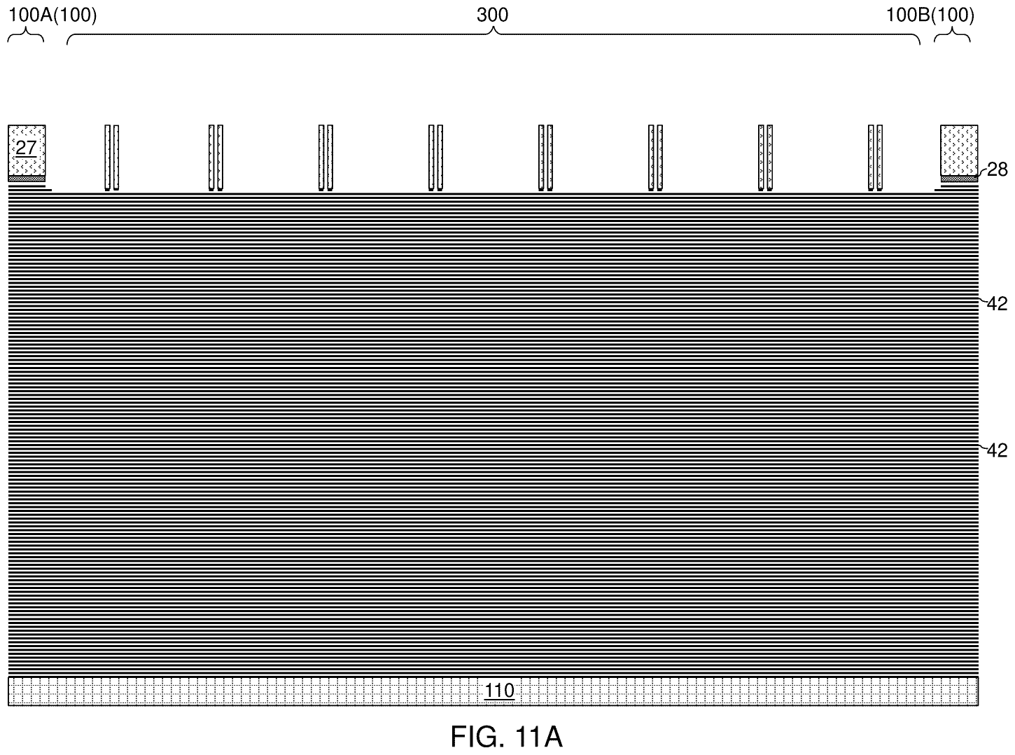

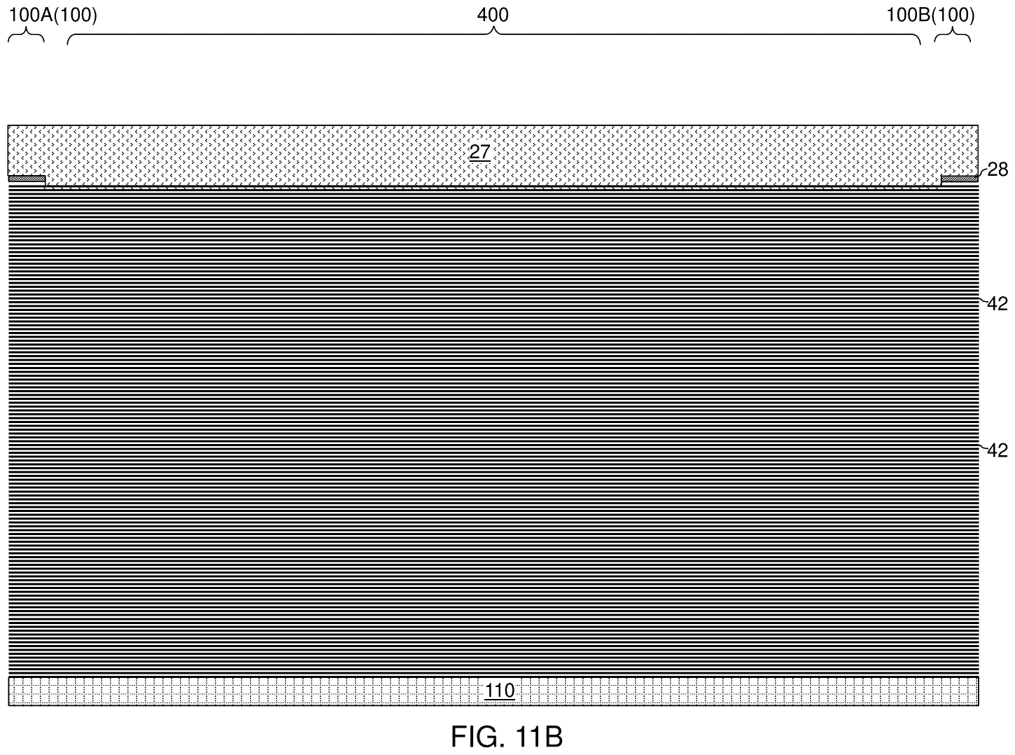

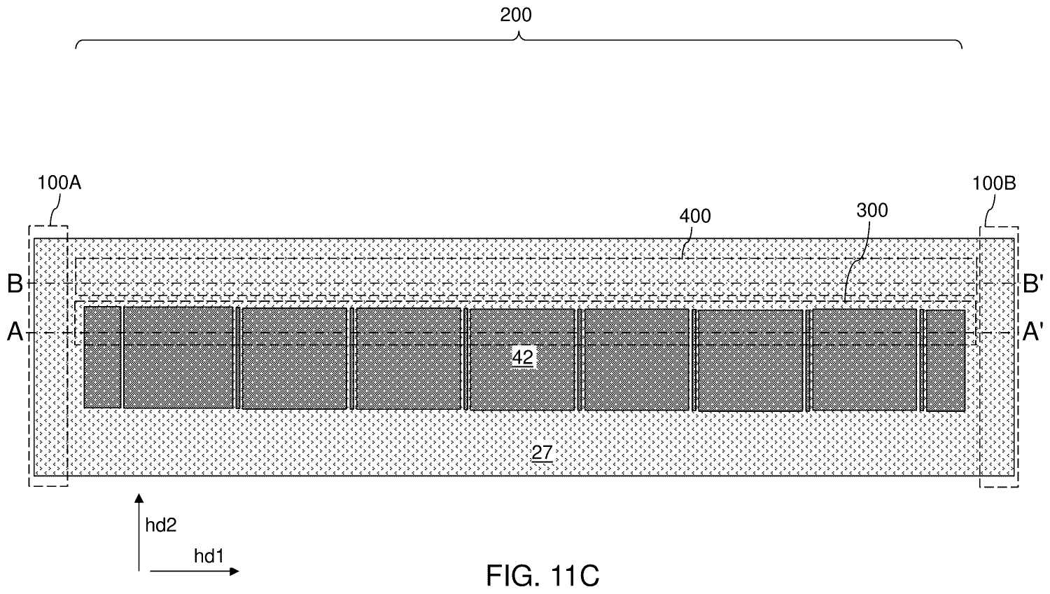

Referring to FIGS. 11A-11C, the processing steps described with reference to FIGS. 4A-4E can be performed with a modification in the pattern of the second photoresist layer 27 in view of formation of a single opening in each inter-array region 200 in the second configuration in lieu of a pair of openings in each inter-array region 200 in the first configuration. In the second configuration, each of the primary rectangular openings in the second photoresist layer 27 may have the same length along the first horizontal direction hd1. In this case, a pair of a primary rectangular opening and a supplementary rectangular opening may be a repetition unit that is periodically repeated within a row of rectangular openings in the second photoresist layer 27 in each contact region 300. An anisotropic etch process can be performed as described with reference to FIGS. 4A-4E to transfer the pattern of the rectangular openings in the second photoresist layer 27 through a pair of an insulating layer 32 and a sacrificial material layer 42, which includes a second insulating layer 32 as counted downward from top and a second sacrificial material layer 42 as counted downward from top in the alternating stack (32, 42).

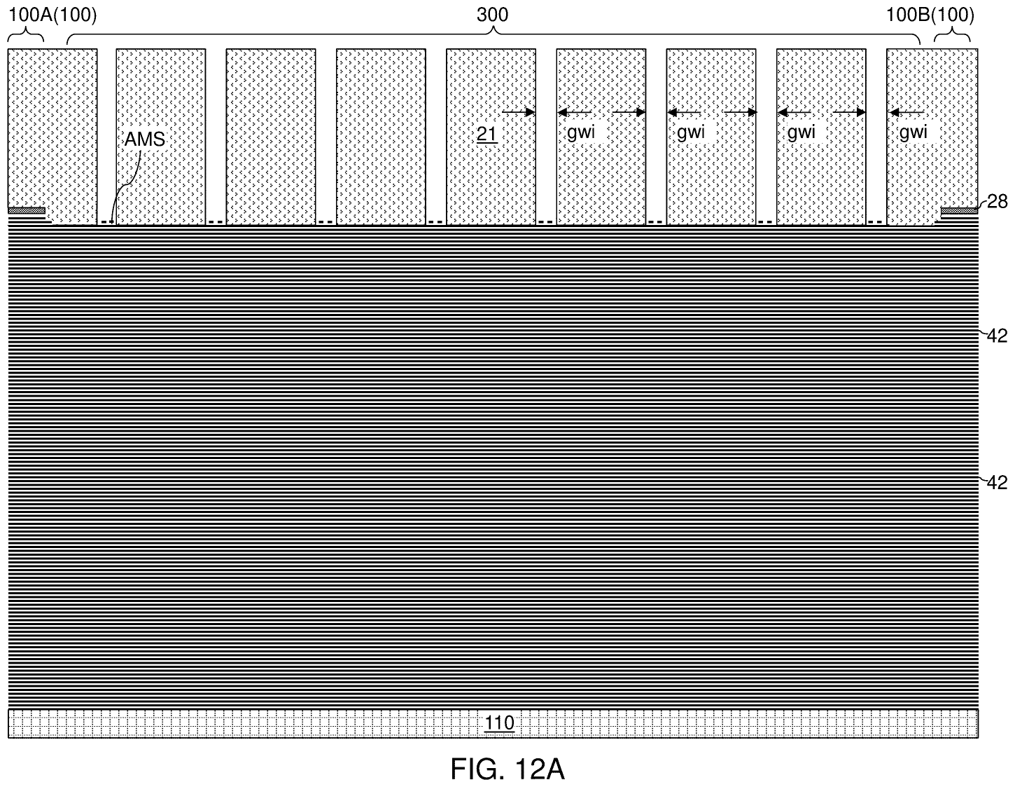

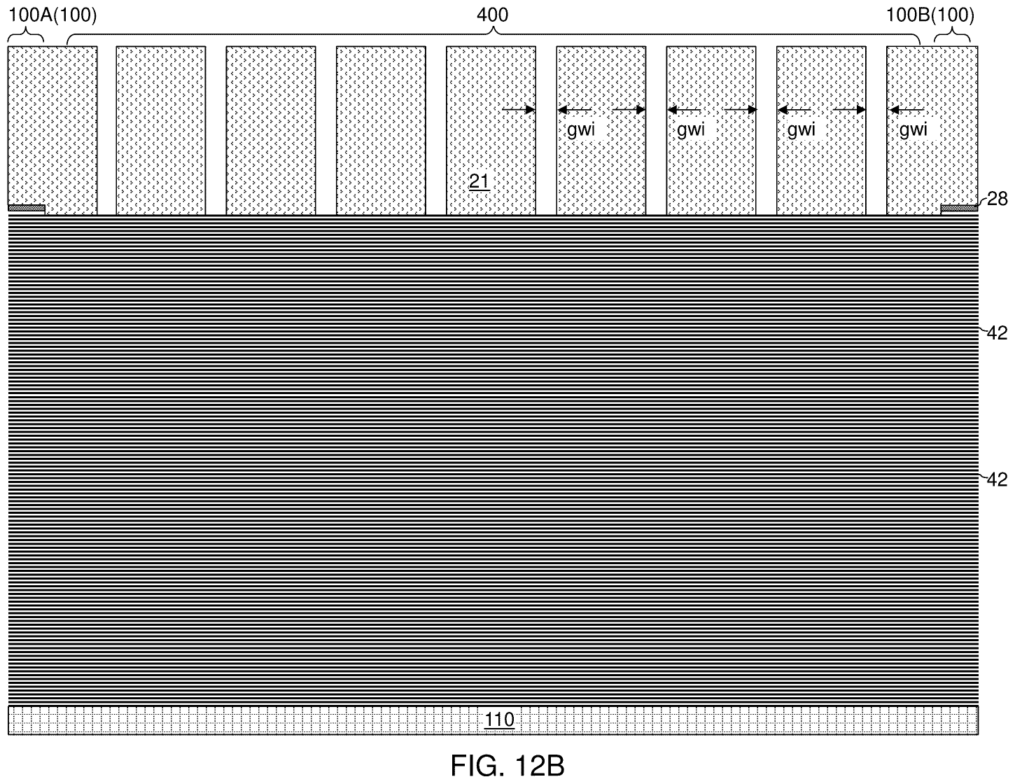

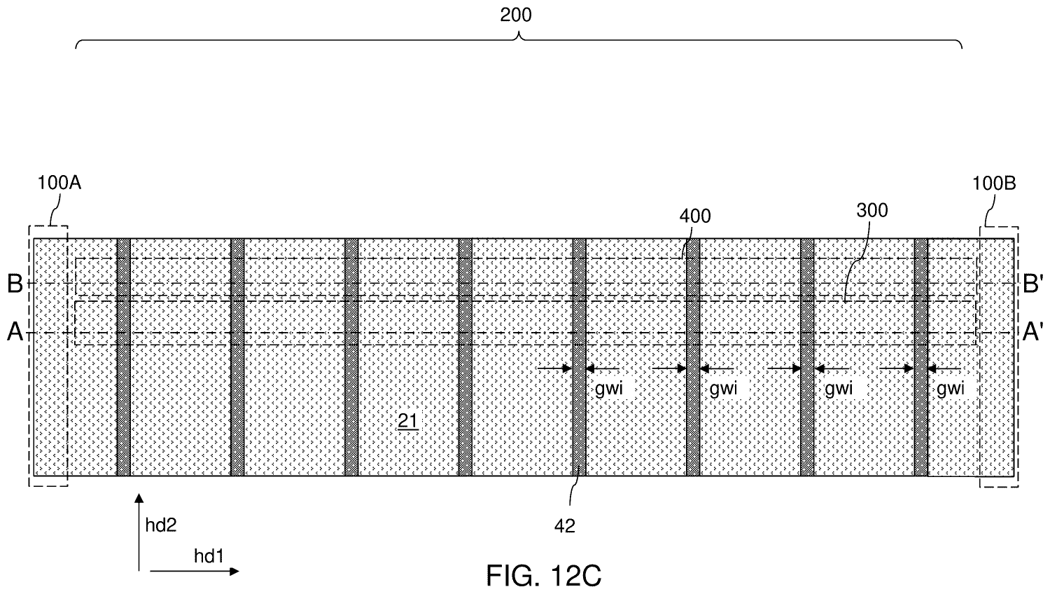

Referring to FIGS. 12A-12C, the processing steps described with reference to FIGS. 5A-5E can be performed. As discussed above, patterned trimmable photoresist material portions 21 may cover the entirety of the memory array regions 100 and the kerf regions 2000, and may have straight edges that laterally extend through inter-array regions 200 within the area of a respective semiconductor die 1000.

According to an aspect of the present disclosure, each neighboring pair of trimmable photoresist material portions 21 of the trimmable photoresist material portions 21 overlying a respective semiconductor die 1000 may be laterally spaced from each other along the first horizontal direction hd1 by a respective gap having a same initial gap width gwi that is invariant along the second horizontal direction hd2. In one embodiment, the locations of the gaps between each neighboring pair of trimmable photoresist material portions 21 can be selected such that a pair of alignment mark strips AMS is located entirely within the area of an overlying gap.

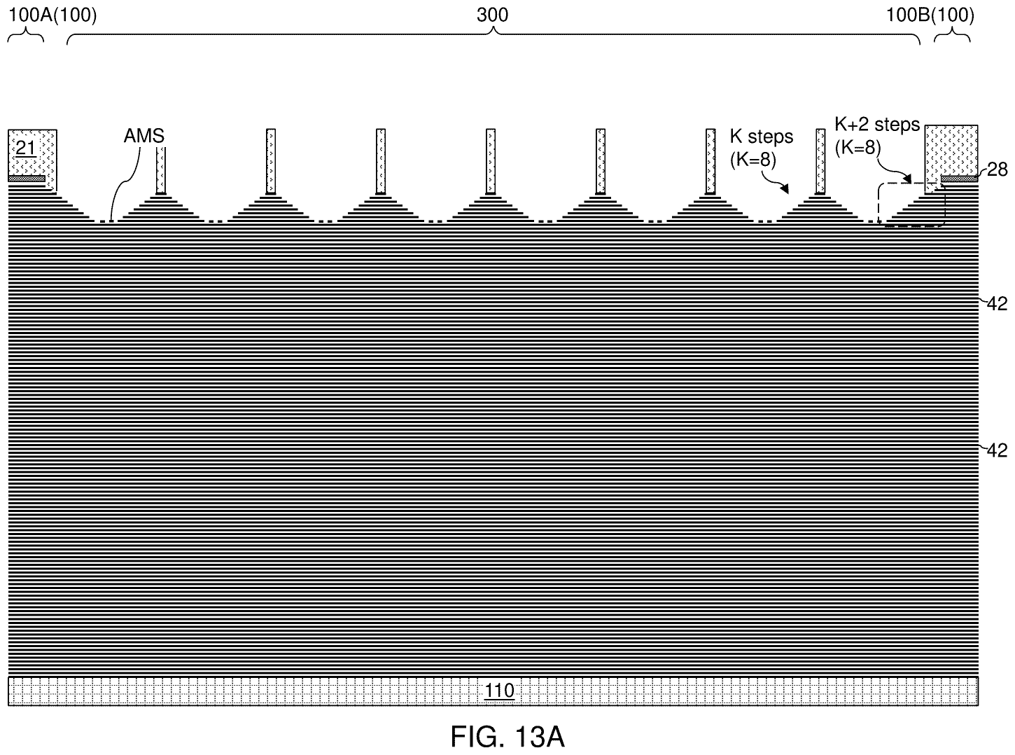

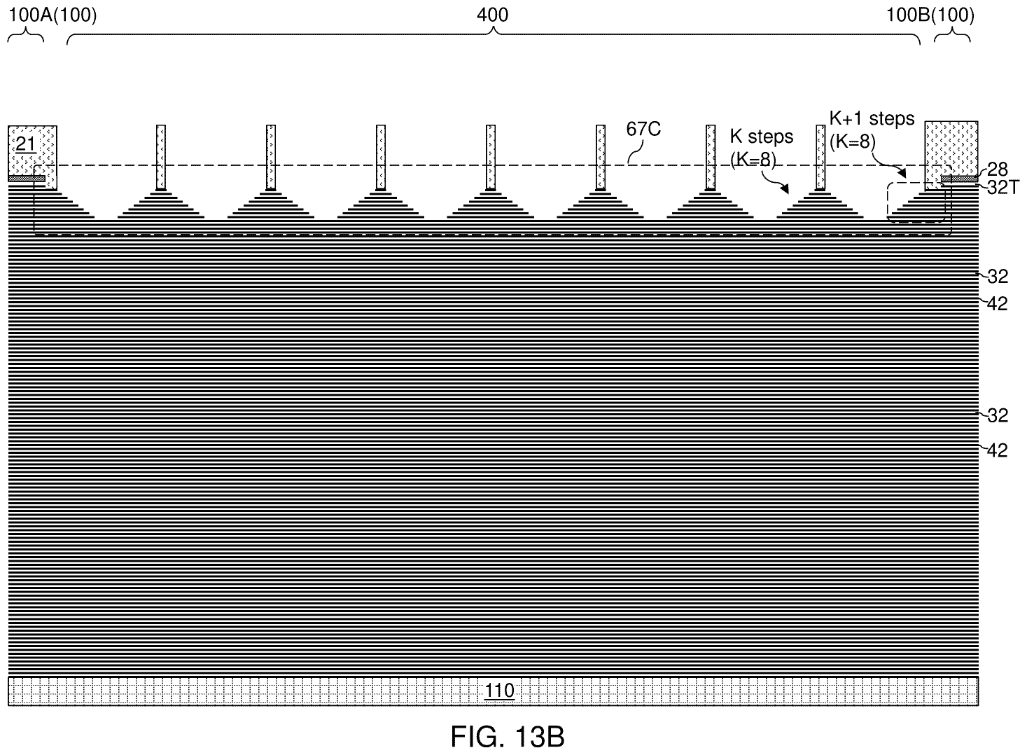

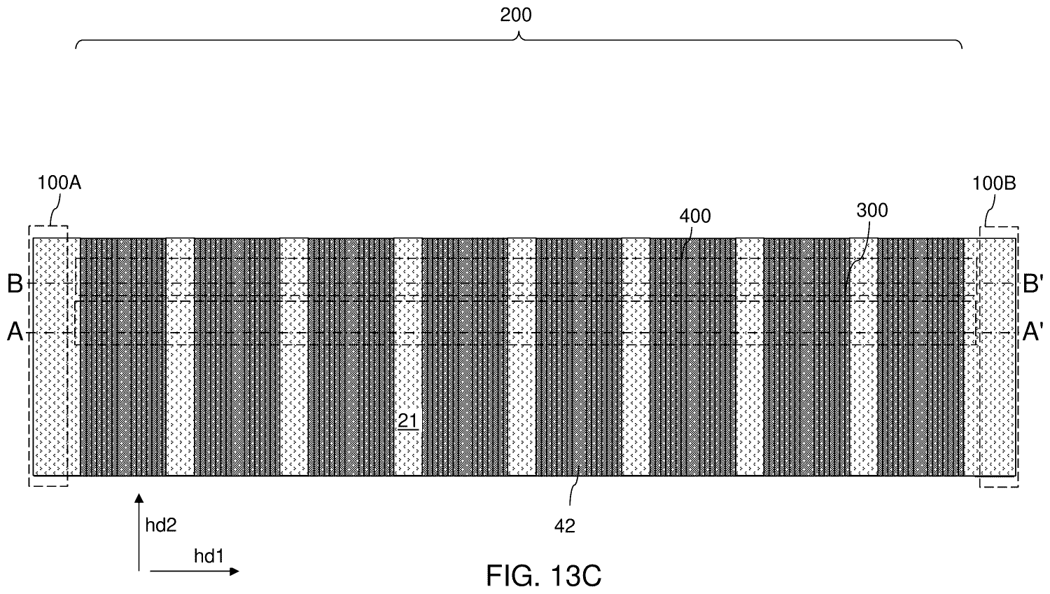

Referring to FIGS. 13A-13C, the processing steps described with reference to FIGS. 6A-6E can be performed. Thus, a set of processing steps that include K anisotropic etch processes interlaced with (K−1) photoresist trimming processes can be performed. K is an integer greater than 2. In one embodiment, the value of the integer K may be in a range from 3 to 16, such as from 4 to 12, although lesser and greater values may also be employed. In one embodiment, a combination of processing steps including an anisotropic etch step and a photoresist trimming step may be repeated (K−1) times, and a terminal anisotropic etch process may be subsequently performed to provide the K anisotropic etch processes and the (K−1) photoresist trimming processes.

The staircase structures comprise contact-region staircase structures that are formed in the contact regions 300, and connection-region staircase structures 67C that are formed in the connection regions 400. Each staircase structure comprises K vertically-extending surface segments. In one embodiment, each staircase structure located in a contact region 300 and laterally spaced from that are distal from the hard mask layer 28 by at least one alignment mark strip AMS may consist of K vertically-extending surface segments and (K+1) horizontally-extending surface segments. Such staircase structures are herein referred to as first-type contact-region staircase structures. Each staircase structure located in a contact region 300 and is more proximal to the hard mask layer 28 than any alignment mark strip AMS may include (K+2) vertically-extending surface segments (“K+2 steps”) and (K+3) horizontally-extending surface segments. Such staircase structures are herein referred to as second-type contact-region staircase structures. In one embodiment, each staircase structure located in a connection region 400 and laterally offset from a first-type contact-region staircase structure along the second horizontal direction hd2 may consist of K vertically-extending surface segments and (K+1) horizontally-extending surface segments. Such staircase structures are herein referred to as first-type connection-region staircase structures. Each staircase structure located in a connection region 400 and laterally offset from a second-type contact-region staircase structure along the second horizontal direction hd2 may include (K+1) vertically-extending surface segments and (K+2) horizontally-extending surface segments. Such staircase structures are herein referred to as second-type connection-region staircase structures. The trimmable photoresist material portions 21 can be subsequently removed, for example, by ashing.

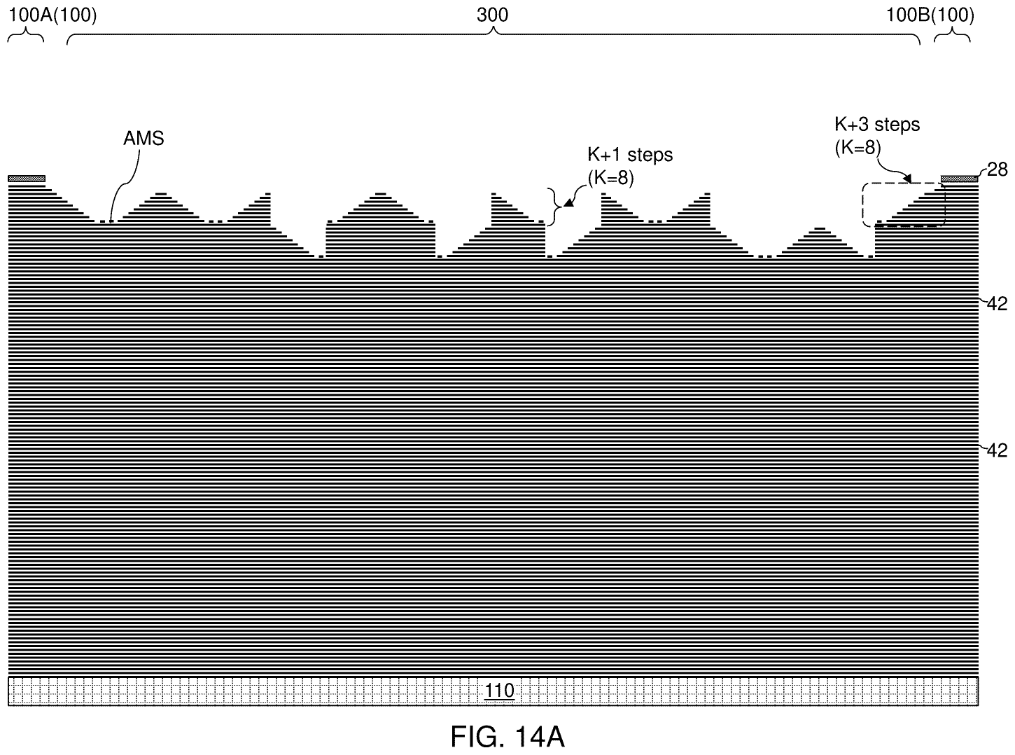

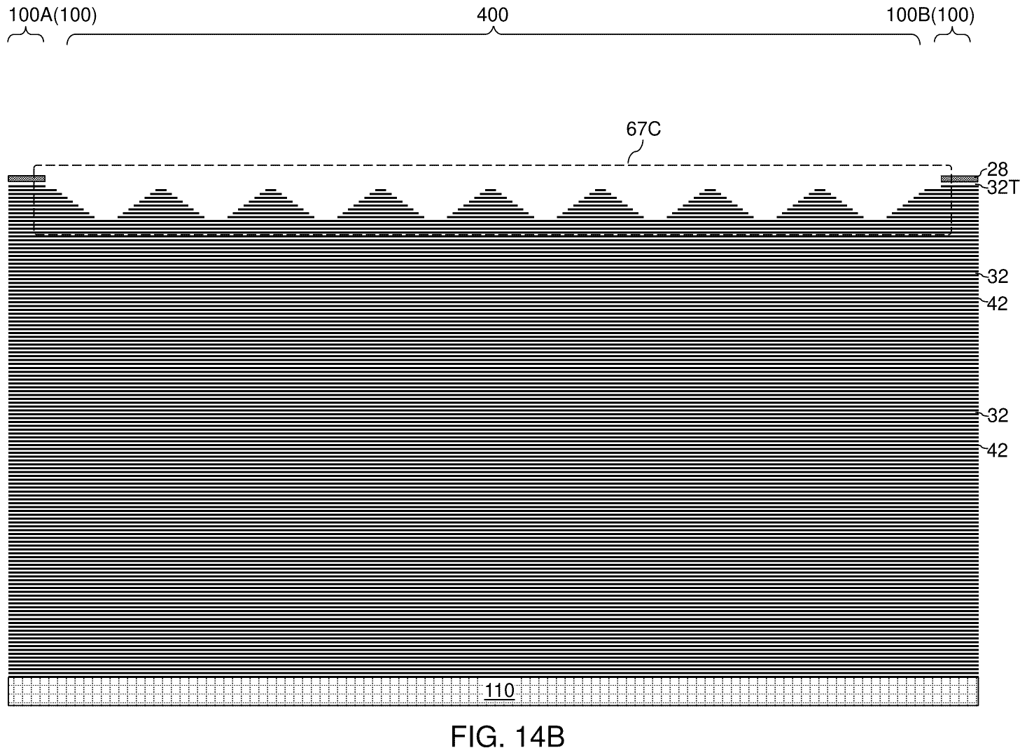

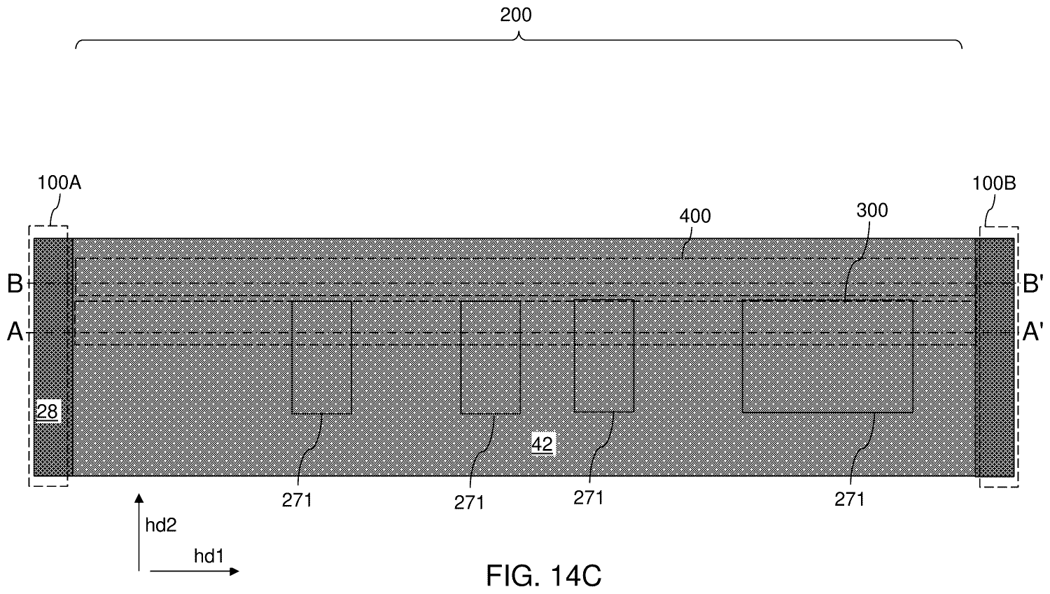

Referring to FIGS. 14A-14C, the processing steps described with reference to FIGS. 7A-7E can be performed. Thus, a first masked vertical recess process can be performed to vertically recess the unmasked portions of the alternating stack (32, 42) by a first vertical recess distance. The first masked vertical recess process may comprise an anisotropic etch process that etches (K+1) pairs of an insulating layers 32 and a sacrificial material layer 42. The anisotropic etch process may comprise a reactive ion etch process. Unmasked portions of the alternating stack (32, 42) can be vertically recessed by the first vertical recess distance, which may be (K+1) times the sum of a thickness of an insulating layer 32 and a thickness of a sacrificial material layer 42. The first complementary subset of the contact-region staircase structures can be vertically recessed by the first vertical recess distance, while the first primary subset of the contact-region staircase structures is not vertically recessed. A moat cavity 169 (See FIG. 7E) can be formed in each boundary region at the peripheries of the semiconductor dies 1000. The first mask-level photoresist layer can be subsequently removed, for example, by ashing.

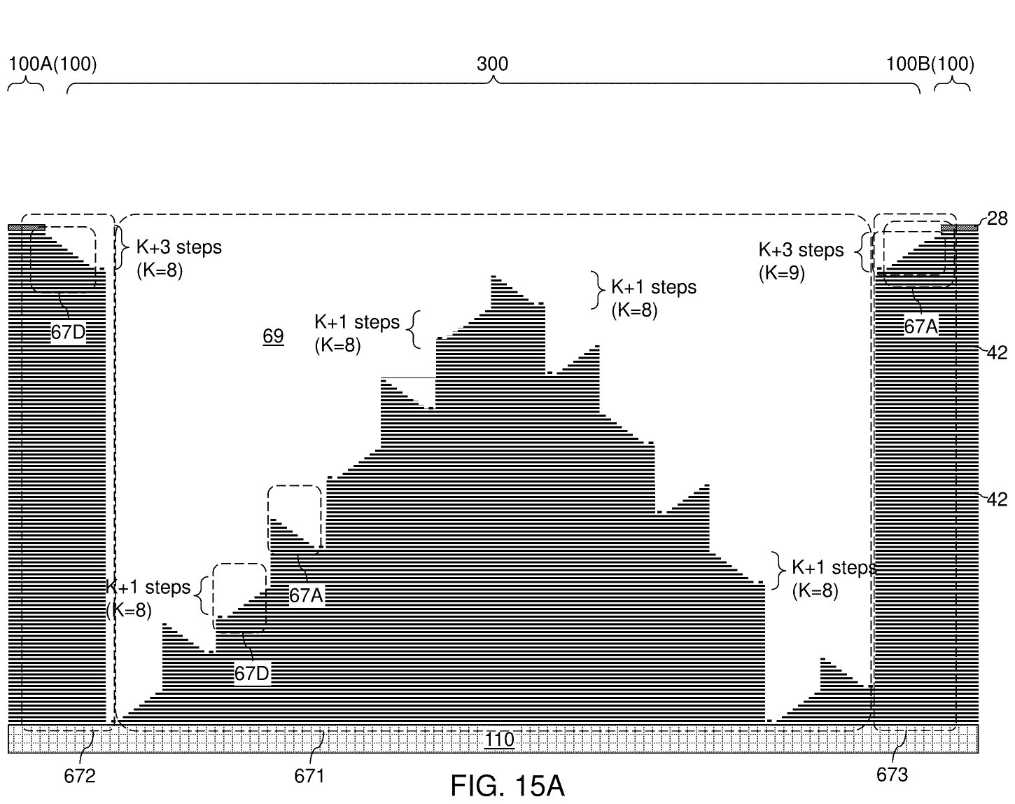

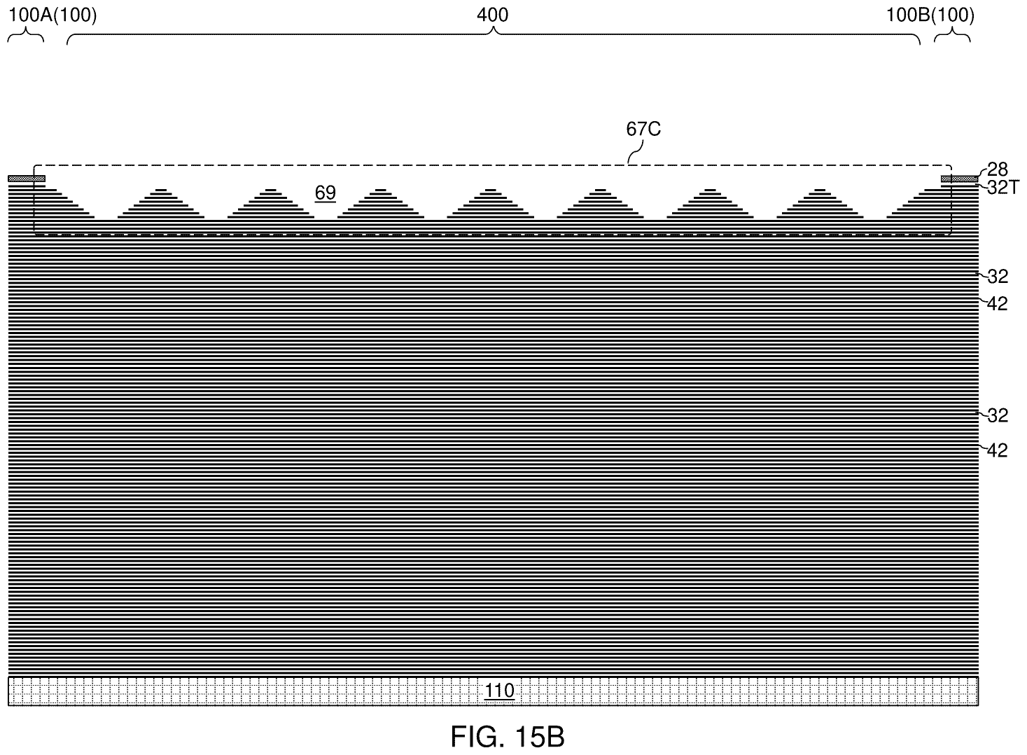

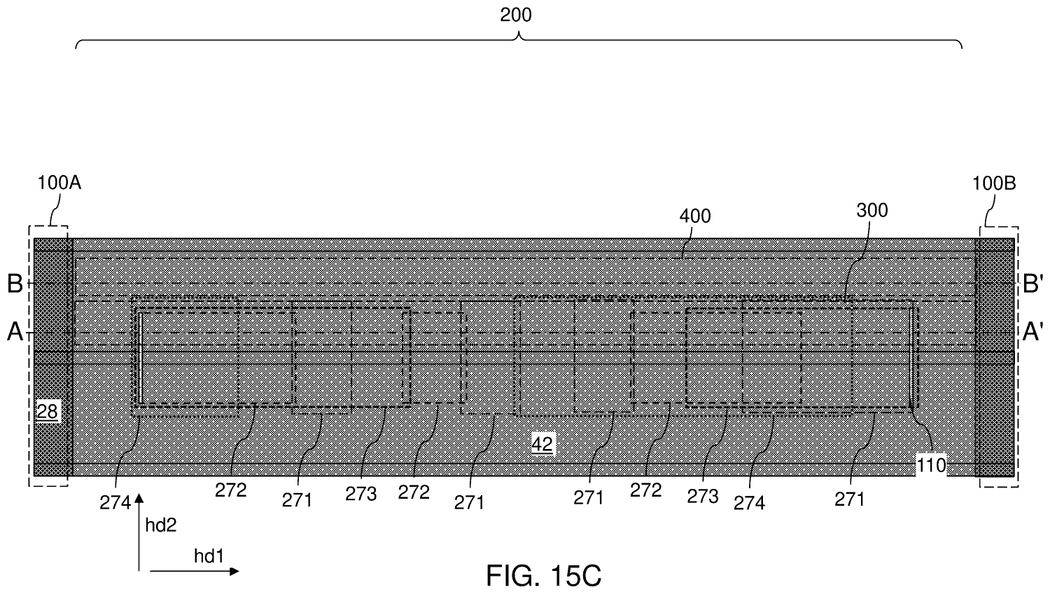

Referring to FIGS. 15A-15C, the processing steps described with reference to FIGS. 8A-8E can be performed to vertically recess the various staircase structures in the contact regions 300. A retro-stepped cavity 69 can be formed within each combination of a contact region 300 and a connection region 400. The retro-stepped cavities 69 and the staircase structures of the second configuration of the exemplary structure may be similar to the retro-stepped cavities 69 and the staircase structures of the first configuration of the exemplary structure except that surface segments of the semiconductor material layer may, or may not, be exposed to the retro-stepped cavities 69, and except that the staircase structures are laterally arranged with a uniform periodicity along the first horizontal direction hd1 (when viewed without regard to the height variations of the staircase structures).

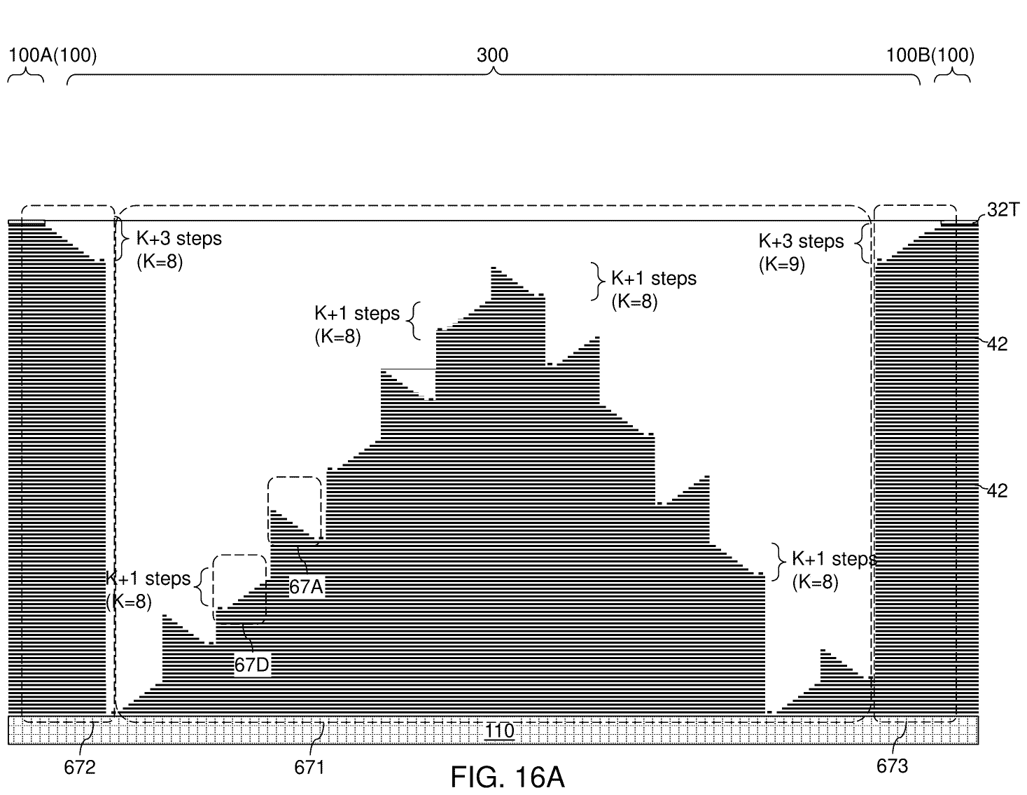

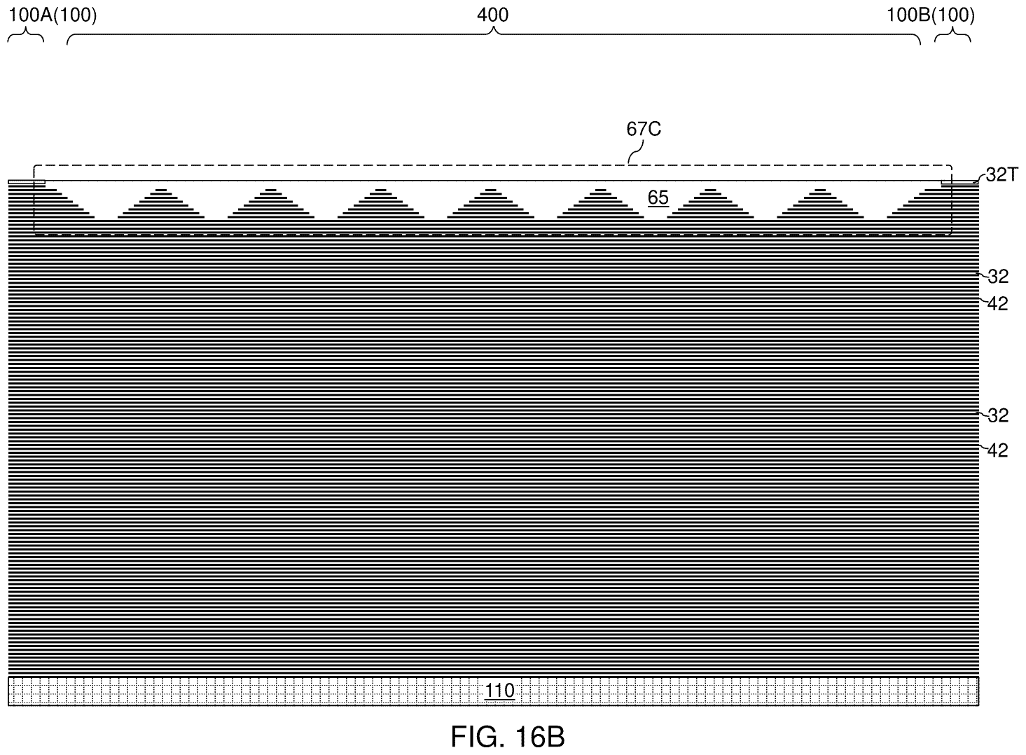

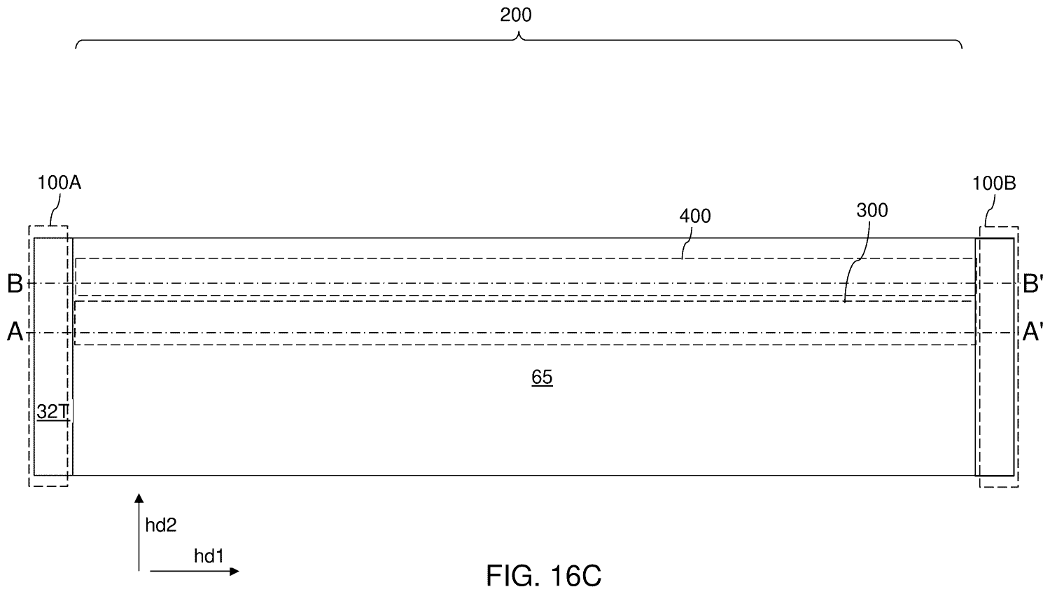

Referring to FIGS. 16A-16C, the processing steps described with reference to FIGS. 9A-9E can be performed to form retro-stepped dielectric material portions 65 and dielectric moat structures 165. A single retro-stepped dielectric material portion 65 may be formed within each inter-array region 200.

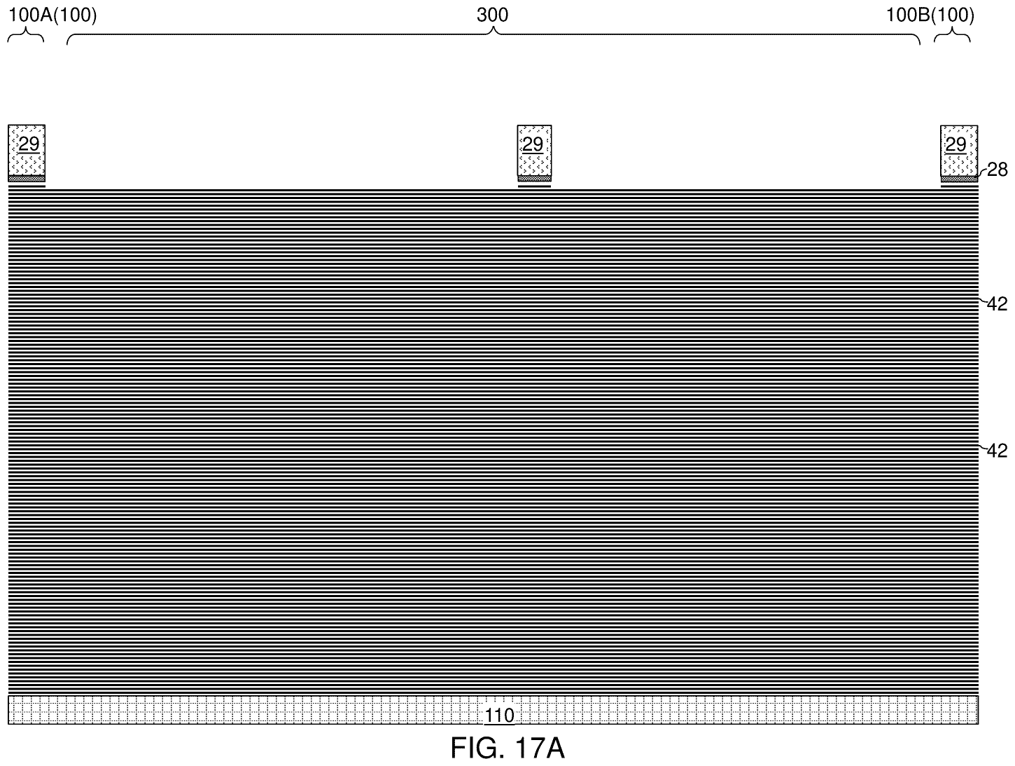

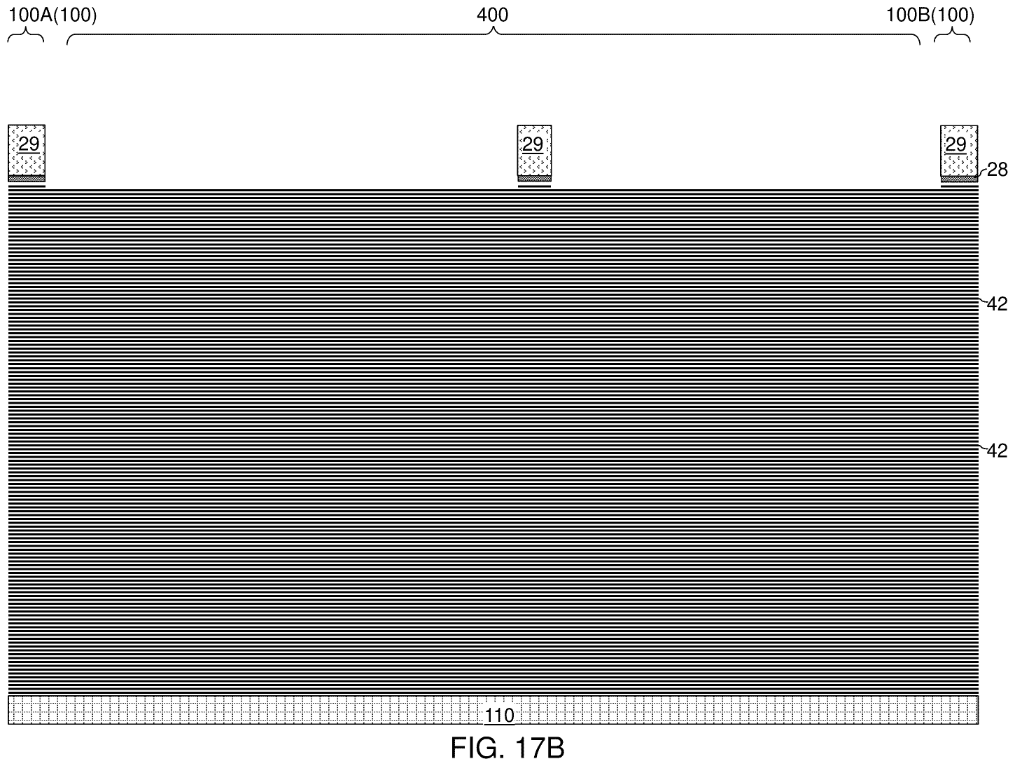

Referring to FIGS. 17A and 17B, a third configuration of the exemplary structure is illustrated after patterning the alternating stack (32, 42) employing a first patterned photoresist layer 29. The third configuration of the exemplary structure can be the same as the first configuration of the exemplary structure illustrated in FIGS. 3A-3E.

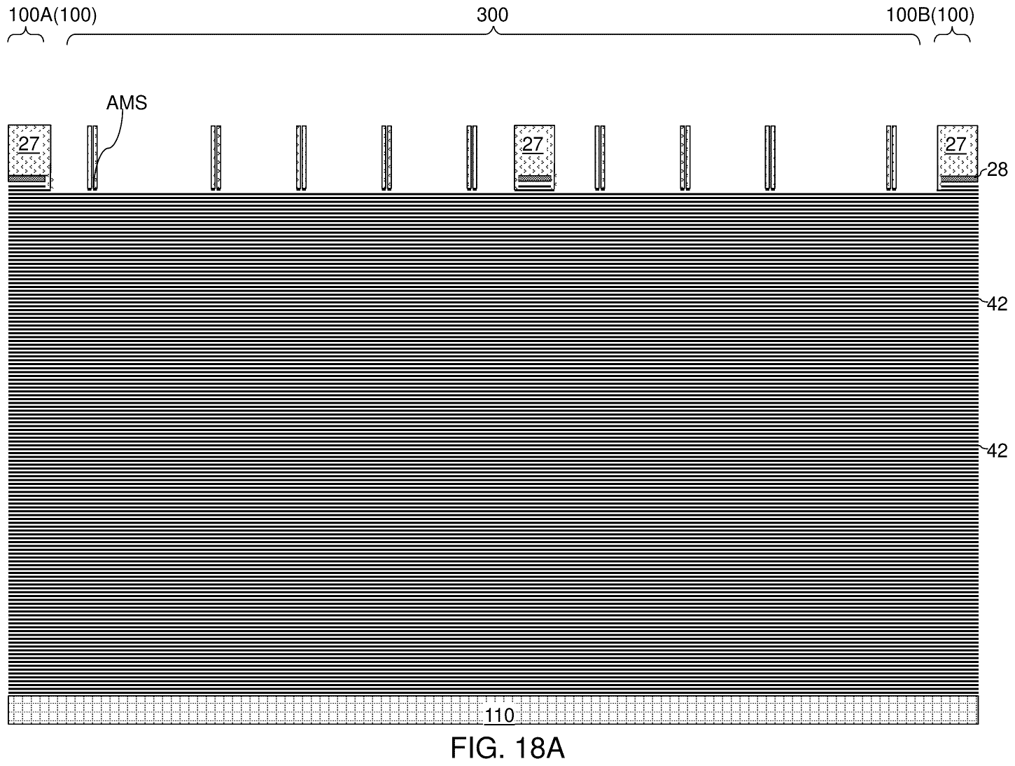

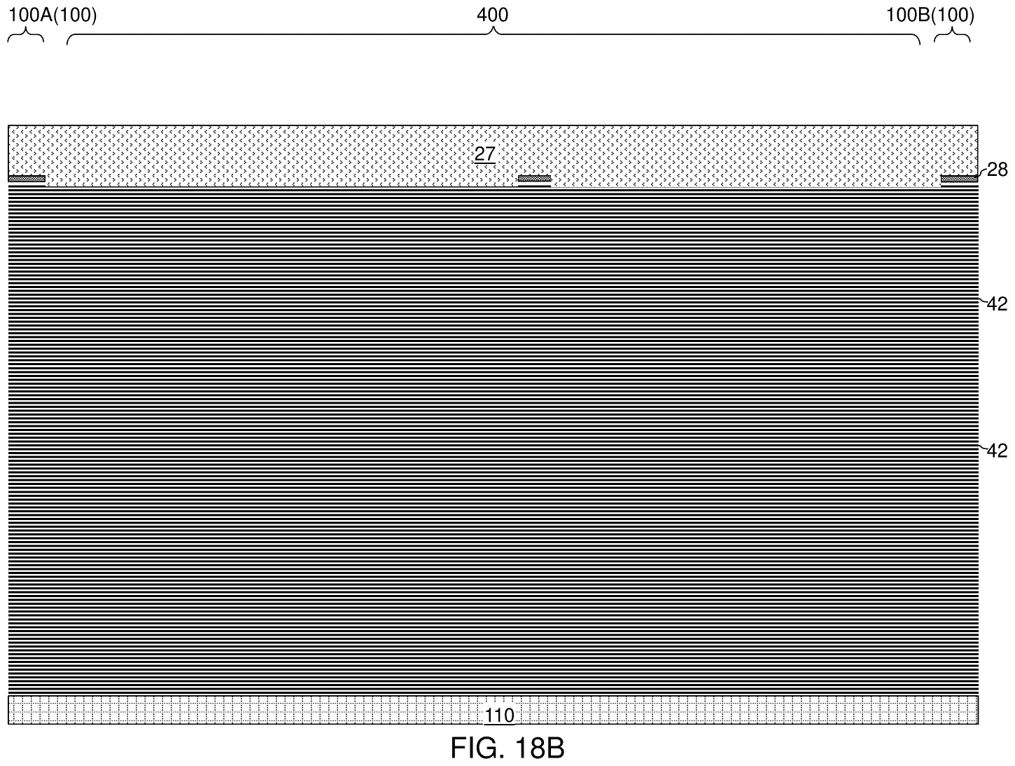

Referring to FIGS. 18A and 18B, the processing steps described with reference to FIGS. 4A-4E can be performed. The third configuration of the exemplary structure at the processing steps of FIGS. 18A and 18B may be the same as the first configuration of the exemplary structure described with reference to FIGS. 4A-4E.

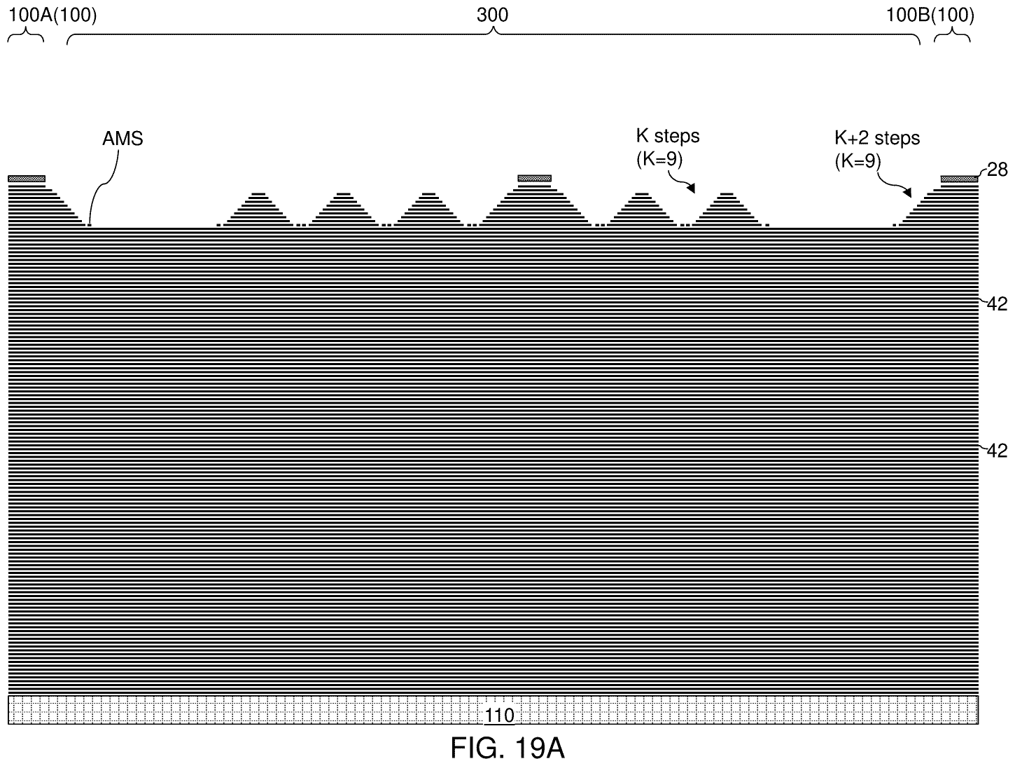

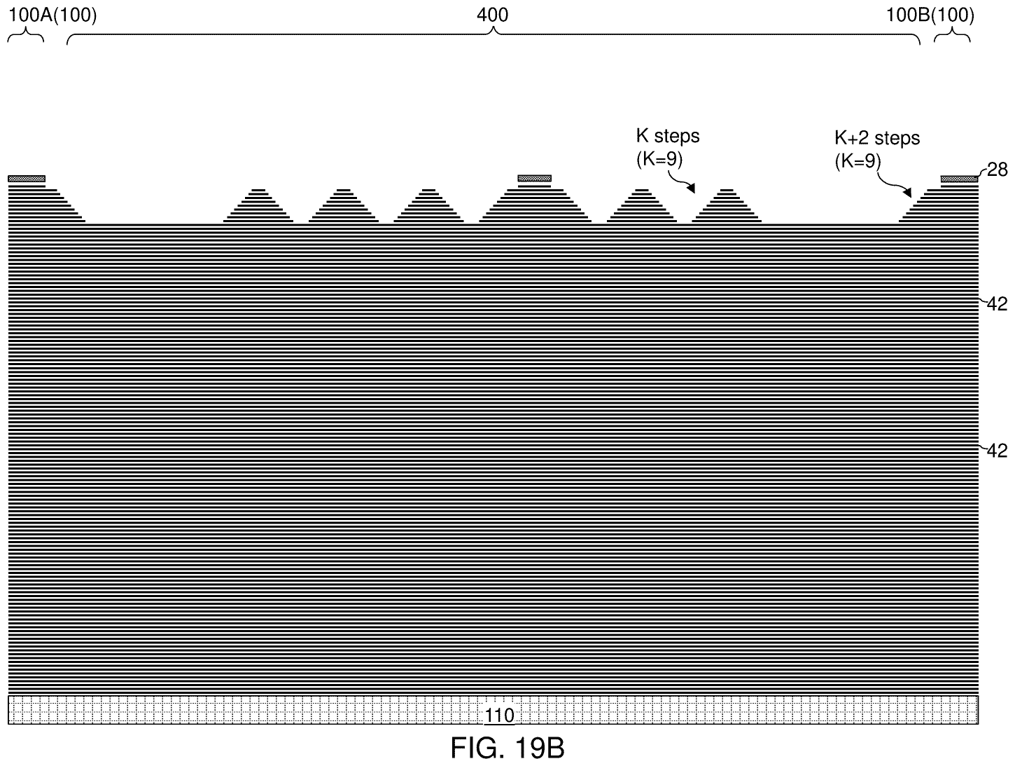

Referring to FIGS. 19A and 19B, the processing steps described with reference to FIGS. 5A-5E and 6A-6E can be performed. In the third configuration, the gap between neighboring pairs of patterned trimmable photoresist material portions 21 as formed prior to any anisotropic etch process may be not uniform.

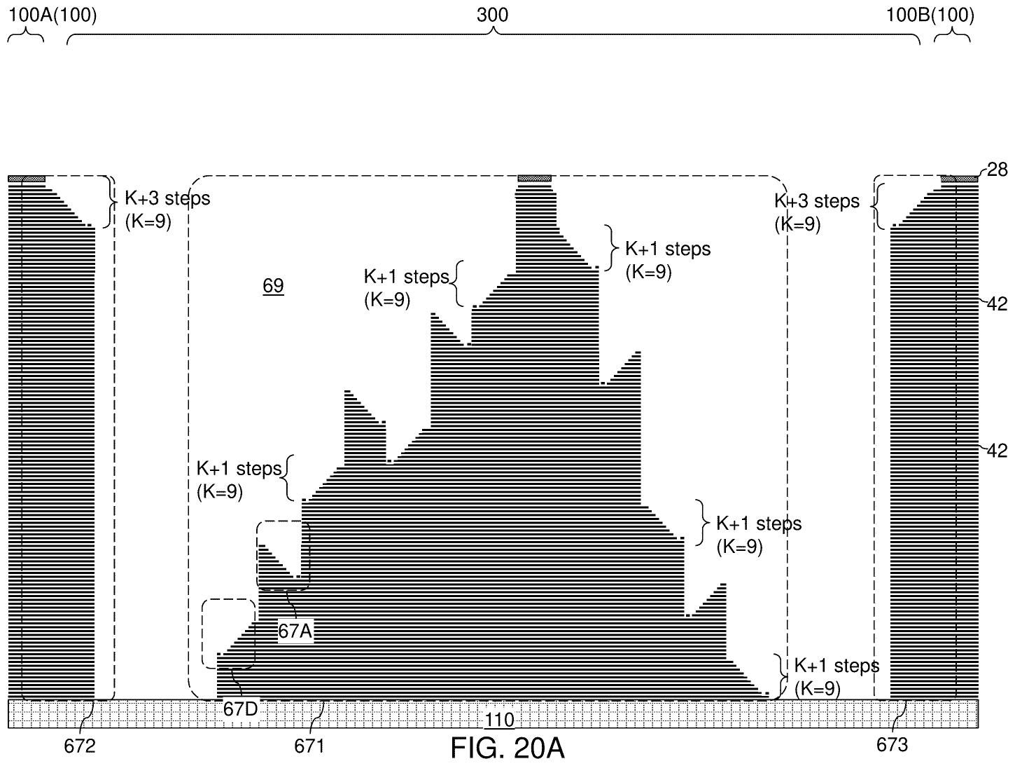

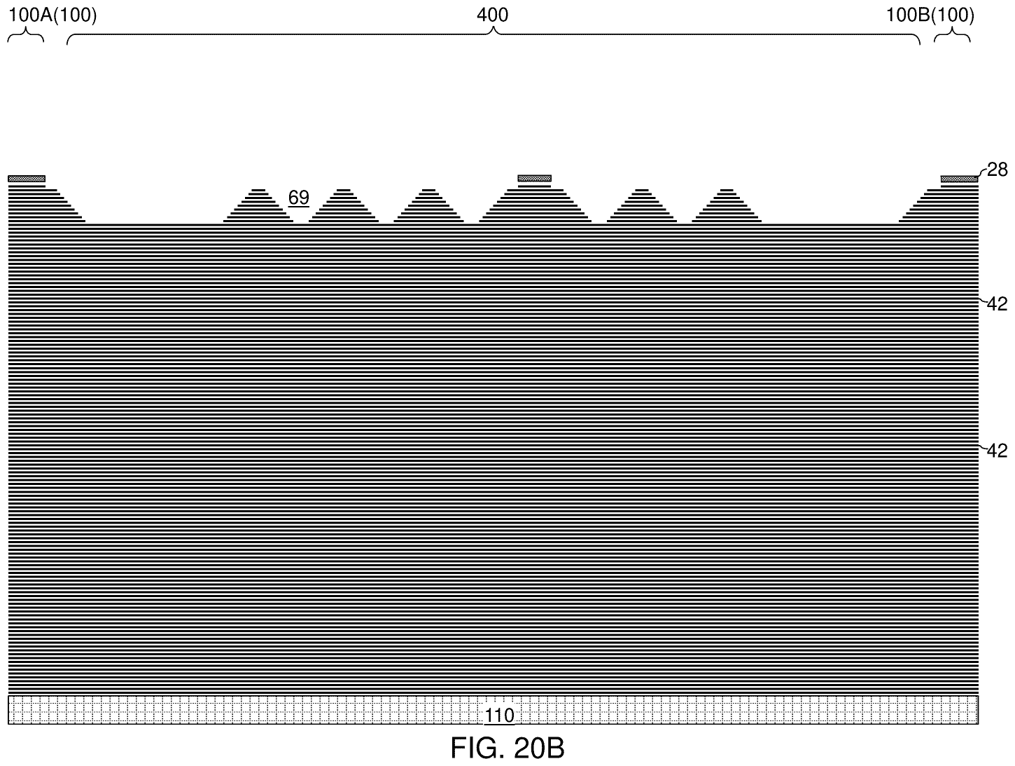

Referring to FIGS. 20A and 20B, the processing steps described with reference to FIGS. 7A-7E and 8A-8E can be performed to vertically recess the various staircase structures in the contact regions 300. A pair of retro-stepped cavities 69 can be formed within each combination of a contact region 300 and a connection region 400. The retro-stepped cavities 69 and the staircase structures of the third configuration of the exemplary structure may be similar to the retro-stepped cavities 69 and the staircase structures of the first configuration of the exemplary structure.

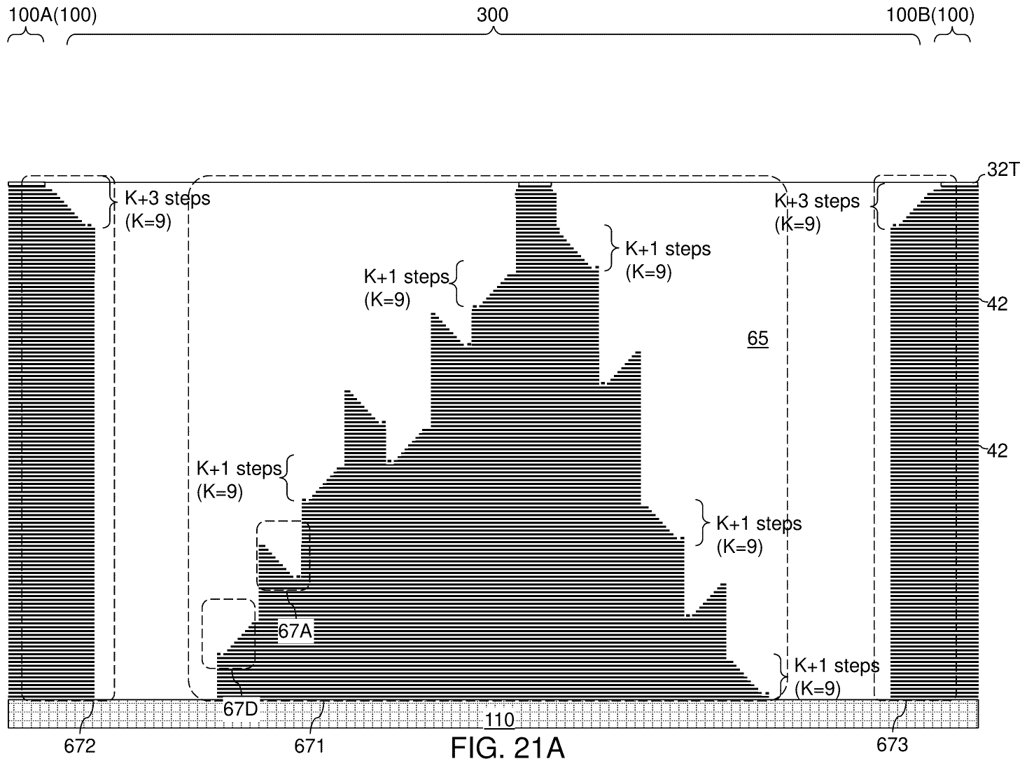

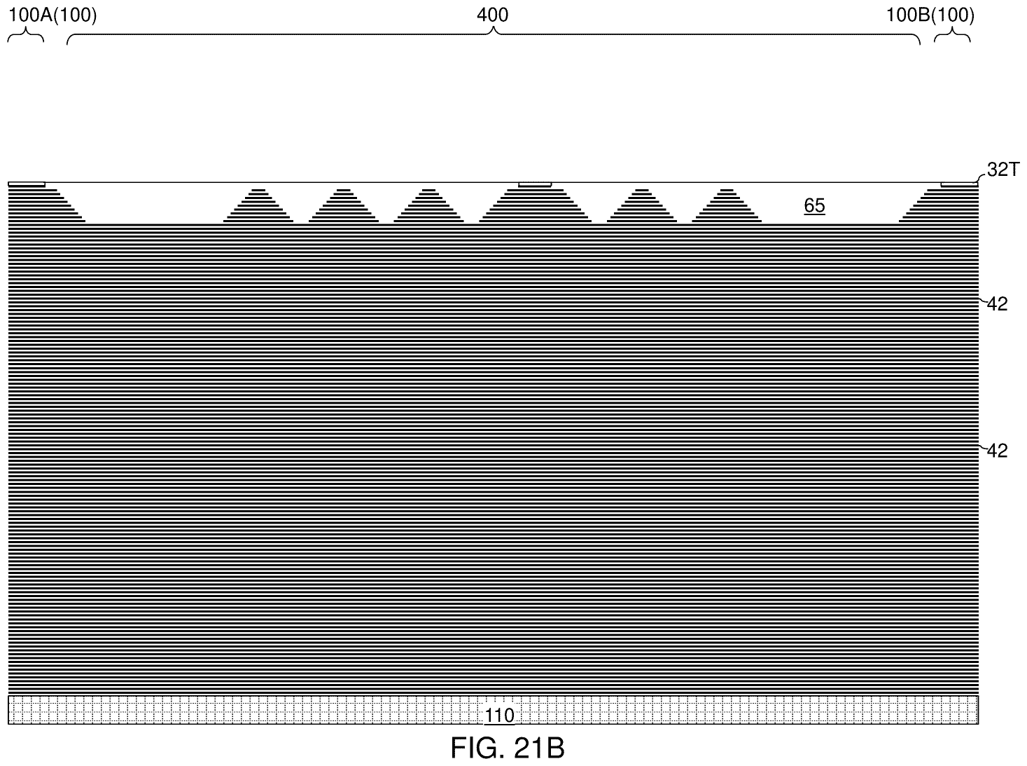

Referring to FIGS. 21A and 21B, the processing steps described with reference to FIGS. 9A-9E can be performed to form retro-stepped dielectric material portions 65 and dielectric moat structures 165. Two retro-stepped dielectric material portion 65 may be formed within each inter-array region 200.

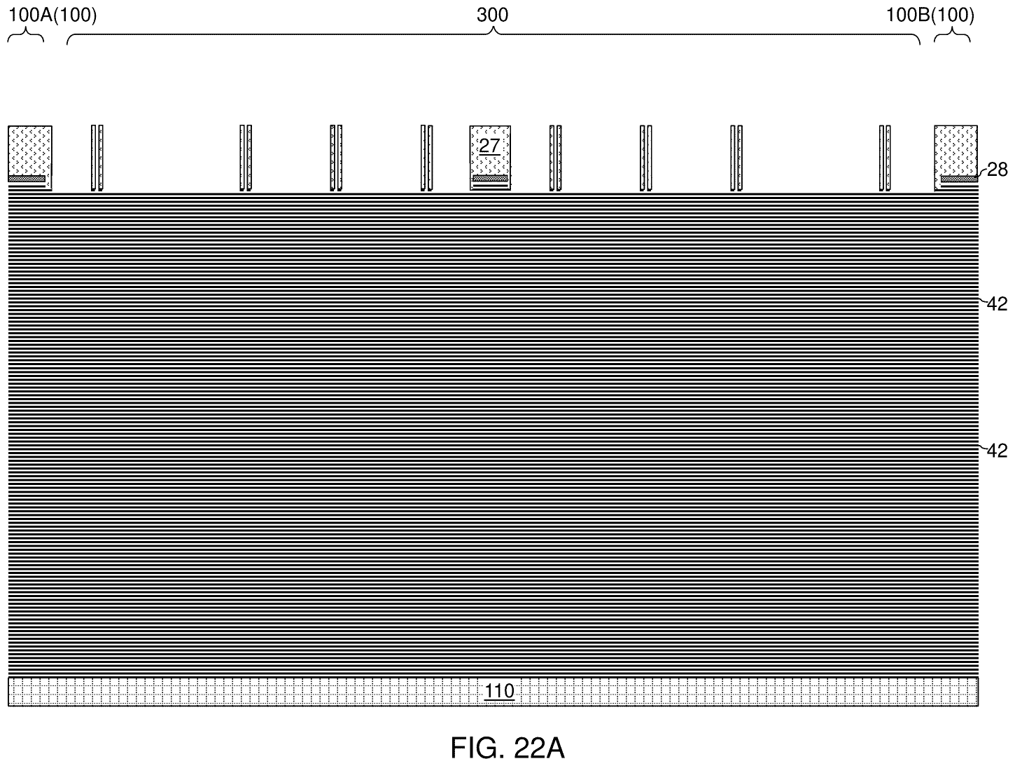

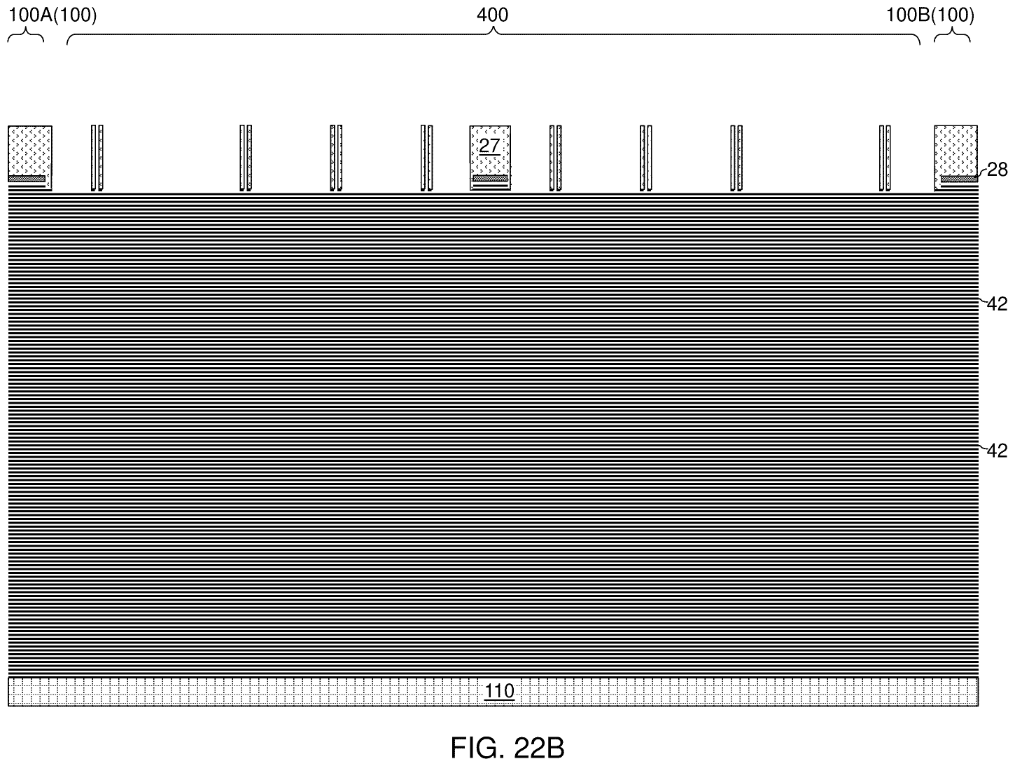

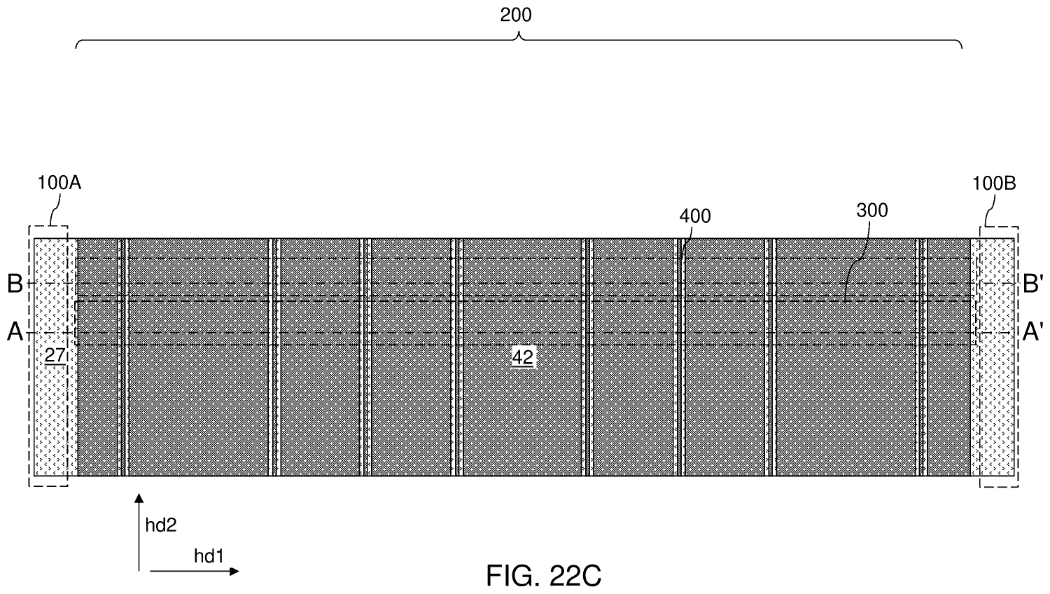

Referring to FIGS. 22A-22C, a fourth configuration of the exemplary structure is illustrated after patterning the alternating stack (32, 42) employing a second patterned photoresist layer 27. The fourth configuration of the exemplary structure can be derived from the first configuration of the exemplary structure illustrated in FIGS. 4A-4E by modifying the pattern of the second patterned photoresist layer 27. Specifically, the pattern of the second patterned photoresist layer 27 in the entirety of the inter-array regions 200 in the fourth configuration of the exemplary structure may be the same as the pattern of the second patterned photoresist layer 27 in a contact region 300 in the first configuration of the exemplary structure described with reference to FIGS. 4A-4E. Accordingly, the pattern of the second patterned photoresist layer 27 in the connection regions 400 in the fourth configuration of the exemplary structure can be the same as the pattern of the second patterned photoresist layer 27 in the contact regions 300 in the fourth configuration of the exemplary structure. In other words, the second patterned photoresist layer 27 is used to form the scales AMS without covering the connection regions 400.

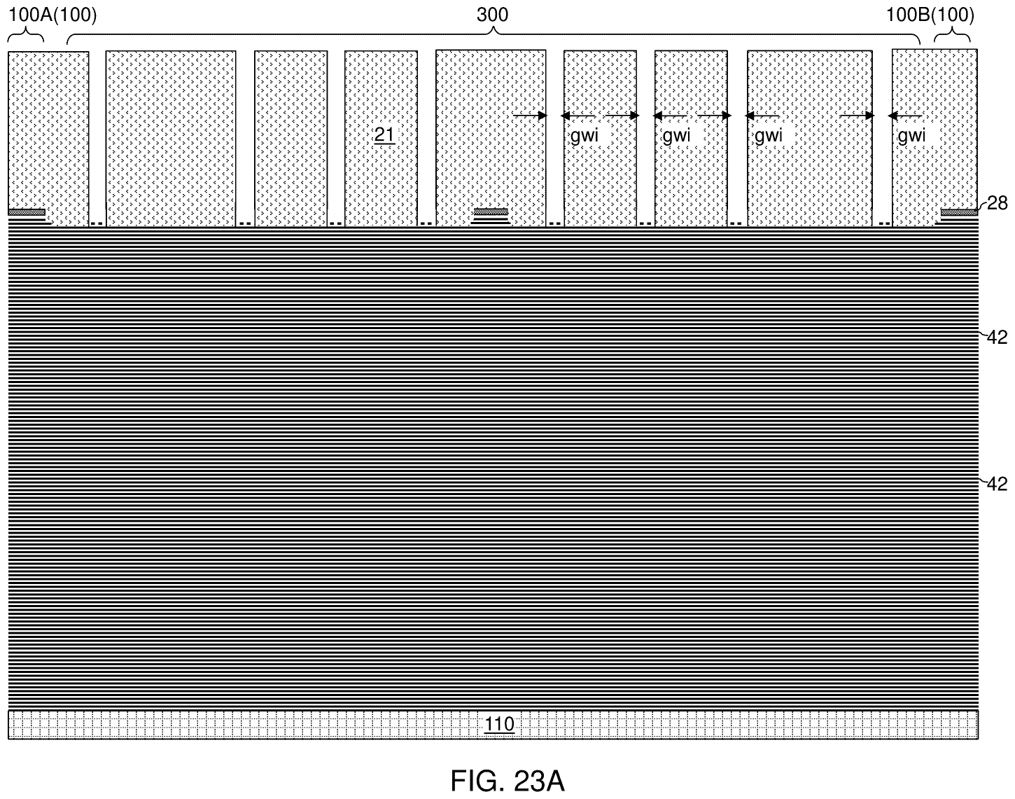

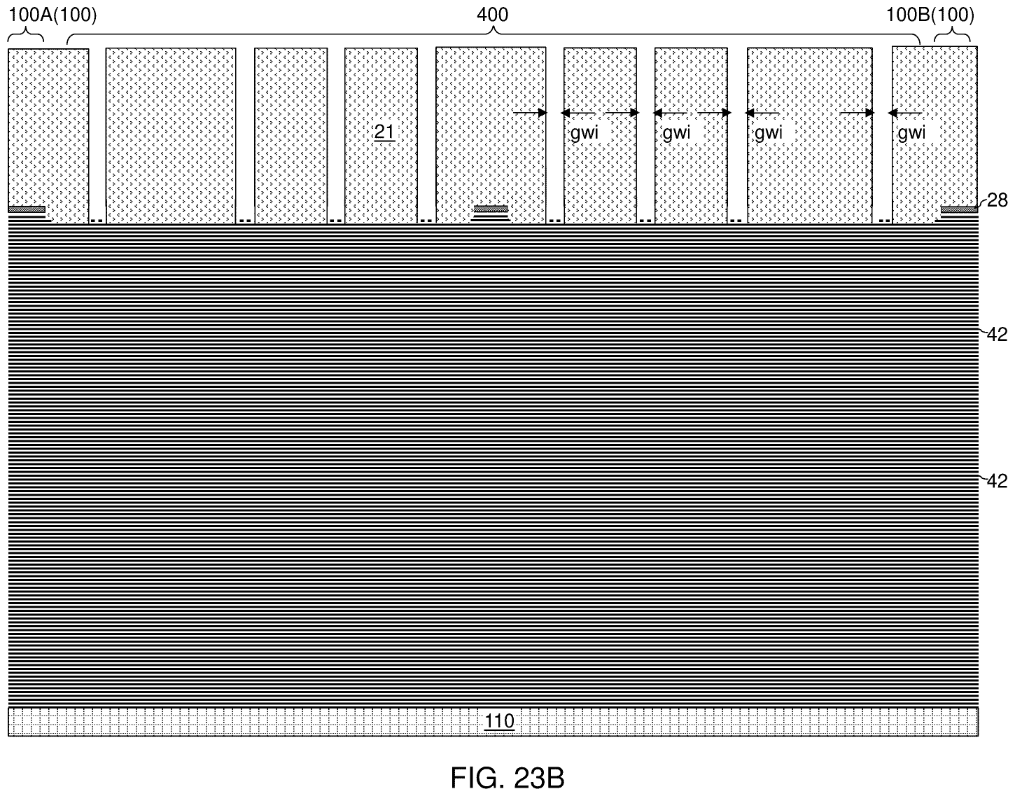

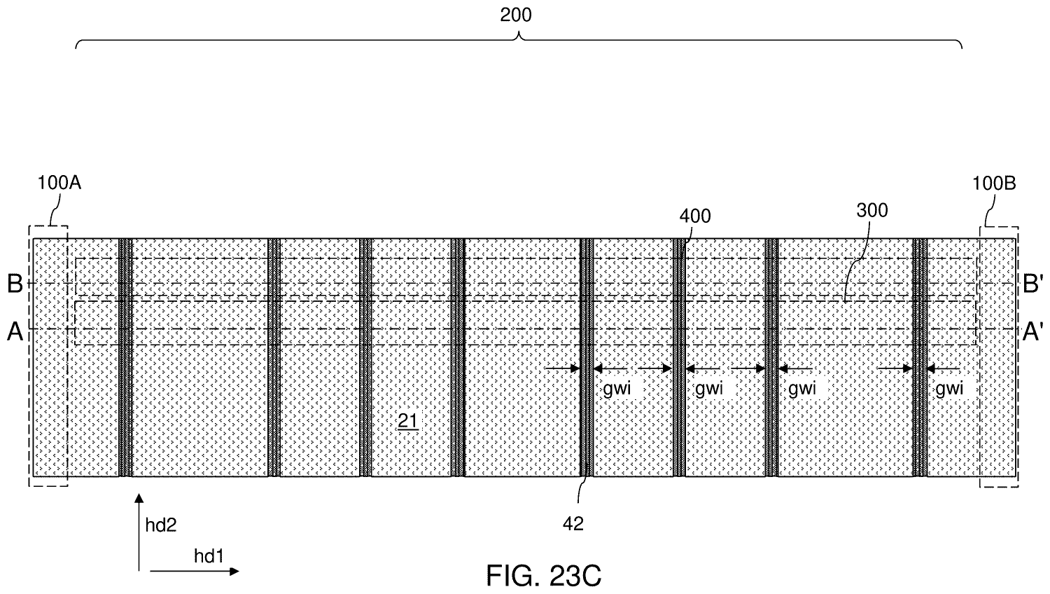

Referring to FIGS. 23A-23C, the processing steps described with reference to FIGS. 5A-5E can be performed. The pattern of the patterned trimmable photoresist material portions 21 may be the same in the first configuration of the exemplary structure. As discussed above, patterned trimmable photoresist material portions 21 may cover the entirety of the memory array regions 100 and the kerf regions 2000, and may have straight edges that laterally extend through inter-array regions 200 within the area of a respective semiconductor die 1000.

In this embodiment, each neighboring pair of trimmable photoresist material portions 21 of the trimmable photoresist material portions 21 overlying a respective semiconductor die 1000 may be laterally spaced from each other along the first horizontal direction hd1 by a respective gap having a same initial gap width gwi that is invariant along the second horizontal direction hd2. As in the first exemplary structure. In one embodiment, the locations of the gaps between each neighboring pair of trimmable photoresist material portions 21 can be selected such that a pair of alignment mark strips AMS is located entirely within the area of an overlying gap.

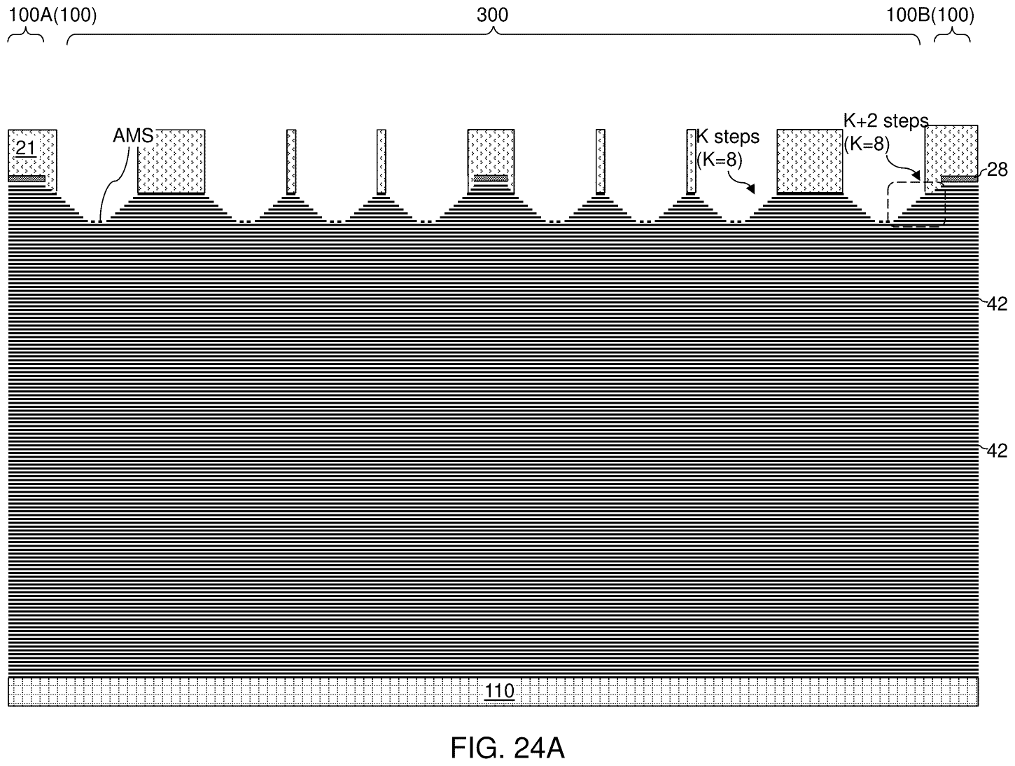

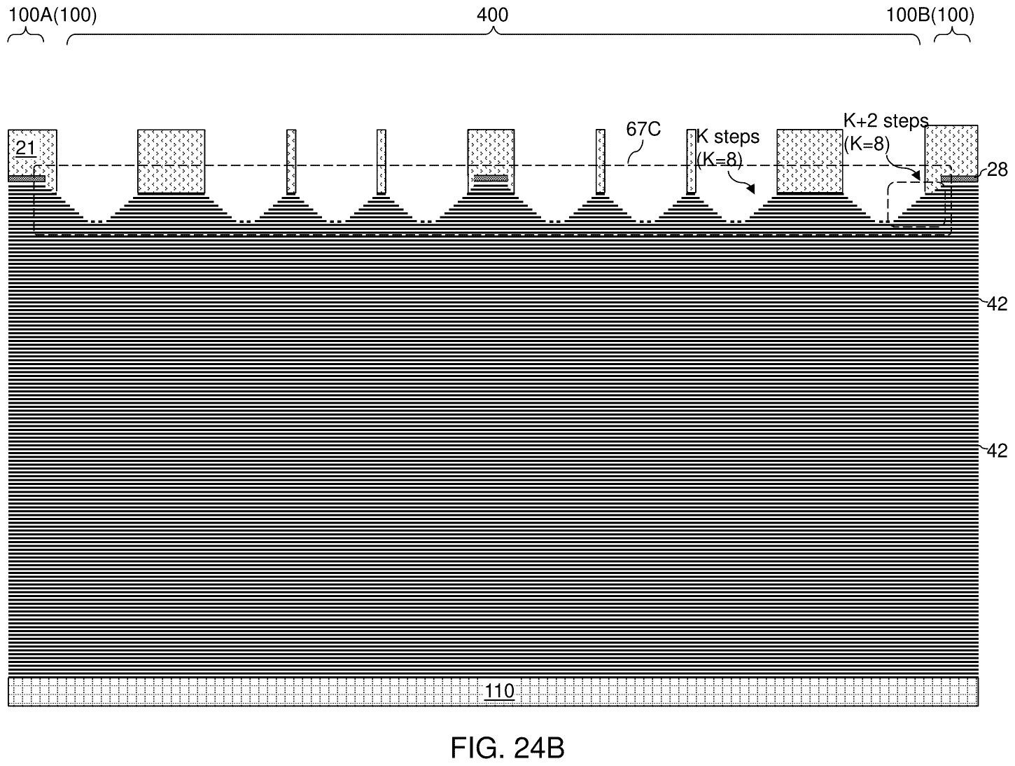

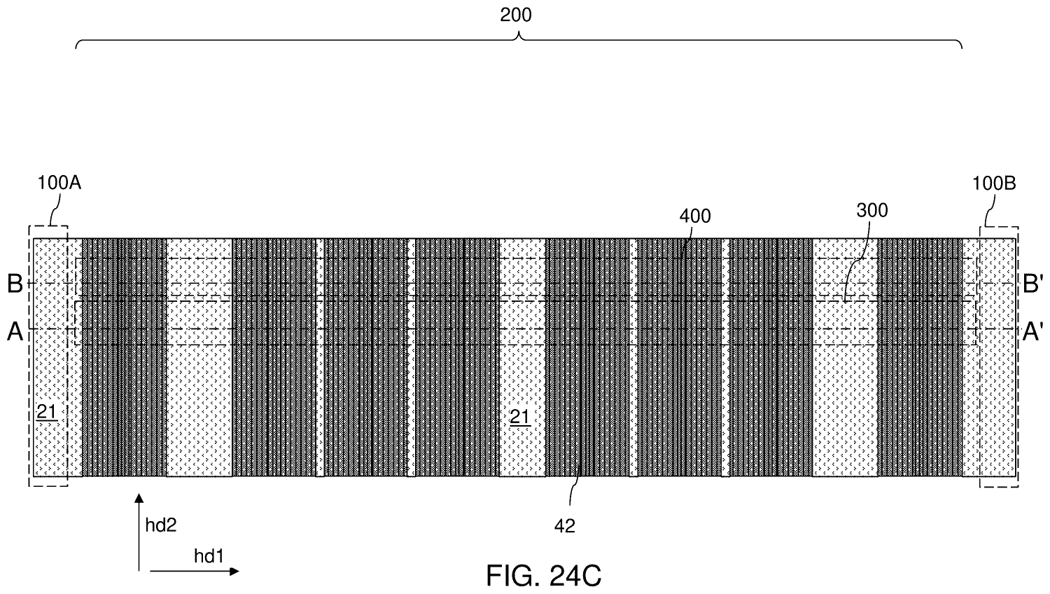

Referring to FIGS. 24A-24C, the processing steps described with reference to FIGS. 6A-6E can be performed. Thus, a set of processing steps that include K anisotropic etch processes interlaced with (K−1) photoresist trimming processes can be performed. K is an integer greater than 2. In one embodiment, the value of the integer K may be in a range from 3 to 16, such as from 4 to 12, although lesser and greater values may also be employed. In one embodiment, a combination of processing steps including an anisotropic etch step and a photoresist trimming step may be repeated (K−1) times, and a terminal anisotropic etch process may be subsequently performed to provide the K anisotropic etch processes and the (K−1) photoresist trimming processes.

The staircase structures comprise contact-region staircase structures that are formed in the contact regions 300, and connection-region staircase structures 67C that are formed in the connection regions 400. Each staircase structure comprises K vertically-extending surface segments. In one embodiment, each staircase structure located in a contact region 300 and laterally spaced from that are distal from the hard mask layer 28 by at least one alignment mark strip AMS may consist of K vertically-extending surface segments and (K+1) horizontally-extending surface segments. Such staircase structures are herein referred to as first-type contact-region staircase structures. Each staircase structure located in a contact region 300 and is more proximal to the hard mask layer 28 than any alignment mark strip AMS may include (K+2) vertically-extending surface segments (“K+2 steps”) and (K+3) horizontally-extending surface segments. Such staircase structures are herein referred to as second-type contact-region staircase structures. In one embodiment, each staircase structure located in a connection region 400 and laterally offset from a first-type contact-region staircase structure along the second horizontal direction hd2 may consist of K vertically-extending surface segments and (K+1) horizontally-extending surface segments. Such staircase structures are herein referred to as first-type connection-region staircase structures. Each staircase structure located in a connection region 400 and laterally offset from a second-type contact-region staircase structure along the second horizontal direction hd2 may include (K+2) vertically-extending surface segments and (K+3) horizontally-extending surface segments. Such staircase structures are herein referred to as second-type connection-region staircase structures. The trimmable photoresist material portions 21 can be subsequently removed, for example, by ashing.

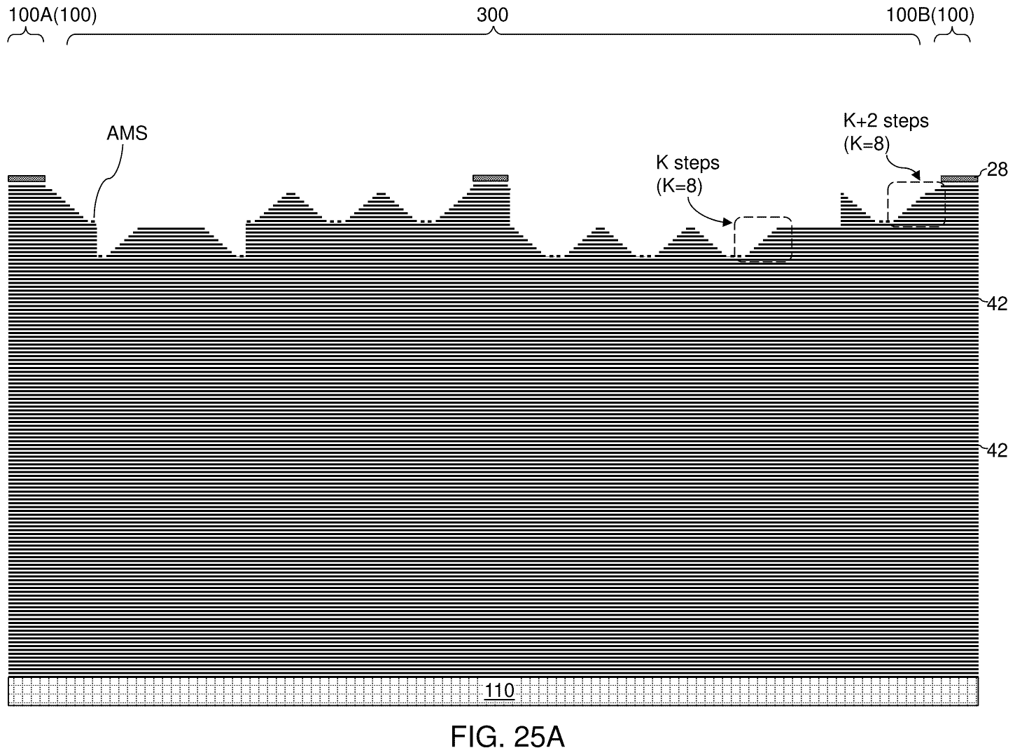

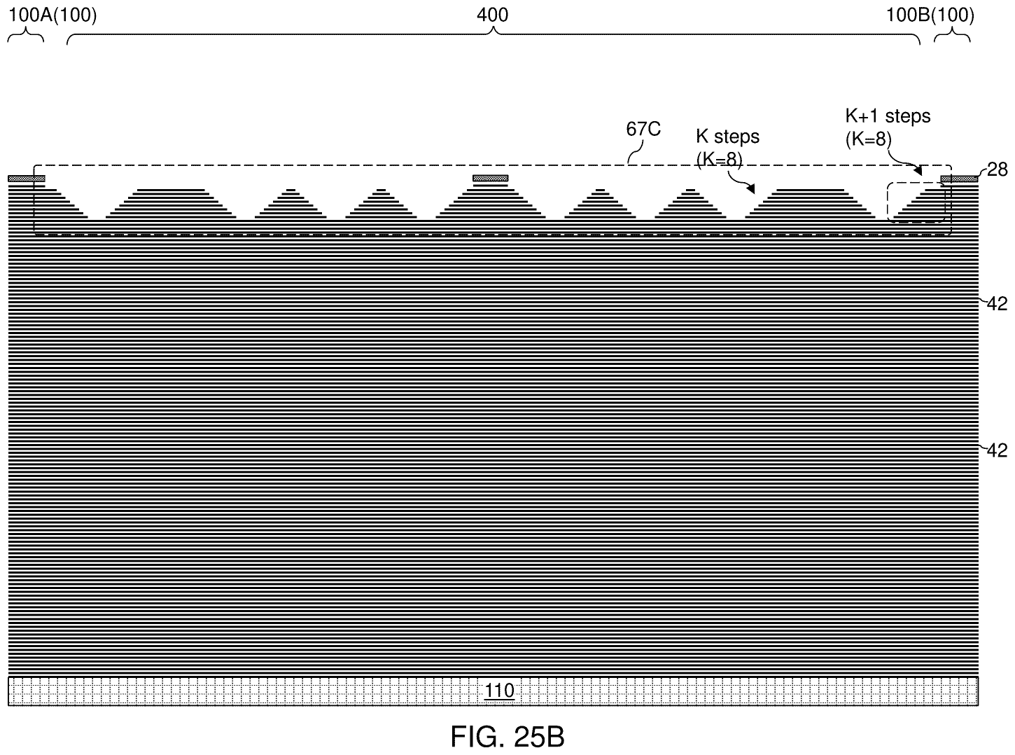

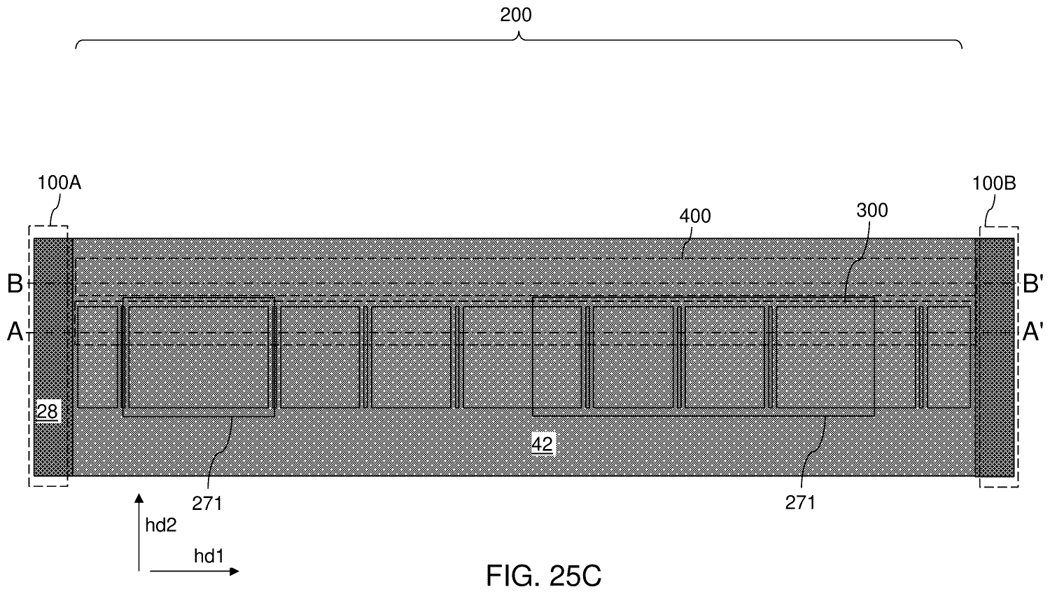

Referring to FIGS. 25A-25C, the processing steps described with reference to FIGS. 7A-7E can be performed. Thus, a first masked vertical recess process can be performed to vertically recess the unmasked portions of the alternating stack (32, 42) by a first vertical recess distance. The first masked vertical recess process may comprise an anisotropic etch process that etches (K+1) pairs of an insulating layers 32 and a sacrificial material layer 42. The anisotropic etch process may comprise a reactive ion etch process. Unmasked portions of the alternating stack (32, 42) can be vertically recessed by the first vertical recess distance, which may be (K+1) times the sum of a thickness of an insulating layer 32 and a thickness of a sacrificial material layer 42. The first complementary subset of the contact-region staircase structures can be vertically recessed by the first vertical recess distance, while the first primary subset of the contact-region staircase structures is not vertically recessed. A moat cavity 169 (See FIG. 7E) can be formed in each boundary region at the peripheries of the semiconductor dies 1000. The first mask-level photoresist layer can be subsequently removed, for example, by ashing.

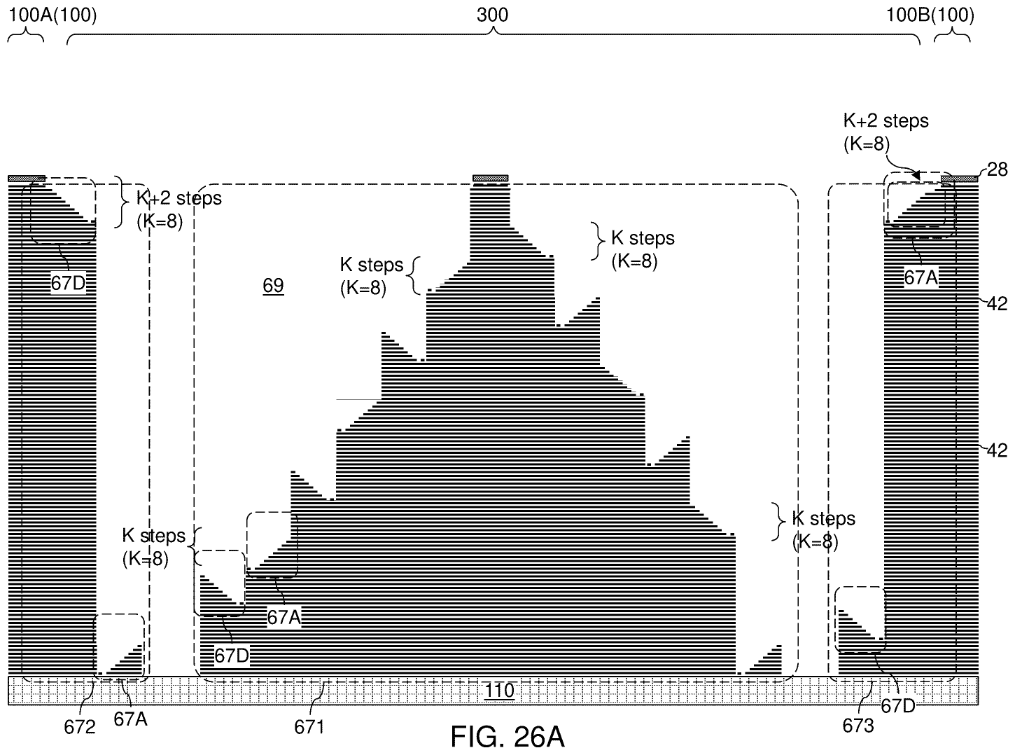

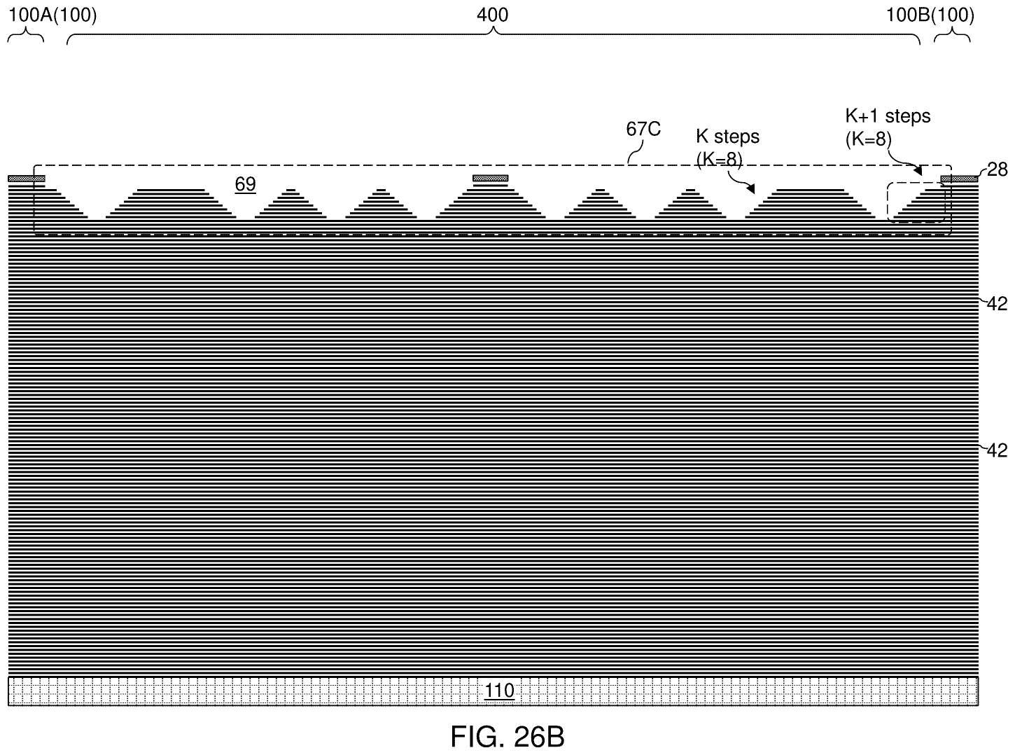

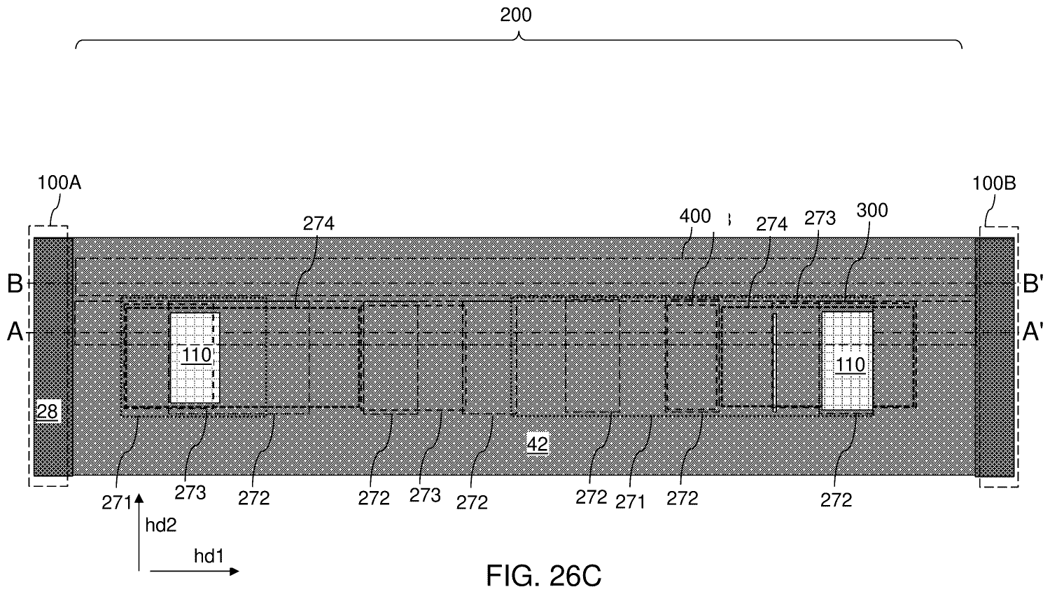

Referring to FIGS. 26A-26C, the processing steps described with reference to FIGS. 8A-8E can be performed to vertically recess the various staircase structures in the contact regions 300. A pair of retro-stepped cavities 69 can be formed within each combination of a contact region 300 and a connection region 400.

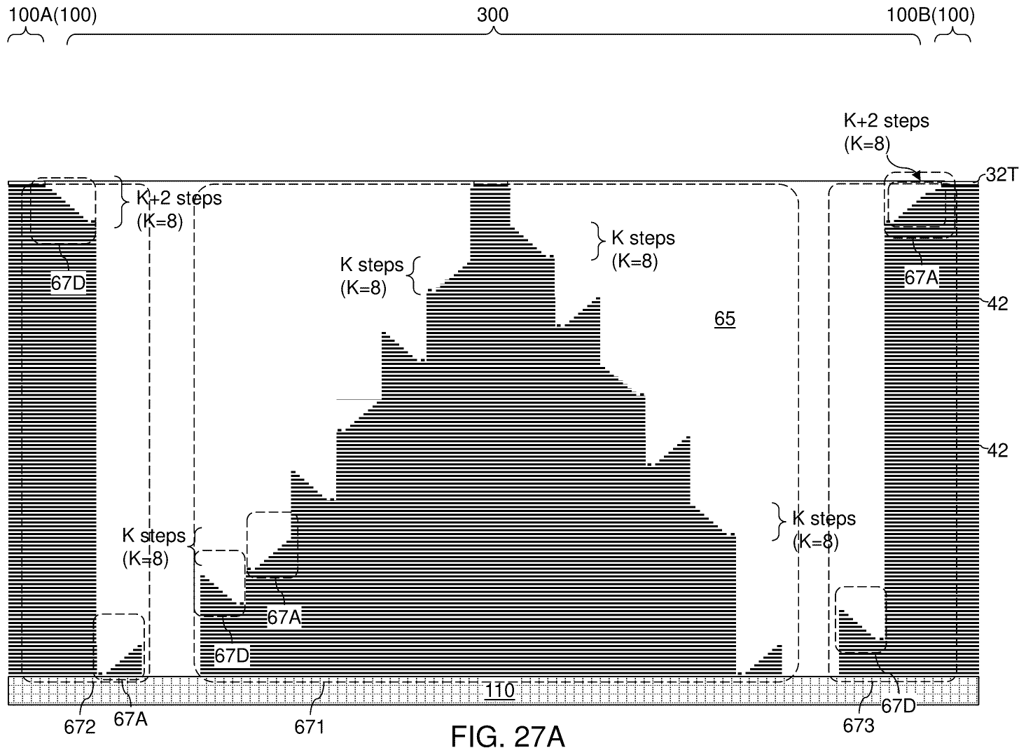

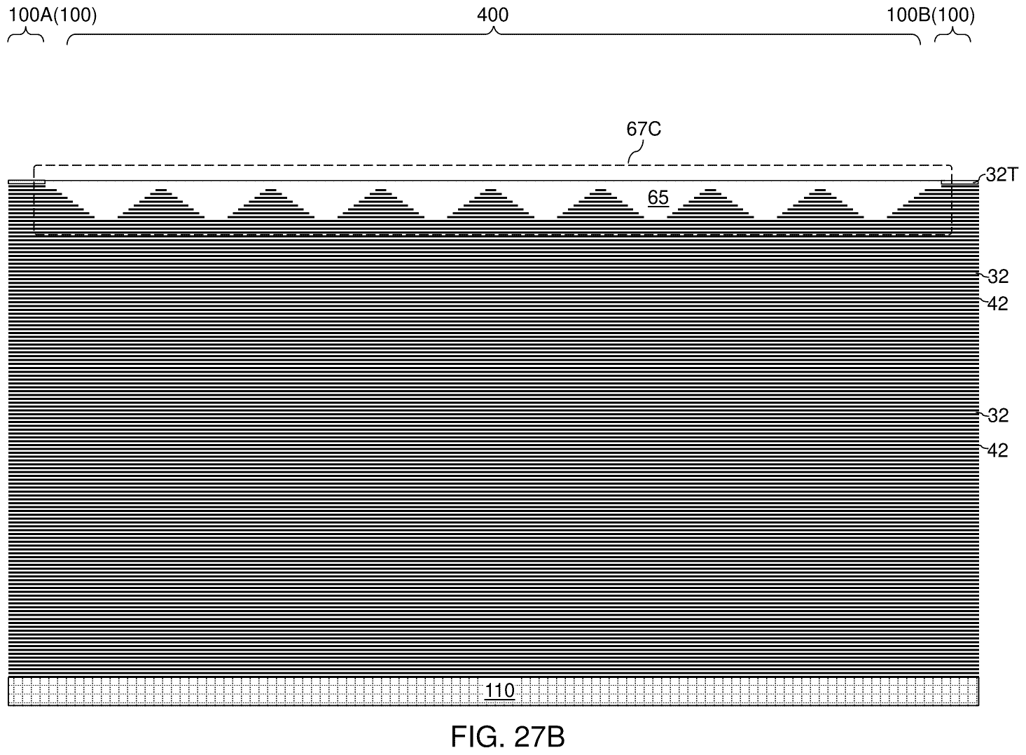

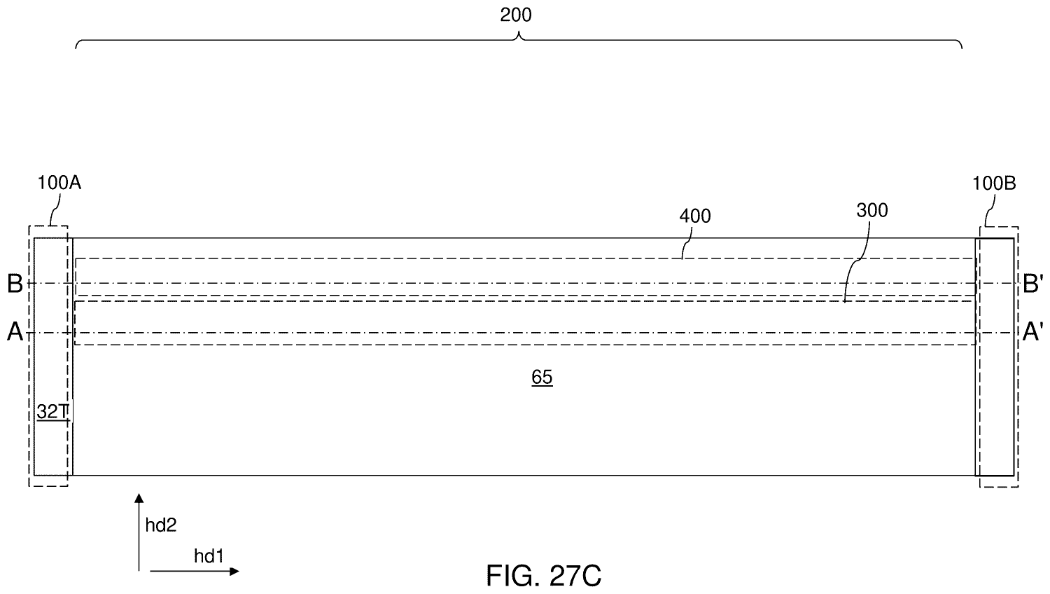

Referring to FIGS. 27A-27C, the processing steps described with reference to FIGS. 9A-9E can be performed to form retro-stepped dielectric material portions 65 and dielectric moat structures 165. A pair of retro-stepped dielectric material portions 65 may be formed within each inter-array region 200.

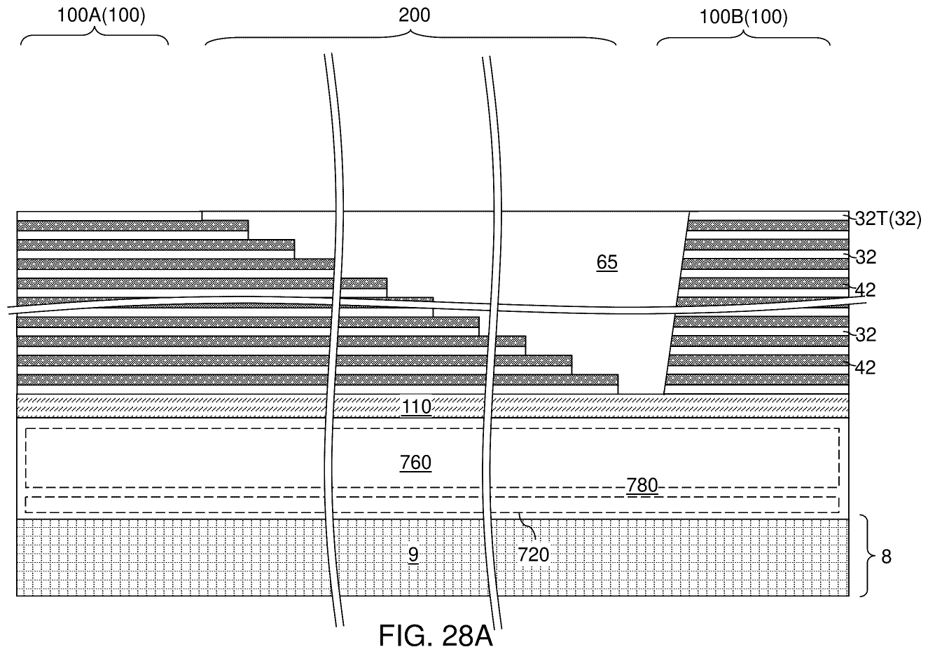

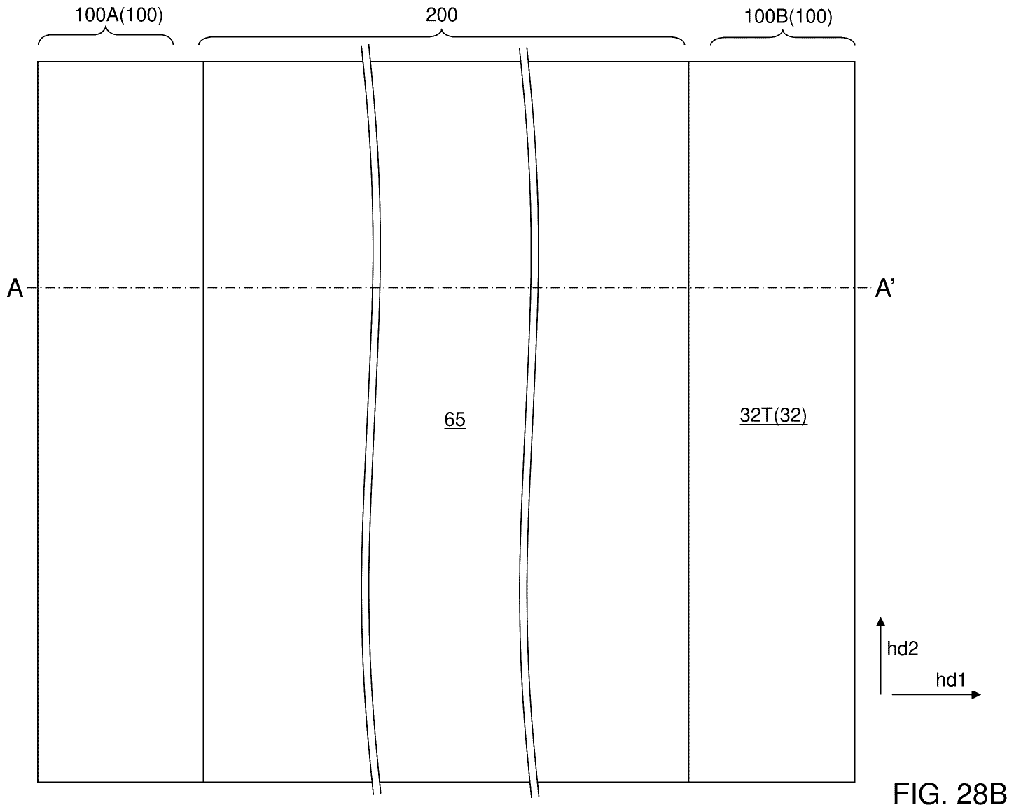

Referring to FIGS. 28A and 28B, the exemplary structure is illustrated after formation of the retro-stepped dielectric material portions 65 and dielectric moat structures 165. The exemplary structure illustrated in FIGS. 28A and 28B may have any of the configurations of the exemplary structure as described with reference to FIGS. 9A-9E, 16A 16C, 21A and 21B, or 27A-27C.

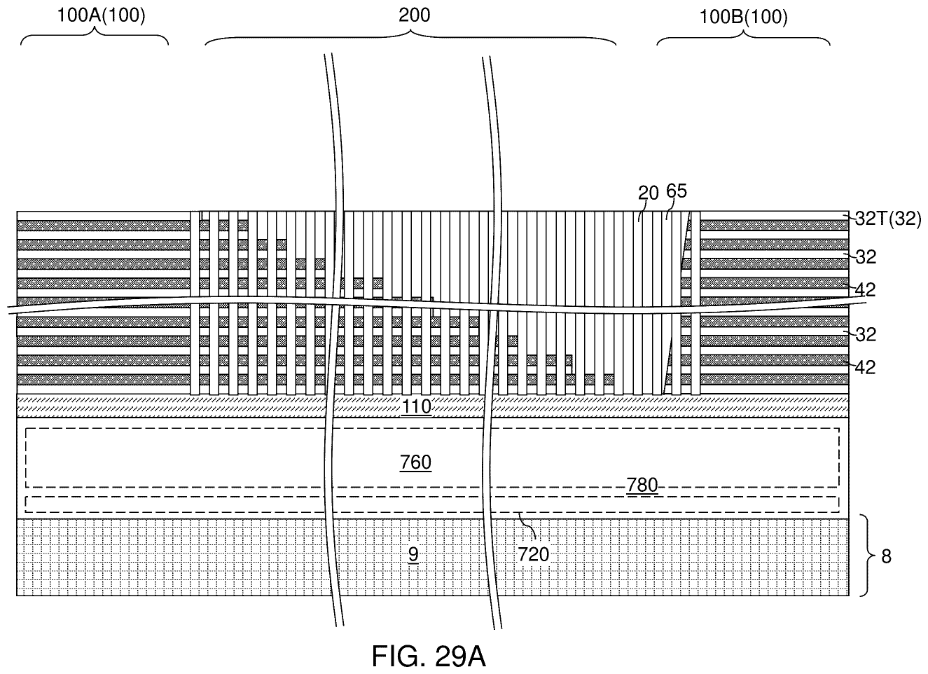

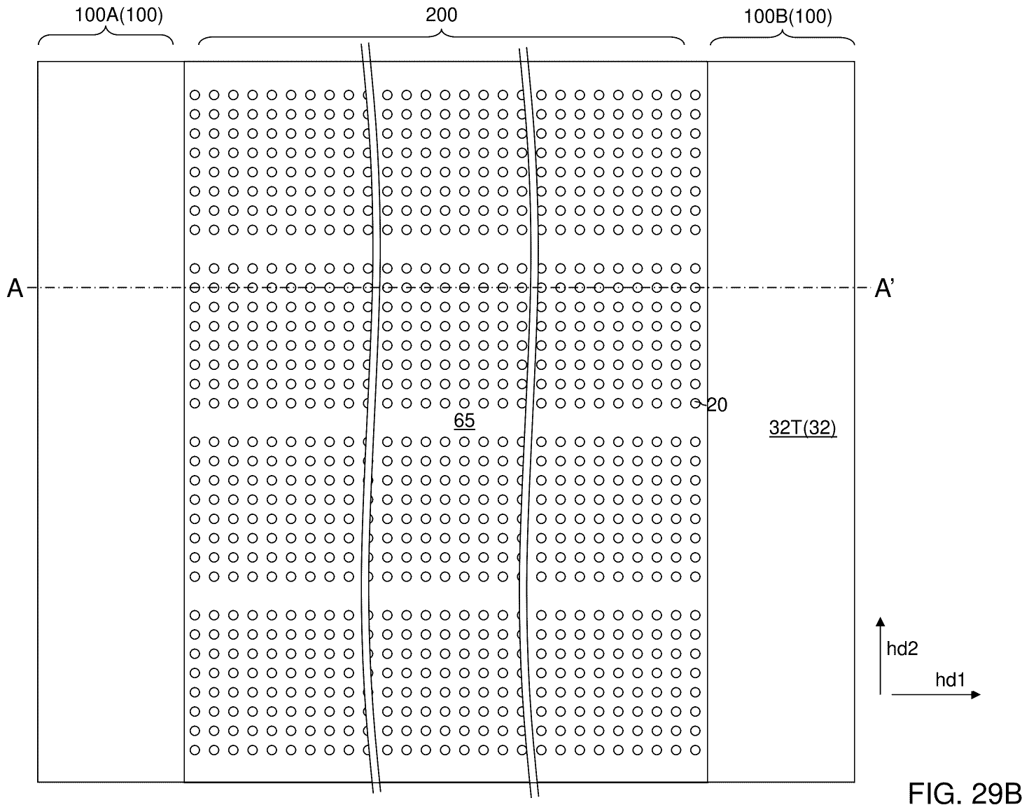

Referring to FIGS. 29A and 29B, a photoresist layer (not shown) can be applied over the alternating stack (32, 42) and the retro-stepped dielectric material portions 65, and can be lithographically patterned to form arrays of openings in the contact regions 200. An anisotropic etch process can be performed to transfer the pattern of the opening in the photoresist layer through the retro-stepped dielectric material portions 65 and the alternating stack (32, 42) to form optional support openings in the contact regions 200. Each of the support openings may vertically extend from the horizontal plane including the topmost surface of the alternating stack (32, 42) at least to the horizontal plane including the bottommost surface of the alternating stack (32, 42), and optionally into an upper portion of the semiconductor material layer 110. The photoresist layer can be subsequently removed, for example, by ashing.

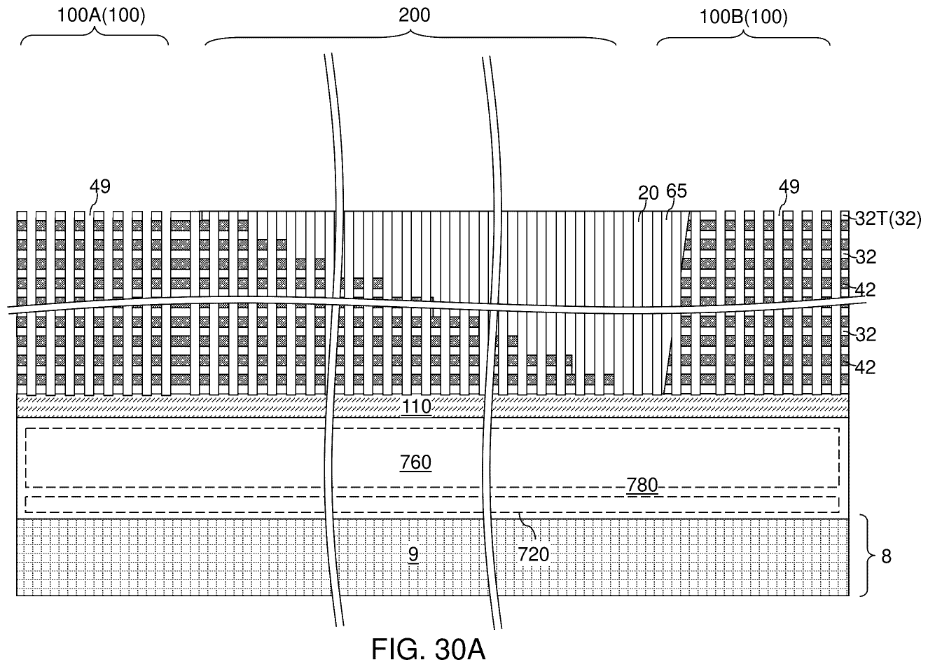

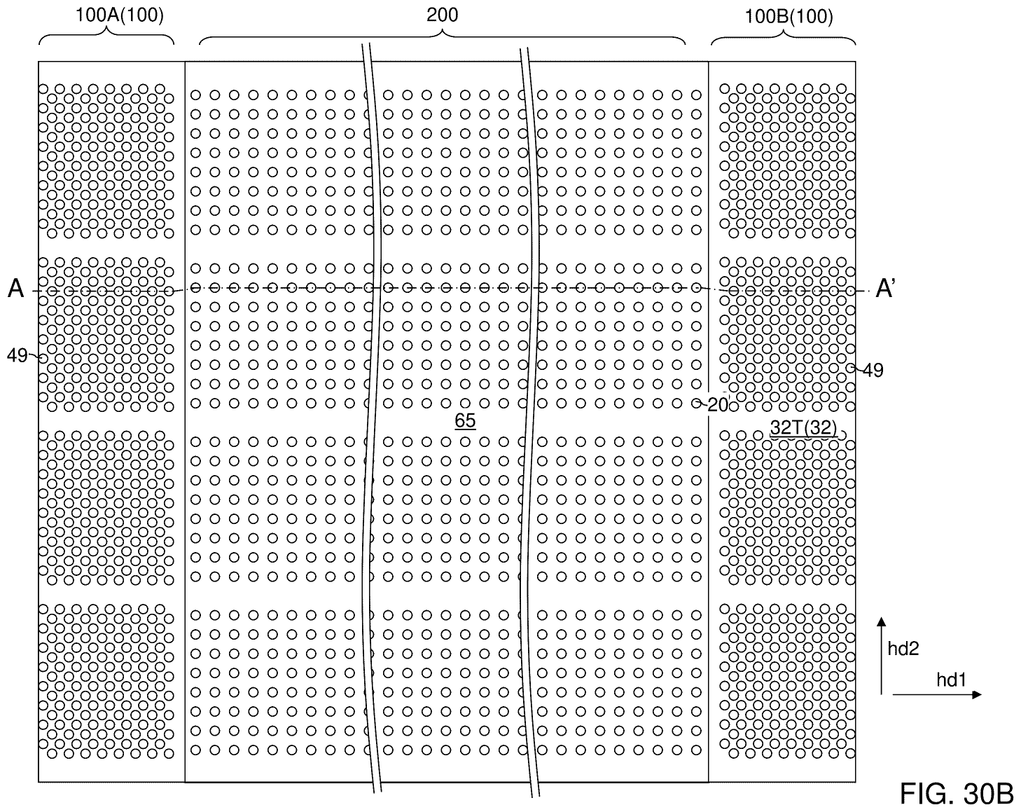

At least one dielectric fill material, such as undoped silicate glass (i.e., silicon oxide) and/or a doped silicate glass can optionally be deposited in the support openings. Excess portions of the at least one dielectric fill material can be removed from above the horizontal plane including the top surface of the topmost insulating layer 32T and the retro-stepped dielectric material portions 65 by a planarization process, which may employ a recess etch process. Remaining portions of the at least one dielectric fill material constitutes support pillar structures 20, which are subsequently used to provide structural support during replacement of the sacrificial material layers 42 with electrically conductive layers. Alternatively, the processing steps illustrated with reference to FIGS. 29A and 29B may be omitted, and the support pillar structures may be formed concurrently with formation of memory opening fill structures, as will be described below with respect to FIGS. 30A-32B.

Referring to FIGS. 30A and 30B, a photoresist layer (not shown) can be applied over the alternating stack (32, 42), and can be lithographically patterned to form arrays of memory openings 49 in the memory regions 100. An anisotropic etch process can be performed to transfer the pattern of the opening in the photoresist layer through the alternating stack (32, 42) to form memory openings 49. Each of the memory openings 49 may vertically extend from the horizontal plane including the topmost surface of the alternating stack (32, 42) at least to the horizontal plane including the bottommost surface of the alternating stack (32, 42), and optionally into an upper portion of the semiconductor material layer 110. The photoresist layer can be subsequently removed, for example, by ashing. In the alternative embodiment, the above-described support openings may be formed in the inter-array regions 200 concurrently with formation of the memory openings 49 in the memory regions 100.

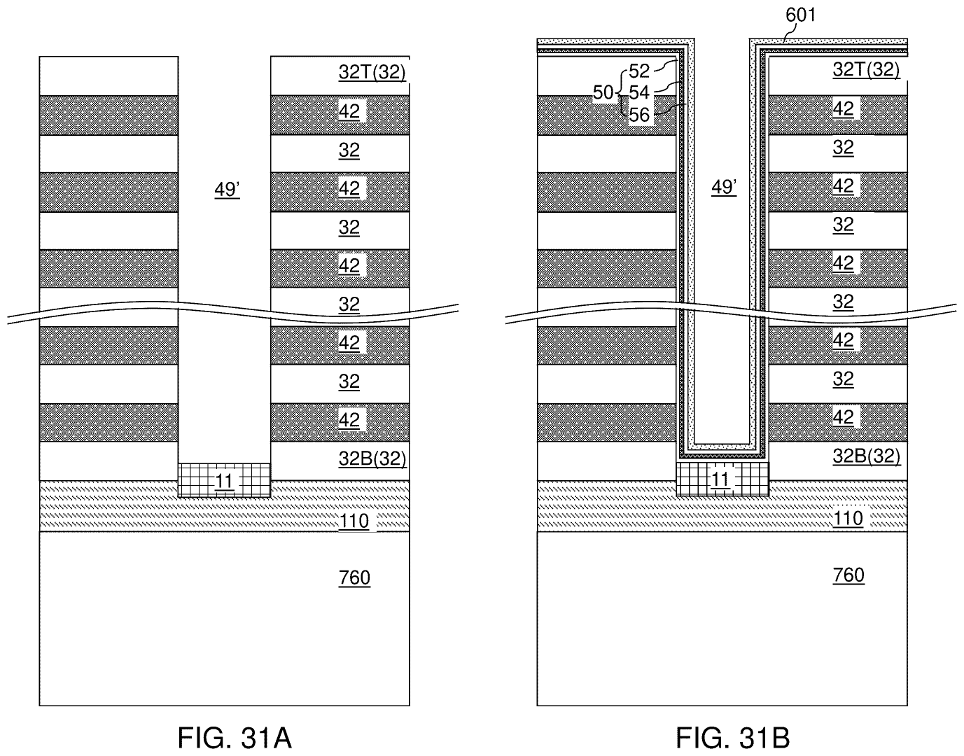

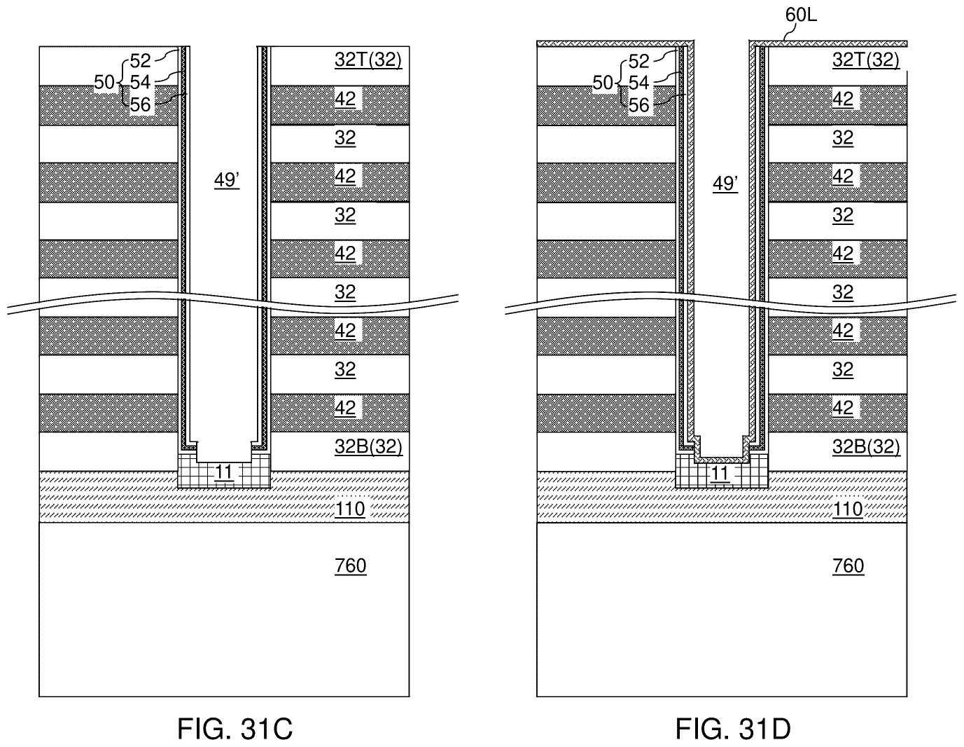

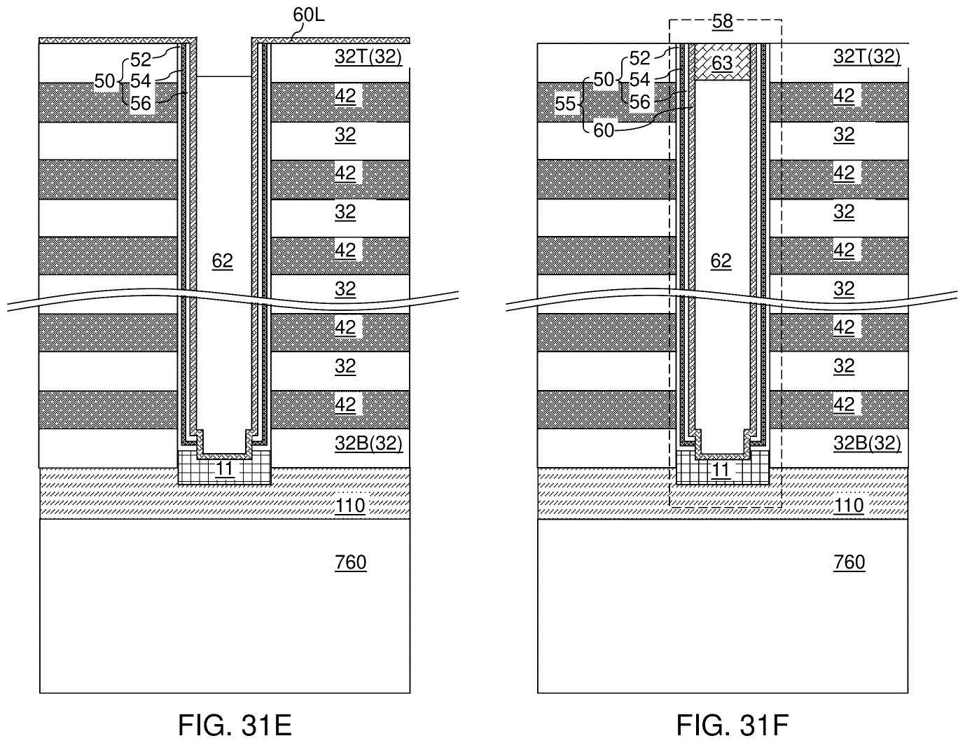

FIGS. 31A-31F are sequential vertical cross-sectional views of a memory opening 49 during formation of a memory opening fill structure 58 according to an embodiment of the present disclosure.

Referring to FIG. 31A, a memory opening 49 in the exemplary device structure of FIGS. 30A and 30B is illustrated. The memory opening 49 extends through the alternating stack (32, 42), and optionally into an upper portion of the semiconductor material layer 110. The recess depth of the bottom surface of each memory opening 49 with respect to the top surface of the semiconductor material layer 110 can be in a range from 0 nm to 30 nm, although greater recess depths can also be employed. Optionally, the sacrificial material layers 42 can be laterally recessed partially to form laterally-extending cavities (not shown), for example, by an isotropic etch.

An optional pedestal channel portion 11 (which may be a silicon pedestal) can be formed at the bottom portion of each memory opening 49, for example, by a selective semiconductor deposition process. In one embodiment, the pedestal channel portion 11 can be doped with electrical dopants of the same conductivity type as the semiconductor material layer 110, which is a first conductivity type. In one embodiment, the top surface of each pedestal channel portion 11 can be formed below a horizontal plane including the top surface of the bottommost insulating layer 32B. The pedestal channel portion 11 can be a portion of a transistor channel that extends between a source region to be subsequently formed in the semiconductor material layer 110 and a drain region to be subsequently formed in an upper portion of the memory opening 49. A memory cavity 49′ is present in the unfilled portion of the memory opening 49 above the pedestal channel portion 11.

Referring to FIG. 31B, a stack of layers including a blocking dielectric layer 52, a memory material layer 54, and an optional dielectric liner 56 can be deposited in each memory opening 49. The stack of layers is herein referred to as a memory film 50.

The blocking dielectric layer 52 can include a single dielectric material layer or a stack of a plurality of dielectric material layers. In one embodiment, the blocking dielectric layer 52 can include a dielectric metal oxide layer consisting essentially of a dielectric metal oxide. In one embodiment, the blocking dielectric layer 52 can include a dielectric metal oxide having a dielectric constant greater than 7.9, i.e., having a dielectric constant greater than the dielectric constant of silicon nitride. Alternatively or additionally, the blocking dielectric layer 52 can include a dielectric semiconductor compound such as silicon oxide, silicon oxynitride, silicon nitride, or a combination thereof. In one embodiment, the blocking dielectric layer 52 can include silicon oxide. In this case, the dielectric semiconductor compound of the blocking dielectric layer 52 can be formed by a conformal deposition method such as low pressure chemical vapor deposition, atomic layer deposition, or a combination thereof. The thickness of the dielectric semiconductor compound can be in a range from 1 nm to 20 nm, although lesser and greater thicknesses can also be employed.

The memory material layer 54 may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within laterally-extending cavities into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer. Generally, the memory material layer 54 may comprise a vertical stack of memory elements that are located at levels of the sacrificial material layers 42. For example, the vertical stack of memory elements may be embodied as annular portions of the memory material layer 54 located at levels of the sacrificial material layers 42.

The optional dielectric liner 56, if present, comprises a dielectric liner material. In one embodiment, the dielectric liner 56 may comprise a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 can include a stack of a first silicon oxide layer, a silicon oxynitride layer, and a second silicon oxide layer, which is commonly known as an ONO stack. In one embodiment, the dielectric liner 56 can include a silicon oxide layer that is substantially free of carbon or a silicon oxynitride layer that is substantially free of carbon. The thickness of the dielectric liner 56 can be in a range from 2 nm to 20 nm, although lesser and greater thicknesses can also be employed.

Optionally, a sacrificial cover material layer 601 may be formed over the memory film 50.

Referring to FIG. 31C, the optional sacrificial cover material layer 601, the dielectric liner 56, the memory material layer 54, the blocking dielectric layer 52 are sequentially anisotropically etched employing at least one anisotropic etch process. The portions of the sacrificial cover material layer 601, the dielectric liner 56, the memory material layer 54, and the blocking dielectric layer 52 located above the top surface of the topmost insulating layer 32T can be removed by the at least one anisotropic etch process. Further, the horizontal portions of the sacrificial cover material layer 601, the dielectric liner 56, the memory material layer 54, and the blocking dielectric layer 52 at a bottom of each memory cavity 49′ can be removed to form openings in remaining portions thereof. Each of the sacrificial cover material layer, the dielectric liner 56, the memory material layer 54, and the blocking dielectric layer 52 can be etched by a respective anisotropic etch process employing a respective etch chemistry, which may or may not be the same for the various material layers.

Each remaining portion of the sacrificial cover material layer 601, if employed, can have a tubular configuration. A surface of the pedestal channel portion 11 (or a surface of the semiconductor material layer 110 in case a pedestal channel portions 11 is not employed) can be physically exposed underneath the opening through the sacrificial cover material layer, the dielectric liner 56, the memory material layer 54, and the dielectric metal oxide blocking dielectric layer 52. Optionally, the physically exposed semiconductor surface at the bottom of each memory cavity 49′ can be vertically recessed so that the recessed semiconductor surface underneath the memory cavity 49′ is vertically offset from the topmost surface of the pedestal channel portion 11 (or of the semiconductor material layer 110 in case pedestal channel portions 11 are not employed) by a recess distance. In one embodiment, the sacrificial cover material layer 601, the dielectric liner 56, the memory material layer 54, and the blocking dielectric layer 52 can have vertically coincident sidewalls. The sacrificial cover material layer 601 can be subsequently removed selective to the material of the dielectric liner 56. In case the sacrificial cover material layer 601 includes amorphous silicon, a wet etch process employing hot trimethyl-2 hydroxyethyl ammonium hydroxide (“hot TMY”) or tetramethyl ammonium hydroxide (TMAH) can be performed to remove the sacrificial cover material layer. Alternatively, the sacrificial cover material layer 601 may be retained in the final device if it comprises a silicon material.

Referring to FIG. 31D, a semiconductor channel layer 60L can be deposited directly on the semiconductor surface of the pedestal channel portion 11 or the semiconductor material layer 110 if the pedestal channel portion 11 is omitted, and directly on the memory film 50. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can have a doping of a first conductivity type, which is the same as the conductivity type of the semiconductor material layer 110 and the pedestal channel portions 11. The semiconductor channel layer 60L can be formed by a conformal deposition method such as low pressure chemical vapor deposition (LPCVD). The thickness of the semiconductor channel layer 60L can be in a range from 2 nm to 10 nm, although lesser and greater thicknesses can also be employed. The semiconductor channel layer 60L may partially fill the memory cavity 49′ in each memory opening, or may fully fill the cavity in each memory opening.

Referring to FIG. 31E, a dielectric core layer can be deposited to fill any remaining portion of the memory cavity 49′ within each memory opening 49. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating.

The horizontal portion of the dielectric core layer can be removed, for example, by a recess etch process such that each remaining portions of the dielectric core layer is located within a respective memory opening 49 and has a respective top surface below the horizontal plane including the top surface of the topmost insulating layer 32T. Each remaining portion of the dielectric core layer constitutes a dielectric core 62.

Referring to FIG. 31F, a doped semiconductor material having a doping of a second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each combination of a memory film 50 and a vertical semiconductor channel 60 within a memory opening 49 constitutes a memory stack structure 55. The memory stack structure 55 is a combination of a vertical semiconductor channel 60, an optional dielectric liner 56, a plurality of memory elements comprising portions of the memory material layer 54, and an optional blocking dielectric layer 52. Each combination of a pedestal channel portion 11 (if present), a memory stack structure 55, a dielectric core 62, and a drain region 63 within a memory opening 49 is herein referred to as a memory opening fill structure 58.

In the alternative embodiment in which the support openings are formed at the same time as the memory openings 49, the support pillar structures 20 may be formed in the support openings at the same time as the memory opening fill structures 58. In this alternative embodiment, the support pillar structures 20 have the same composition as the memory opening fill structures 58, but are not electrically connected to the subsequently formed bit lines.

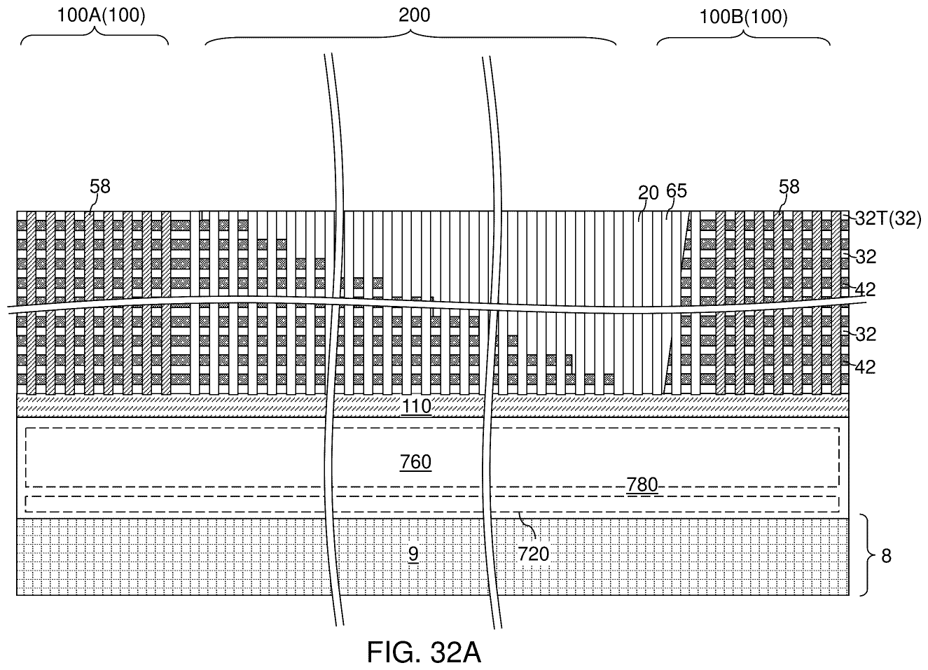

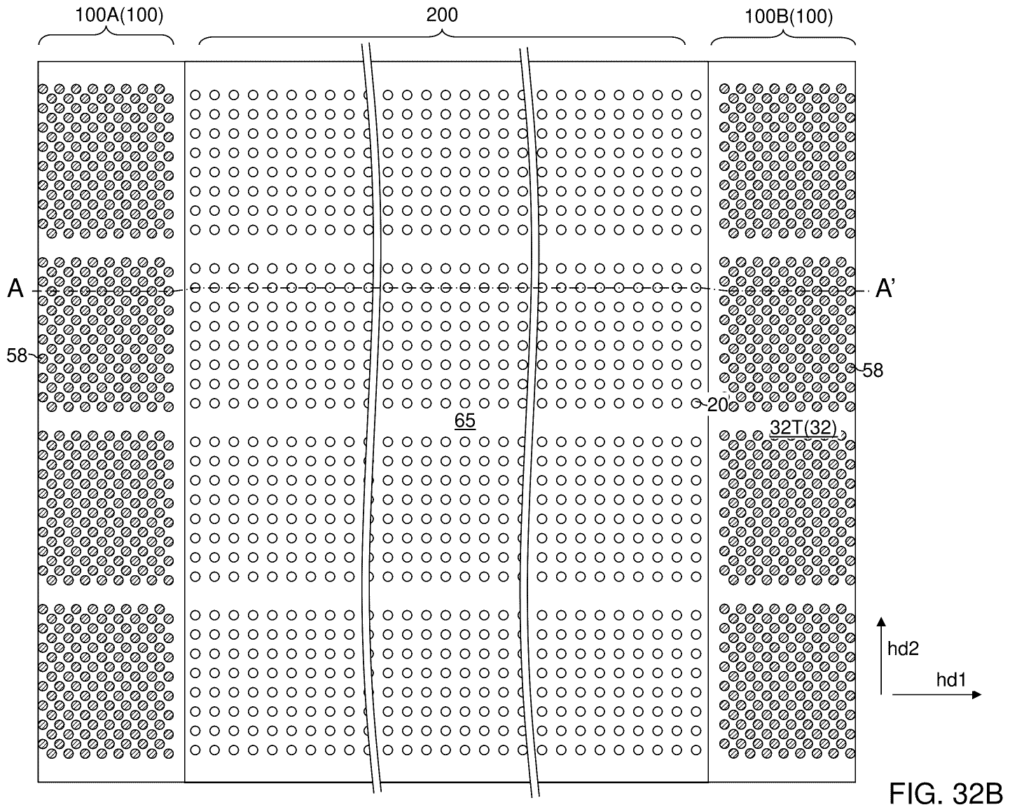

Referring to FIGS. 32A and 32B, the exemplary structure is illustrated after formation of memory opening fill structures 58 and support pillar structure 20 within the memory openings 49 and the support openings 19, respectively. An instance of a memory opening fill structure 58 can be formed within each memory opening 49. An instance of the support pillar structure 20 can be formed within each support opening. Other memory stack structures including different layer stacks or structures for the memory film 50 and/or for the vertical semiconductor channel 60 may also be used.

In summary, each memory opening fill structure 58 can be formed in a respective one of the memory openings 49. Each of the memory opening fill structures 58 comprises a respective vertical stack of memory elements (e.g., portions of the memory film 50) and a vertical semiconductor channel 60. Within each plane, a first subset of the memory opening fill structures 58 is located in a first memory array region 100A, and a second subset of the memory opening fill structures 58 is located in a second memory array region 100B that is laterally offset from the first memory array region 100A along the first horizontal direction hd1.

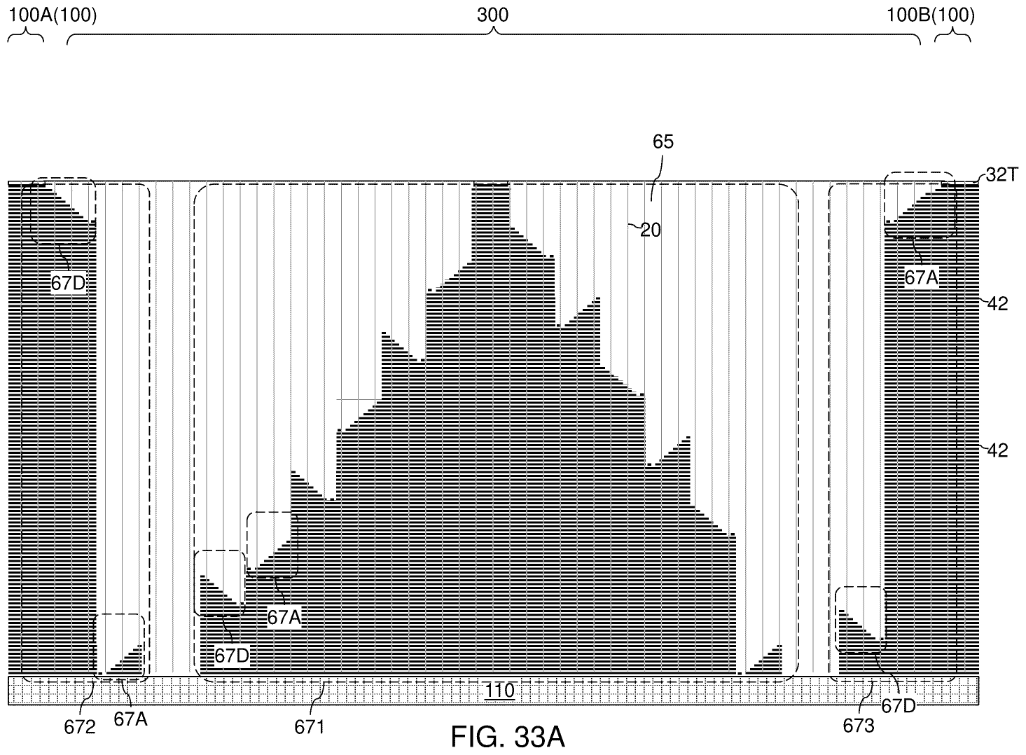

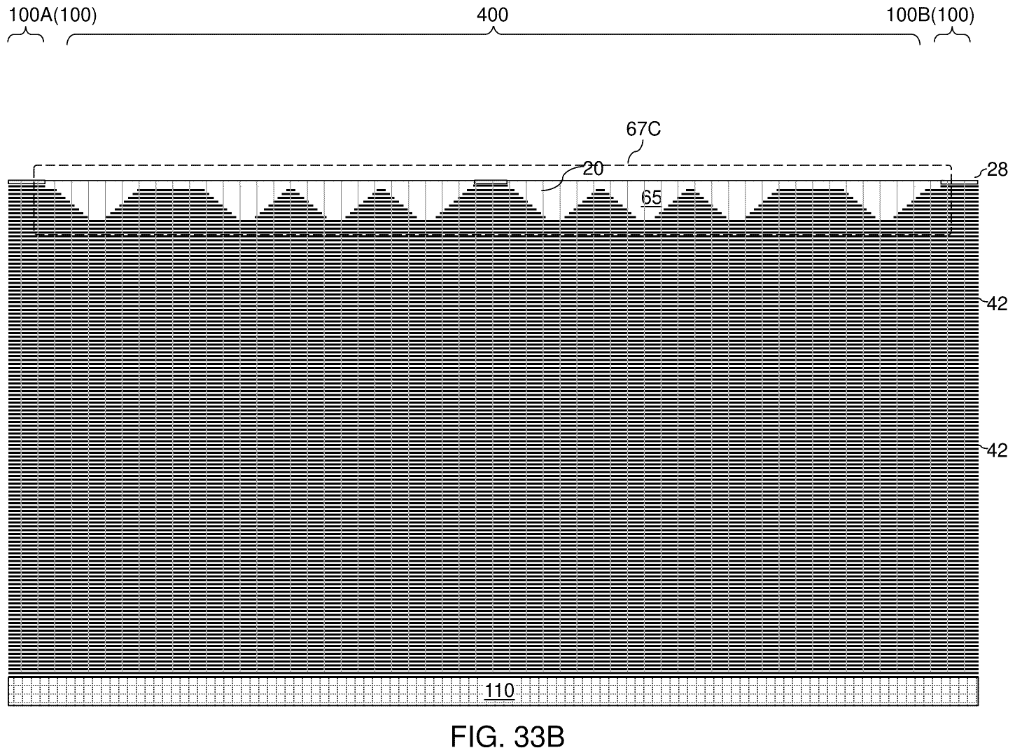

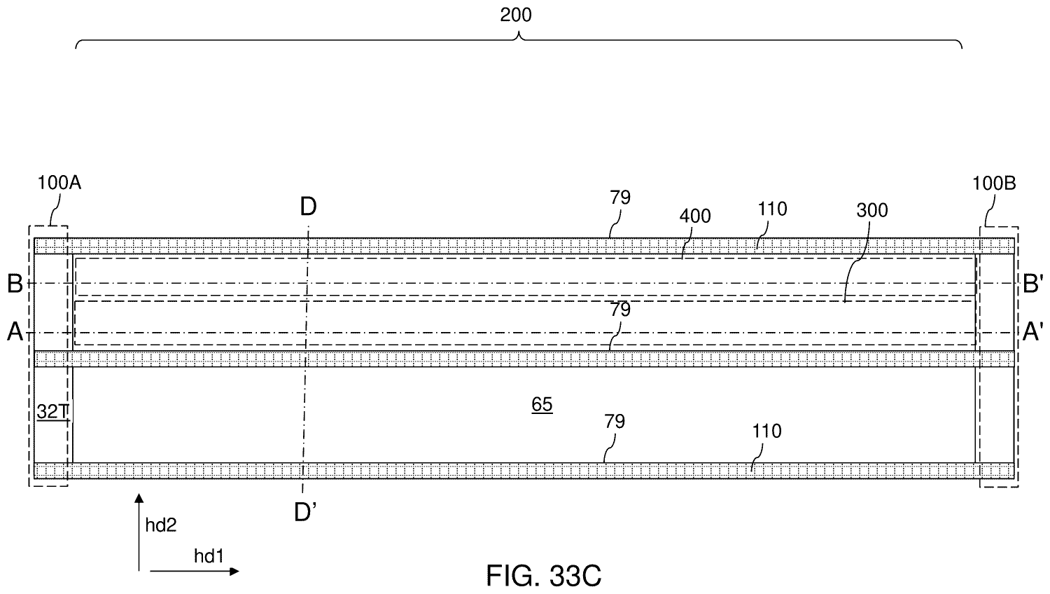

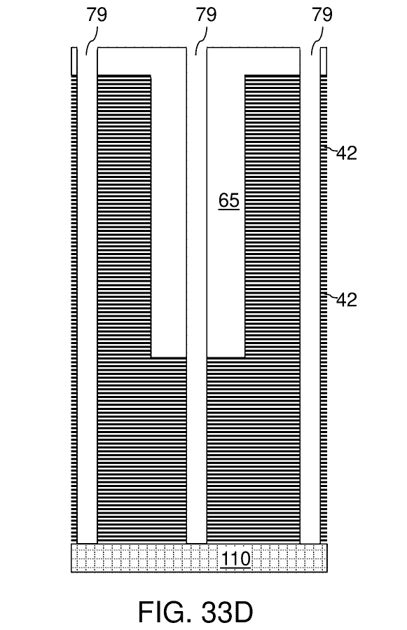

Referring to FIGS. 33A-33D, a photoresist layer (not shown) can be applied over the alternating stack (32, 42), the memory opening fill structures 58, and the retro-stepped dielectric material portions 65, and can be lithographically patterned to form elongated openings in areas between clusters of memory opening fill structures 58. The pattern in the photoresist layer can be transferred through the alternating stack (32, 42) and the retro-stepped dielectric material portions 65 employing an anisotropic etch to form lateral isolation trenches 79, which vertically extend from the topmost surface of the alternating stack (32, 42) at least to the top surface of semiconductor material layer 110, and laterally extend along the first horizontal direction hd1 through a respective inter-array region 200 and a pair of memory array regions 100.

In one embodiment, the lateral isolation trenches 79 can laterally extend along a first horizontal direction hd1 (which is a word line direction), and can be laterally spaced apart to each other along a second horizontal direction hd2 (which is a bit line direction) that is perpendicular to the first horizontal direction hd1. The memory opening fill structures 58 can be arranged in rows that extend along the first horizontal direction hd1. Each lateral isolation trench 79 can have a uniform width that is invariant along the lengthwise direction (i.e., along the first horizontal direction hd1). Multiple rows of memory opening fill structures can be located between a neighboring pair of lateral isolation trenches 79. In one embodiment, the lateral isolation trenches 79 can include source contact openings in which source contact via structures can be subsequently formed. The photoresist layer can be removed, for example, by ashing.

The width of the lateral isolation trenches 79 along the second horizontal direction hd2 can be greater than the thickness of each sacrificial material layer 42. The alternating stack (32, 42) is divided into multiple alternating stacks (32, 42) that are laterally spaced apart along the second horizontal direction hd2 by the lateral isolation trenches 79.

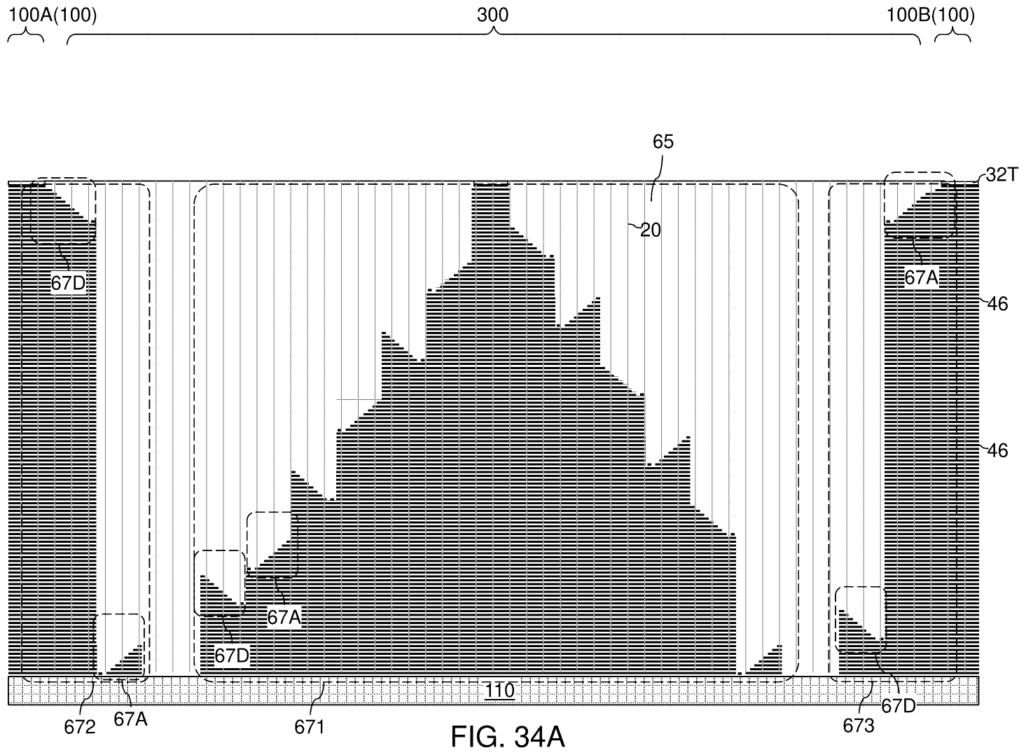

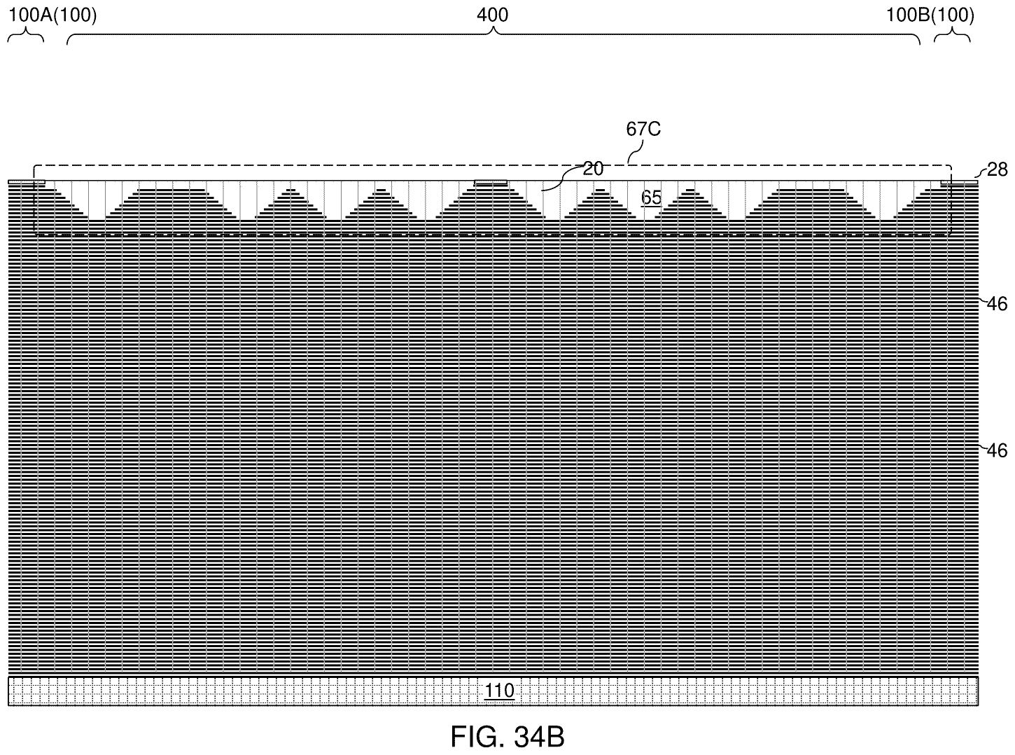

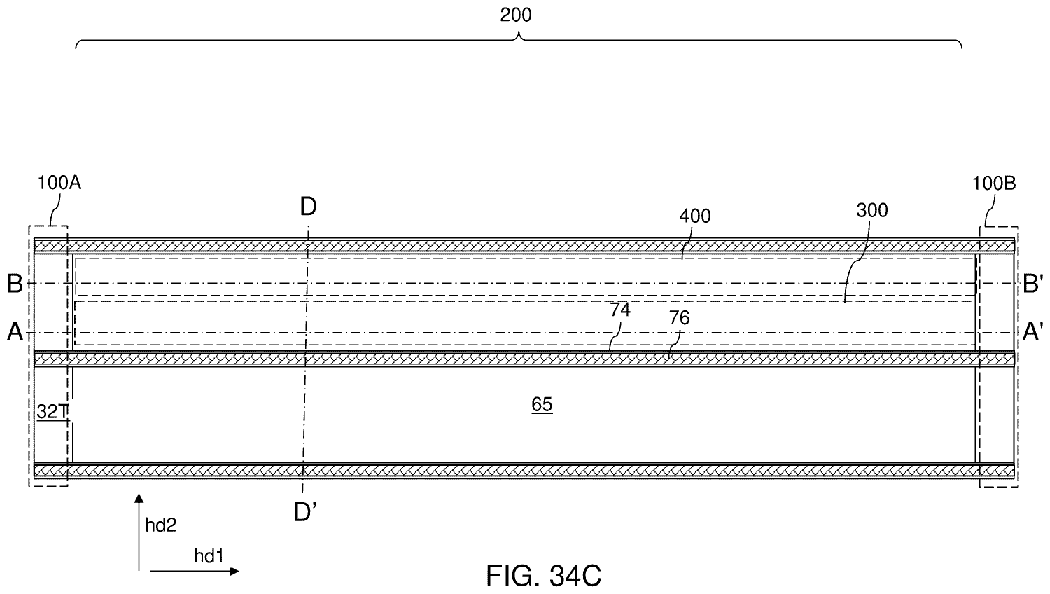

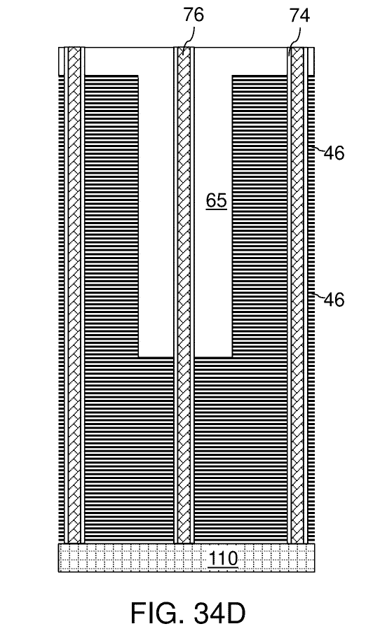

Referring to FIGS. 34A-34D, an isotropic etch process can be performed to introduce an isotropic etchant that etches a material of the sacrificial material layers 42 into the lateral isolation trenches 79. For example, if the sacrificial material layers 42 comprise silicon nitride, the isotropic etch process may comprise a wet etch process employing hot phosphoric acid. Laterally-extending cavities 43 are formed in volumes from which portions of the sacrificial material layers 42 are removed by the isotropic etch process. According to an aspect of the present disclosure, the isotropic etch process has a sufficient etch distance to remove all portions of the sacrificial material layers 42 in the memory array regions 100 and the contact regions 200 while not removing portions of the sacrificial material layers 42 that are in contact with the dielectric moat structures 165. Laterally-extending cavities can be formed in the volumes from which the sacrificial material layers 42 are removed.

Backside blocking dielectric layer (not shown) may be optionally deposited in the laterally-extending cavities on the physically exposed surfaces of the retro-stepped dielectric material portions 65, the memory opening fill structures 58, and the insulating layers 32 by a conformal deposition process. At least one conductive material can be deposited in unfilled volumes of the laterally-extending cavities by providing at least one reactant gas into the laterally-extending cavities through the lateral isolation trenches. For example, the at least one conductive material may comprise a metallic barrier layer and a metallic fill material.

The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

The metal fill material can be deposited over the metallic barrier layer to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas, such as WF₆. In one embodiment, the metallic fill material layer can be a tungsten layer including a residual level of fluorine atoms as impurities. The metallic fill material layer is spaced from the insulating layers 32 and the memory opening fill structures 58 by the metallic barrier layer, which is a metallic barrier layer that blocks diffusion of fluorine atoms therethrough.

A plurality of electrically conductive layers 46 can be formed in the plurality of laterally-extending cavities 43, and a continuous metallic material layer can be formed on the sidewalls of each lateral isolation trench 79 and over the topmost insulating layer 32T. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the topmost insulating layer 32T by performing an etch process that etches the at least one conductive material of the continuous electrically conductive material layer. Each remaining portion of the deposited metallic material in the laterally-extending cavities constitutes an electrically conductive layer 46. Each electrically conductive layer 46 can be a conductive line structure. Thus, the sacrificial material layers 42 are replaced with the electrically conductive layers 46.

The middle electrically conductive layers 46 can function as a combination of a plurality of control gate electrodes located at a same level and a word line electrically interconnecting, i.e., electrically shorting, the plurality of control gate electrodes located at the same level. The plurality of control gate electrodes within each electrically conductive layer 46 are the control gate electrodes for the vertical memory devices including the memory stack structures 55. In other words, the electrically conductive layer 46 can be a word line that functions as a common control gate electrode for the plurality of vertical memory devices. At least one upper most electrically conductive layer 46 may comprise a drain side select gate electrode. At least one lower most electrically conductive layer 46 may comprise a source side select gate electrode.

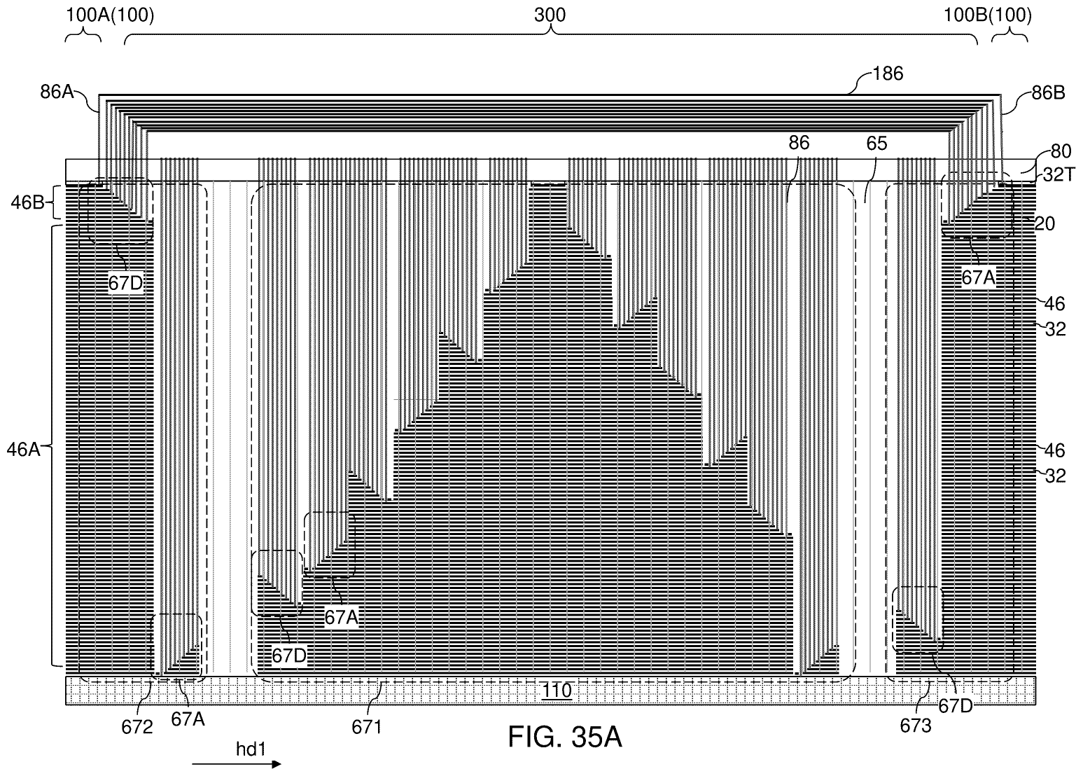

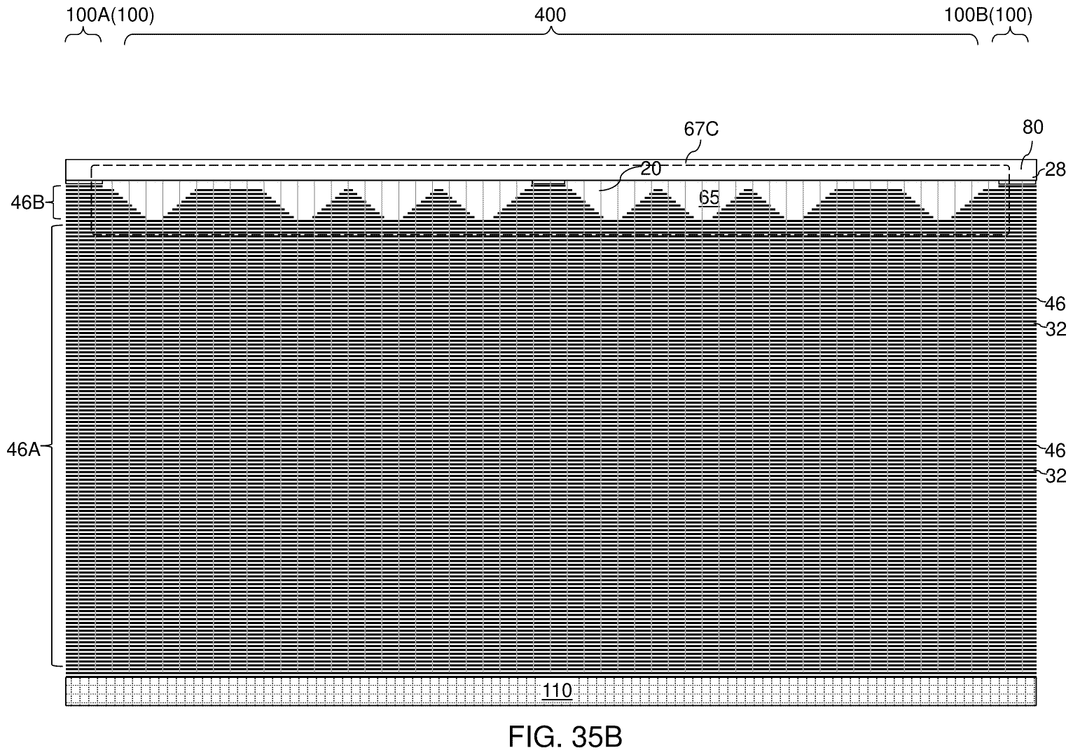

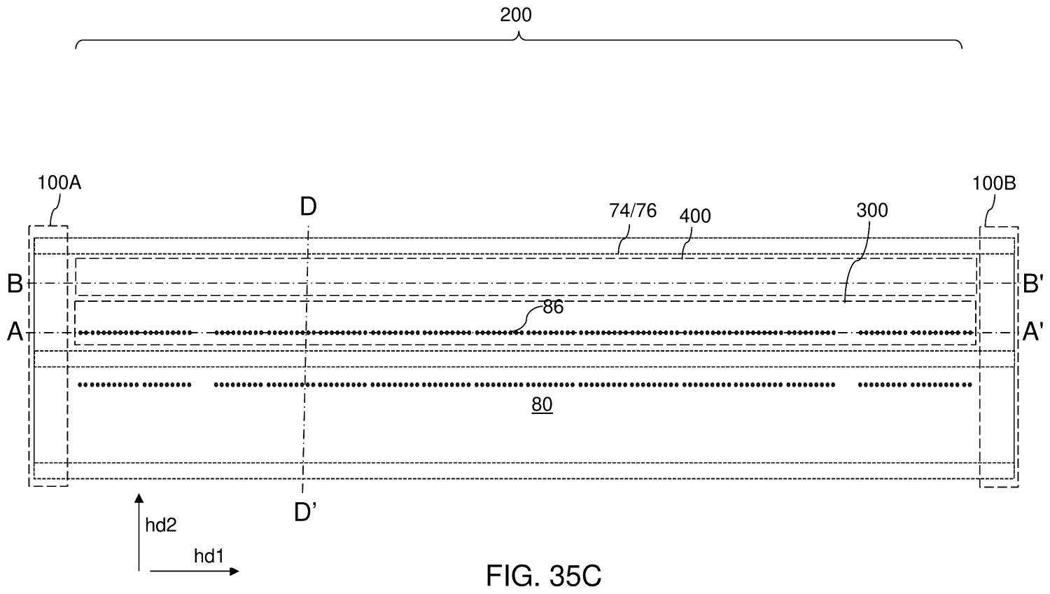

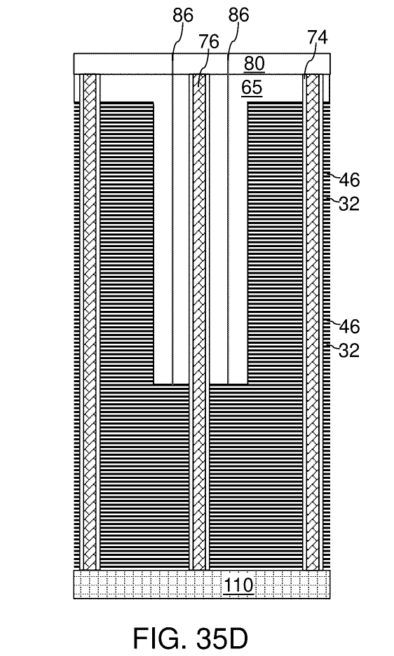

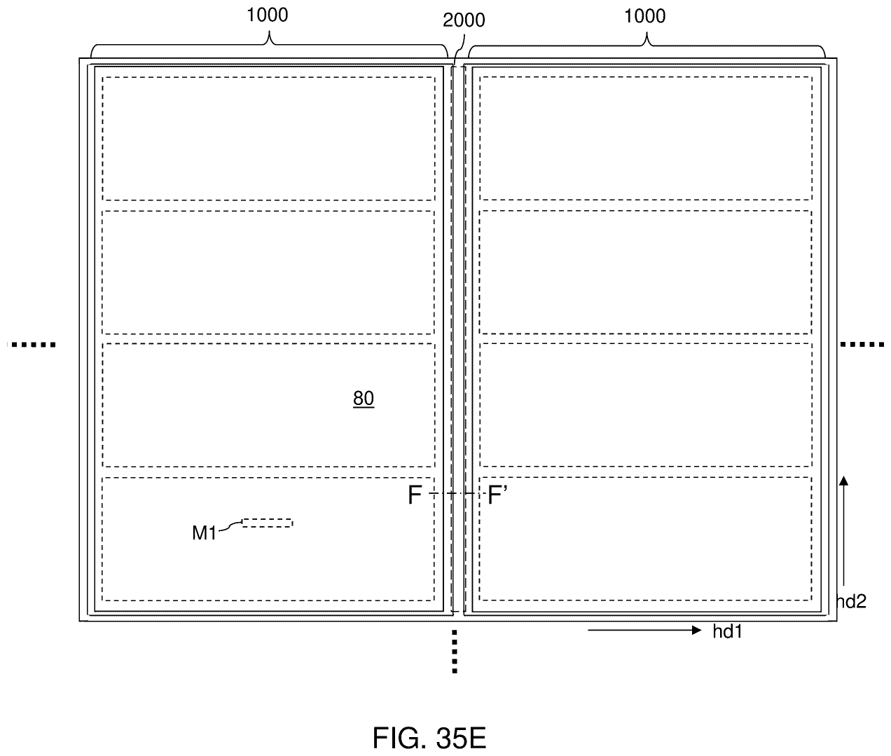

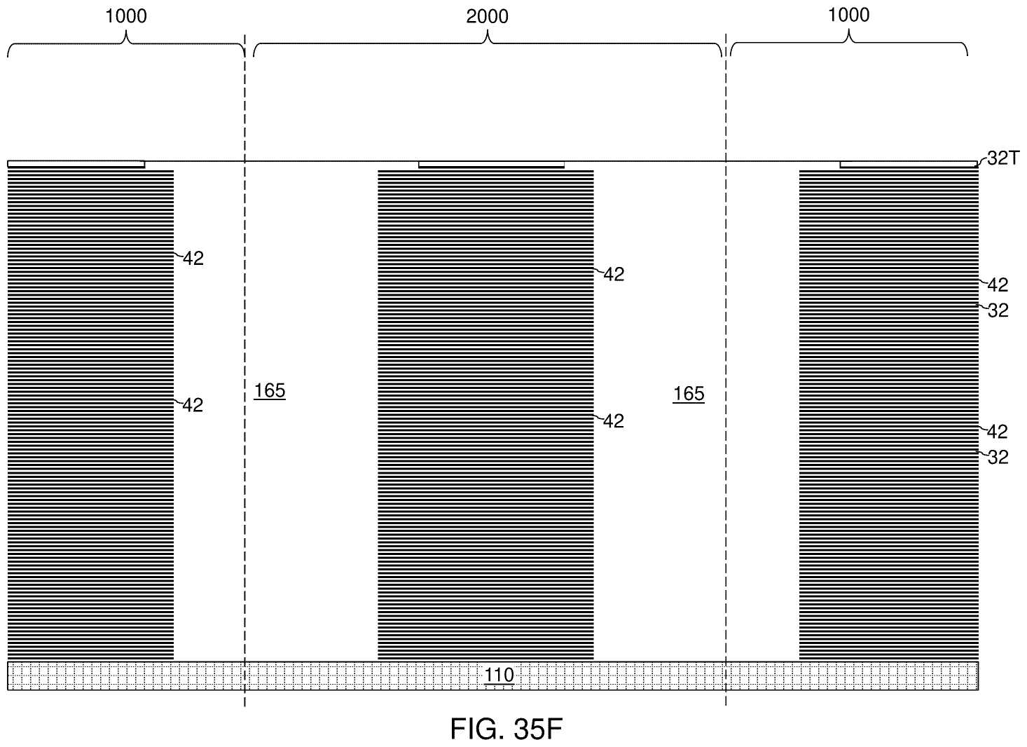

Referring to FIGS. 35A-35F, an insulating material layer can be conformally deposited in peripheral regions of the lateral isolation trenches 79. An optional anisotropic etch process can be performed to remove horizontally-extending portions of the insulating material layer. Each remaining portion of the insulating material layer in the lateral isolation trenches 79 constitute insulating spacers 74. At least one conductive material, such as at least one metallic material, can optionally be deposited in remaining volumes of the lateral isolation trenches 79. Excess portions of the at least one conductive material can be removed from above the horizontal plane including the top surface of the alternating stack by performing a planarization process, such as a chemical mechanical polishing process. Each remaining portion of the at least one conductive material in a respective one of the lateral isolation trenches 79 constitute a source contact wall structure 76. Each contiguous combination of an insulating spacer 74 and a source contact wall structure 76 constitutes an isolation trench fill structure (74, 76).

A dielectric material, such as silicon oxide, can be deposited over the alternating stacks (32, 46) of insulating layers 32 and electrically conductive layers 46 and over the retro-stepped dielectric material portions 65 to form a contact-level dielectric layer 80. A photoresist layer can be applied over the contact-level dielectric layer 80, and can be lithographically patterned to form openings over areas of the memory opening fill structures 58 and horizontally-extending portions of the electrically conductive layers 46 that underlie the stepped bottom surfaces of the retro-stepped dielectric material portions 65. An anisotropic etch process can be performed to form drain contact via cavities (not shown) over the drain regions 63 of the memory opening fill structures 58, and to form layer contact via cavities over the horizontally-extending surfaces of the electrically conductive layers 46 underlying the retro-stepped dielectric material portions 65. At least one conductive material can be deposited in the drain contact via cavities to form drain contact via structures (not shown), and can be deposited in the layer contact via cavities to form layer contact via structures 86. Each layer contact via structure 86 contacts a top surface segment of a respective electrically conductive layer 46. Each electrically conductive layer 46 can be contacted by at least one layer contact via structure 86.

As shown in FIG. 35B, at least the topmost electrically conductive layers 46 which form the connection-region staircase structures 67C do not continuously extend through the connection region 400 from the first memory array region 100A to the second memory array region 100B because they are separated by the retro-stepped cavities 69 filled with the retro-stepped dielectric material portions 65. Each of the topmost electrically discontinuous electrically conductive layers 46 is contacted by a respective pair of first and second layer contact via structures (86A, 86B), as shown in FIG. 35A. The first layer contact via structure 86A contacts a top surface segment of the topmost electrically conductive layer 46 that is located adjacent to the first memory array region 100A. The second layer contact via structure 86B contacts a top surface segment of the topmost electrically conductive layer 46 that is located adjacent to the second memory array region 100B. The respective pair of first and second layer contact via structures (86A, 86B) are electrically connected to each other by a respective one of electrically conductive bridges 186. Each of the electrically conductive bridges 186 comprises an electrically conductive layer which is located above the alternating stack (32, 46) and the contact-level dielectric layer 80 as needed. Additional metal interconnect structures and bit lines (not shown) may be formed above the contact-level dielectric layer 80 as needed.

Referring to all drawings and according to various embodiments of the present disclosure, a three-dimensional memory device comprises: an alternating stack (32, 46) of insulating layers 32 and electrically conductive layers 46, wherein the alternating stack (32, 46) comprises multiple staircase structures (671, 672, 673) that are arranged along a first horizontal direction hd1; memory openings 49 vertically extending through the alternating stack (32, 46); memory opening fill structures 58 located in the memory openings 49, wherein each of the memory opening fill structures 58 comprises a respective vertical stack of memory elements (e.g., portions of the memory film 50) and a vertical semiconductor channel 60; and at least one retro-stepped dielectric material portion 65 contacting the multiple staircase structures (671, 672, 673), wherein: a first subset of the memory opening fill structures 58 is located in a first memory array region 100A; a second subset of the memory opening fill structures 58 is located in a second memory array region 100B that is laterally offset from the first memory array region 100A along a first horizontal direction hd1; the multiple staircase structures (671, 672, 673) are located in a contact region 300 which is located between the first memory array region 100A and the second memory array region 100B; a predominant subset 46A of the electrically conductive layers 46 extends continuously between the first memory array region 100A and the second memory array region 100B within a connection region 400 that is located between the first memory array region 100A and the second memory array region 100B and laterally offset from the contact region 300 along a second horizontal direction hd2; a portion of the alternating stack (32, 46) located in the connection region 400 comprises connection-region staircase structures 67C; and each horizontally-extending surface segment within the multiple staircase structures (671, 672, 673) in the contact region 300 is vertically offset downward from a respective most proximal horizontally-extending surface segment in the connection-region staircase structures 67C at least by a sum of a thickness of an insulating layer 32 in the alternating stack (32, 46) and a thickness of an electrically conductive layer 46 within the alternating stack (32, 46).

In one embodiment, each staircase structure within the multiple staircase structures (671, 672, 673) comprises a respective set of (K+1) horizontally-extending surface segments that are adjoined to each other by a respective set of K vertically-extending surface segments; and K is an integer greater than 2. In one embodiment, a total number of horizontally-extending surface segments within each staircase structure within a primary subset of the multiple staircase structures (671, 672, 673) is (K+1); and a total number of horizontally-extending surface segments within each staircase structure within a complementary subset of the multiple staircase structures (671, 672, 673) is (K+3). In one embodiment, a total number of horizontally-extending surface segments within each staircase structure within a primary subset of the connection-region staircase structures 67C is (K+1); and a total number of horizontally-extending surface segments within each staircase structure within a complementary subset of the connection-region staircase structures 67C is (K+2).

In one embodiment, each staircase structure within the primary subset of the connection-region staircase structures 67C has a same lateral extent along the first horizontal direction hd1 as a respective staircase structure within the primary subset of the multiple staircase structures (671, 672, 673); and each staircase structure within the complementary subset of the connection-region staircase structures 67C has a same lateral extent along the first horizontal direction hd1 as a respective staircase structure within the complementary subset of the multiple staircase structures (671, 672, 673). In one embodiment, all horizontally-extending surface segments within the primary subset of the connection-region staircase structures 67C are located entirely within a set of (K+1) horizontal planes; and each horizontally-extending surface segment within the primary subset of the multiple staircase structures (671, 672, 673) is located below a bottommost horizontal plane of the set of (K+1) horizontal planes, and is vertically spaced from the bottommost horizontal plane by at least two insulating layers 32 within the alternating stack (32, 46).

In one embodiment, all horizontally-extending surface segments within the connection-region staircase structures 67C are located entirely within a set of (K+2) horizontal planes including a topmost set of (K+2) electrically conductive layers 46 within the alternating stack (32, 46); and all horizontally-extending surface segments within the complementary subset of the multiple staircase structures (671, 672, 673) are located entirely within a set of (K+3) horizontal planes including the set of (K+2) horizontal planes and including a horizontal plane including a top surface of a (K+3)-th electrically conductive layer 46 as counted downward from top within the alternating stack (32, 46). In one embodiment, all horizontally-extending surface segments within the primary subset of the multiple staircase structures (671, 672, 673) are located entirely below a horizontal plane including a top surface of a (K+4)-th electrically conductive layer 46 as counted downward from top within the alternating stack (32, 46).

In one embodiment, each horizontally-extending surface segment within the complementary subset of the multiple staircase structures (671, 672, 673) are vertically offset from a respective horizontally-extending surface segment by a respective vertical step that extends along the first horizontal direction hd1 and having a height that equals a vertical distance between a top surface of an overlying electrically conductive layer 46 and a top surface of an underlying electrically conductive layer 46 within a vertically neighboring pair of electrically conductive layers 46 in the alternating stack (32, 46). In one embodiment, the complementary subset of the multiple staircase structures (671, 672, 673) comprises a pair of outermost staircase structures in a vertical cross-sectional view along a vertical plane that is perpendicular to the second horizontal direction hd2.

In one embodiment, the alternating stack (32, 46) overlies a semiconductor material layer 110; the at least one retro-stepped dielectric material portion 65 contacts a first surface segment of a top surface of the semiconductor material layer 110 and a second surface segment of the top surface of the semiconductor material layer 110 that is laterally spaced from the first surface segment; and the multiple staircase structures (671, 672, 673) comprise first staircase structures 671 located between the first surface segment of the top surface of the semiconductor material layer 110 and the second surface segment of the top surface of the semiconductor material layer 110, second staircase structures 672 laterally spaced from the first staircase structures by the first surface segment, and third staircase structures 673 laterally spaced from the first staircase structures by the second surface segment. In one embodiment, a total number of horizontally-extending surface segments within each staircase structure within a primary subset of the multiple staircase structures (671, 672, 673) is (K+1); a total number of horizontally-extending surface segments within each staircase structure within a complementary subset of the multiple staircase structures (671, 672, 673) is (K+3); the second staircase structure comprises a staircase structure within the complementary subset of the multiple staircase structures (671, 672, 673) and a staircase structure within the primary subset of the multiple staircase structures (671, 672, 673).

In one embodiment, the multiple staircase structures (671, 672, 673) comprise: ascending staircase structures 67A of which horizontally-extending surface segments have a stepwise-increasing height profile that increases stepwise along the first horizontal direction hd1; and descending staircase structures 67D of which horizontally-extending surface segments have a stepwise-decreasing height profile that decreases stepwise along the first horizontal direction hd1. In one embodiment, the first staircase structures 671 comprise a laterally alternating sequence of first descending staircase structures 67D and first ascending staircase structures 67A that alternate along the first horizontal direction hd1; the second staircase structures 672 consist of a second descending staircase structure 67D and a second ascending staircase structure 67A; and the third staircase structures 673 consist of a third descending staircase structure 67D and a third ascending staircase structure 67A. In one embodiment, each of the first ascending staircase structures 67A comprises a respective set of (K+1) horizontally-extending surface segments; each of the first descending staircase structures 67D comprises a respective set of (K+1) horizontally-extending surface segments; the second ascending staircase structure 67A comprises a set of (K+1) horizontally-extending surface segments; and the third descending staircase structure 67D comprises a set of (K+1) horizontally-extending surface segments.

In one embodiment shown in FIGS. 35A and 35B, an additional subset 46B of the electrically conductive layers 46 which form the connection-region staircase structures 67C in the connection region 400 are discontinuous between the first memory array region 100A and the second memory array region 100B. Each of the electrically conductive layers 46 in the additional subset 46B is contacted in the contact region 300 by a respective pair of a first layer contact via structure 86A and a second layer contact via structure 86B. A respective electrically conductive bridge 186 electrically connects the respective pair of the first layer contact via structure 86A and the second layer contact via structure 86B. In contrast, the predominant subset 46A of the electrically conductive layers 46 is continuous between the first memory array region 100A and the second memory array region 100B; and a respective layer contact via structure contacts 86 each of the electrically conductive layers 46 of the predominant subset 46A in the contact region 300.

According to another aspect of the present disclosure, a three-dimensional memory device comprises: an alternating stack (32, 46) of insulating layers 32 and electrically conductive layers 46 overlying a semiconductor material layer 110 (which may comprise a discrete semiconductor layer located over a substrate or a doped well in the upper portion of a semiconductor substrate), wherein the alternating stack (32, 46) comprises multiple staircase structures (671, 672, 673) that are arranged along a first horizontal direction hd1, wherein the multiple staircase structures (671, 672, 673) comprise first staircase structures 671 that are interconnected to each other by widthwise sidewalls that laterally extend along a second horizontal direction hd2 that is perpendicular to the first horizontal direction hd1, second staircase structures 672 that are laterally spaced from the first staircase structures 671, and third staircase structures 673 that are laterally spaced from the first staircase structures 671 and from the second staircase structures 672; memory openings 49 vertically extending through the alternating stack (32, 46); memory opening fill structures 58 located in the memory openings 49, wherein each of the memory opening fill structures 58 comprises a respective vertical stack of memory elements (e.g., portions of the memory film 50) and a vertical semiconductor channel 60; and at least one retro-stepped dielectric material portion 65 contacting the first staircase structures 671, the second staircase structures 672, the third staircase structures 673, a first surface segment of a top surface of the semiconductor material layer 110 located between the first staircase structures 671 and the second staircase structures 672, and a second surface segment of the top surface of the semiconductor material layer 110 located between the first staircase structures 671 and the third staircase structures 673.

In one embodiment, each staircase structure within the multiple staircase structures (671, 672, 673) comprises a respective set of (K+1) horizontally-extending surface segments that are adjoined to each other by a respective set of K vertically-extending surface segments; K is an integer greater than 2; and each vertically-extending surface segment within the multiple staircase structures (671, 672, 673) has a height that equals a vertical spacing between a bottom surface of an overlying insulating layer 32 within a respective vertically neighboring pair of insulating layers 32 within the alternating stack (32, 46) and a bottom surface of an underlying insulating layer 32 within the respective vertically neighboring pair. In one embodiment, each laterally neighboring pair of staircase structures along the second horizontal direction hd2 is vertically offset relative to each other by at least a respective set of (K+1) insulating layers 32 within the alternating stack (32, 46). In one embodiment, a lateral extent of 2(K+1) horizontally-extending surface segments of the third staircase structures 673 along the first horizontal direction hd1 is the same as a lateral extent of 2(K+1) horizontally-extending surface segments of the second staircase structures 672 along the first horizontal direction hd1.

In one embodiment, the multiple staircase structures (671, 672, 673) comprises: ascending staircase structures 67A of which horizontally-extending surface segments have a stepwise-increasing height profile that increases stepwise along the first horizontal direction hd1; and descending staircase structures 67D of which horizontally-extending surface segments have a stepwise-decreasing height profile that decreases stepwise along the first horizontal direction hd1. In one embodiment, the first staircase structures 671 comprise a laterally alternating sequence of first descending staircase structures 67D and first ascending staircase structures 67A that alternate along the first horizontal direction hd1; the second staircase structures 672 consist of a second descending staircase structure 67D and a second ascending staircase structure 67A; and the third staircase structures 673 consist of a third descending staircase structure 67D and a third ascending staircase structure 67A.

In one embodiment, each of the first ascending staircase structures 67A comprises a respective set of (K+1) horizontally-extending surface segments; each of the first descending staircase structures 67D comprises a respective set of (K+1) horizontally-extending surface segments; the second ascending staircase structure 67A comprises a set of (K+1) horizontally-extending surface segments; and the third descending staircase structure 67D comprises a set of (K+1) horizontally-extending surface segments. In one embodiment, each of the first ascending staircase structures 67A, the first descending staircase structures 67D, the second ascending staircase structure 67A, and the third descending staircase structure 67D has a same lateral extent along the first horizontal direction hd1. In one embodiment, the second descending staircase structure 67D comprises a set of (K+3) horizontally-extending surface segments; and the third ascending staircase structure 67A comprises a set of (K+3) horizontally-extending surface segments.

In one embodiment, a first subset of the memory opening fill structures 58 is located in a first memory array region 100A; a second subset of the memory opening fill structures 58 is located in a second memory array region 100B that is laterally offset from the first memory array region 100A along the first horizontal direction hd1; and the first staircase structures 671, the second staircase structures 672, the third staircase structures 673, the first surface segment of the top surface of the semiconductor material layer 110, and the second surface segment of the top surface of the semiconductor material layer 110 are located in a contact region 300 located between the first memory array region 100A and the second memory array region 100B. In one embodiment, a predominant subset of the electrically conductive layers 46 extends continuously between the first memory array region 100A and the second memory array region 100B within a connection region 400 that is located between the first memory array region 100A and the second memory array region 100B and laterally offset from the contact region 300 along the second horizontal direction hd2.

In one embodiment, a portion of the alternating stack (32, 46) located in the connection region 400 comprises connection-region staircase structures 67C, wherein each horizontally-extending surface segment of the connection-region staircase structures 67C is located above a horizontal plane including a topmost horizontally-extending surface segment of the first staircase structures 671, and is vertically spaced from the horizontal plane by at least two insulating layers 32 within the alternating stack (32, 46). In one embodiment, each staircase structure within the multiple staircase structures (671, 672, 673) comprises a respective set of (K+1) horizontally-extending surface segments that are adjoined to each other by a respective set of K vertically-extending surface segments; one of the second staircase structures 672 comprises horizontally-extending surface segments that are located within a set of (K+3) horizontal planes; one of the third staircase structure comprises additional horizontally-extending surface segments that are located within the set of (K+3) horizontal planes; and an entirety of horizontally-extending surface segments of the connection-region staircase structures 67C is located within a set of (K+2) horizontal planes that includes each horizontal plane within the set of (K+3) horizontal planes except a bottommost horizontal plane within the set of (K+3) horizontal planes.

In one embodiment, the three-dimensional memory device is embodied as a portion of a semiconductor die 1000; the semiconductor die 1000 comprises a peripheral alternating stack (32, 42) of additional insulating layers 32 and spacer material layers (such as unreplaced portions of the sacrificial material layers 42) located in a peripheral region of the semiconductor die 1000, and further comprises a dielectric moat structure 165 that laterally surrounds the peripheral alternating stack (32, 42); the peripheral alternating stack (32, 42) has a same height as the alternating stack (32, 46); and a straight sidewall of the dielectric moat structure 165 contacts each additional insulating layer 32 within the peripheral alternating stack (32, 42) other than a topmost insulating layer 32 within the peripheral alternating stack (32, 42). In one embodiment, the dielectric moat structure 165 comprises a lateral protrusion region that laterally protrudes inward from the straight sidewall and contacts a sidewall of the topmost insulating layer 32 within the peripheral alternating stack (32, 42) and contacts a sidewall of a topmost spacer material layer within the peripheral alternating stack (32, 42).

The various embodiments of the present disclosure can be employed to provide more compact staircase structures. Furthermore, the number of bridges 186 may be reduced by one in the first through third exemplary structures by covering the connection region 400 with the photoresist layer 29 during the scale etching step shown in FIGS. 4A-4E. This reduces the complexity of the process by reducing the number of bridges 186 without adding any additional photolithography steps. Further, the area occupied by the dielectric moat structures 165 can be reduced by providing long straight sidewalls that extend through each spacer material layer other than the topmost spacer material layer within a peripheral alternating stack (32, 42).

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art.

What is claimed is:

1. A three-dimensional memory device, comprising:
an alternating stack of insulating layers and electrically conductive layers overlying a semiconductor material layer, wherein the alternating stack comprises multiple staircase structures that are arranged along a first horizontal direction, wherein the multiple staircase structures comprise first staircase structures that are interconnected to each other by widthwise sidewalls that laterally extend along a second horizontal direction that is perpendicular to the first horizontal direction, second staircase structures that are laterally spaced from the first staircase structures, and third staircase structures that are laterally spaced from the first staircase structures and from the second staircase structures;
memory openings vertically extending through the alternating stack;
memory opening fill structures located in the memory openings, wherein each of the memory opening fill structures comprises a respective vertical stack of memory elements and a vertical semiconductor channel; and
at least one retro-stepped dielectric material portion contacting the first staircase structures, the second staircase structures, the third staircase structures, a first surface segment of a top surface of the semiconductor material layer located between the first staircase structures and the second staircase structures, and a second surface segment of the top surface of the semiconductor material layer located between the first staircase structures and the third staircase structures.

2. The three-dimensional memory device of claim 1, wherein:
each staircase structure within the multiple staircase structures comprises a respective set of (K+1) horizontally-extending surface segments that are adjoined to each other by a respective set of K vertically-extending surface segments;
K is an integer greater than 2; and
each vertically-extending surface segment within the multiple staircase structures has a height that equals a vertical spacing between a bottom surface of an overlying insulating layer within a respective vertically neighboring pair of insulating layers within the alternating stack and a bottom surface of an underlying insulating layer within the respective vertically neighboring pair.

3. The three-dimensional memory device of claim 2, wherein each laterally neighboring pair of staircase structures along the second horizontal direction is vertically offset relative to each other by at least a respective set of (K+1) insulating layers within the alternating stack.

4. The three-dimensional memory device of claim 1, wherein a lateral extent of 2(K+1) horizontally-extending surface segments of the third staircase structures along the first horizontal direction is the same as a lateral extent of 2(K+1) horizontally-extending surface segments of the second staircase structures along the first horizontal direction.

5. The three-dimensional memory device of claim 1, wherein the multiple staircase structures comprises:
ascending staircase structures of which horizontally-extending surface segments have a stepwise-increasing height profile that increases stepwise along the first horizontal direction; and
descending staircase structures of which horizontally-extending surface segments have a stepwise-decreasing height profile that decreases stepwise along the first horizontal direction.

6. The three-dimensional memory device of claim 5, wherein:
the first staircase structures comprise a laterally alternating sequence of first descending staircase structures and first ascending staircase structures that alternate along the first horizontal direction;
the second staircase structures consist of a second descending staircase structure and a second ascending staircase structure; and
the third staircase structures consist of a third descending staircase structure and a third ascending staircase structure.

7. The three-dimensional memory device of claim 6, wherein:
each of the first ascending staircase structures comprises a respective set of (K+1) horizontally-extending surface segments;
each of the first descending staircase structures comprises a respective set of (K+1) horizontally-extending surface segments;
the second ascending staircase structure comprises a set of (K+1) horizontally-extending surface segments; and
the third descending staircase structure comprises a set of (K+1) horizontally-extending surface segments.

8. The three-dimensional memory device of claim 7, wherein each of the first ascending staircase structures, the first descending staircase structures, the second ascending staircase structure, and the third descending staircase structure has a same lateral extent along the first horizontal direction.

9. The three-dimensional memory device of claim 7, wherein:
the second descending staircase structure comprises a set of (K+3) horizontally-extending surface segments; and
the third ascending staircase structure comprises a set of (K+3) horizontally-extending surface segments.

10. The three-dimensional memory device of claim 1, wherein:
a first subset of the memory opening fill structures is located in a first memory array region;
a second subset of the memory opening fill structures is located in a second memory array region that is laterally offset from the first memory array region along the first horizontal direction; and
the first staircase structures, the second staircase structures, the third staircase structures, the first surface segment of the top surface of the semiconductor material layer, and the second surface segment of the top surface of the semiconductor material layer are located in a contact region located between the first memory array region and the second memory array region.

11. The three-dimensional memory device of claim 10, wherein a predominant subset of the electrically conductive layers extends continuously between the first memory array region and the second memory array region within a connection region that is located between the first memory array region and the second memory array region and laterally offset from the contact region along the second horizontal direction.

12. The three-dimensional memory device of claim 11, wherein a portion of the alternating stack located in the connection region comprises connection-region staircase structures, wherein each horizontally-extending surface segment of the connection-region staircase structures is located above a horizontal plane including a topmost horizontally-extending surface segment of the first staircase structures, and is vertically spaced from the horizontal plane by at least two insulating layers within the alternating stack.

13. The three-dimensional memory device of claim 12, wherein:
a first subset of the electrically conductive layers which form the connection-region staircase structures in the connection region are discontinuous between the first memory array region and the second memory array region;
each of the electrically conductive layers in the first subset is contacted in the contact region by a respective pair of a first layer contact via structure and a second layer contact via structure;
a respective electrically conductive bridge electrically connects the respective pair of the first layer contact via structure and the second layer contact via structure;
a second subset of the electrically conductive layers is continuous between the first memory array region and the second memory array region; and
a respective layer contact via structure contacts each of the electrically conductive layers of the second subset in the contact region.

14. The three-dimensional memory device of claim 12, wherein:
each staircase structure within the multiple staircase structures comprises a respective set of (K+1) horizontally-extending surface segments that are adjoined to each other by a respective set of K vertically-extending surface segments;
one of the second staircase structures comprises horizontally-extending surface segments that are located within a set of (K+3) horizontal planes;
one of the third staircase structure comprises additional horizontally-extending surface segments that are located within the set of (K+3) horizontal planes; and
an entirety of horizontally-extending surface segments of the connection-region staircase structures is located within a set of (K+2) horizontal planes that includes each horizontal plane within the set of (K+3) horizontal planes except a bottommost horizontal plane within the set of (K+3) horizontal planes.

15. The three-dimensional memory device of claim 1, wherein:
the three-dimensional memory device comprises a portion of a semiconductor die;
the semiconductor die comprises a peripheral alternating stack of additional insulating layers and spacer material layers located in a peripheral region of the semiconductor die, and further comprises a dielectric moat structure that laterally surrounds the peripheral alternating stack;
the peripheral alternating stack has a same height as the alternating stack; and
a straight sidewall of the dielectric moat structure contacts each additional insulating layer within the peripheral alternating stack other than a topmost insulating layer within the peripheral alternating stack; and
the dielectric moat structure comprises a lateral protrusion region that laterally protrudes inward from the straight sidewall and contacts a sidewall of the topmost insulating layer within the peripheral alternating stack and contacts a sidewall of a topmost spacer material layer within the peripheral alternating stack.

16. A method forming a three-dimensional memory device, comprising:
forming an alternating stack of insulating layers and sacrificial material layers over a semiconductor material layer, wherein the alternating stack comprises a first memory array region, a second memory array region that is laterally spaced from the first memory array region along a first horizontal direction, and a contact region and a connection region that are located between the first memory array region and the second memory array region and laterally offset from each other along a second horizontal direction;
forming vertical steps extending along the second horizontal direction across the contact region and the connection region by forming trimmable photoresist material portions over the alternating stack and repeatedly performing a combination of processing steps including an anisotropic etch step and a photoresist trimming step, wherein each neighboring pair of trimmable photoresist material portions of the trimmable photoresist material portions is laterally spaced from each other along the first horizontal direction by a same initial gap width that is invariant along the second horizontal direction, and wherein multiple staircase structures are formed in the contact region and connection-region staircase structures are formed in the connection region;
vertically recessing different staircase structures of the multiple staircase structures by different recess depths by performing a series of masked vertical recess processes, whereby the multiple staircase structures comprise a physically exposed top surface segment of each sacrificial material layer within the alternating stack;
forming at least one retro-stepped dielectric material portion over the multiple staircase structures and the connection-region staircase structures; and
replacing the sacrificial material layers with electrically conductive layers.

17. The method of claim 16, further comprising:
forming layer contact via structures which contact the electrically conductive layers; and
forming electrically conductive bridge structures which electrically connect pair of set of the layer contact via structures.

18. The method of claim 16, wherein:
first trimmable photoresist material portions of the trimmable photoresist material portions have a first length along the first horizontal direction; and
at least one second trimmable photoresist material portion of the trimmable photoresist material portions has a second length along the first horizontal direction that is greater than the first length.

19. The method of claim 16, wherein:
the combination of processing steps is repeated (K−1) times;
each staircase structure of the multiple staircase structures and each staircase structure of the connection-region staircase structures comprises K vertically-extending surface segments;
K is an integer greater than 2;
the different recess depths are integer multiples of a unit recess depth that equals the product of (K+1) and a sum of a thickness of an insulating layer in the alternating stack and a thickness of a sacrificial material layer in the alternating stack;
a first surface segment of a top surface of the semiconductor material layer and a second surface segment of the top surface of the surface are exposed after the series of masked vertical recess processes;
the first surface segment and the second surface segment are laterally spaced from each other along the first horizontal direction; and
the multiple staircase structures after the series of masked vertical recess processes comprise first staircase structures located between the first surface segment and the second surface segment, second staircase structures laterally spaced from the first staircase structures by the first surface segment, and third staircase structures laterally spaced from the first staircase structures by the second surface segment.

20. The method of claim 16, further comprising patterning an array of vertical indentation wells that are arranged along the first horizontal direction in upper portion of the alternating stack in the contact region without patterning the alternating stack in the connection region, to form a vertical step between each of the vertical indentation wells and an adjoining portion of the alternating stack.
